(19) United States
(12) Patent Application Publication
(10) Pub. No.: US 2026/0362894 A1
(43) Pub. Date: Nov. 12, 2026

(54) LIGHT-EMITTING DIODE, ELECTRONIC DEVICE COMPRISING THE LIGHT-EMITTING DIODE, AND COMPOSITION FOR PRODUCING LIGHT-EMITTING DIODE

(71) Applicants: Samsung Display Co., LTD., Yongin-si (KR); University of Ulsan Foundation For Industry Cooperation, Ulsan (KR)

(72) Inventors: JUNHA PARK, Yongin-si (KR); MUN-KI SIM, Yongin-si (KR); MIN HYUNG LEE, Ulsan (KR)

(21) Appl. No.: 19/424,579

(22) Filed: Dec. 18, 2025

(30) Foreign Application Priority Data
Apr. 28, 2025 (KR) 10-2025-0055179

(51) Int. Cl. H10K 50/12; C07B 59/00; H10K 85/30; H10K 85/40; H10K 85/60; H10K 102/00

(52) U.S. Cl. CPC H10K 50/12; C07B 59/004; H10K 85/346; H10K 85/40; H10K 85/622; H10K 85/626; H10K 85/633; H10K 85/654; H10K 85/6572; H10K 85/6574; H10K 85/6576; H10K 85/658; C07B 2200/05; H10K 2102/351

(57) ABSTRACT

The present disclosure provides a light-emitting diode, an electronic device including the same, and a composition for producing a light-emitting diode. Particularly, the present disclosure provides a light-emitting diode including a composition for producing a light-emitting diode including a first dopant, which is a fluorescence dopant, and a second dopant, which is a phosphorescence dopant, to improve both material stability and lifespan of a device, an electronic device including the same, and a composition for producing a light-emitting diode.

### CROSS-REFERENCE TO RELATED APPLICATION

The present application claims priority to and the benefit of Korean Patent Application No. 10-2025-0055179, filed on Apr. 28, 2025, in the Korean Intellectual Property Office, and all the benefits accruing therefrom under 35 U.S.C. § 119, the content of which is incorporated herein in its entirety by reference.

### BACKGROUND

### 1. Field

The present disclosure relates to a light-emitting diode, an electronic device including the light-emitting diode, and a composition for producing a light-emitting diode.

### 2. Description of the Related Art

Recently, an organic light-emitting display device as an image display device has been actively developed. An organic light-emitting display device includes a first electrode, a light-emission layer, and a second electrode. The organic light-emitting display device is a display device known as a self-light-emitting type that displays an image by emitting light from a light-emitting material including an organic compound through recombination of a hole and an electron injected from the first electrode and the second electrode in a light-emission layer. In application of the light-emitting diode to a display device, low driving voltage, high light-emission efficiency, and long life span of the light-emitting diode are desired, and continued development of a material for the light-emitting diode to stably implement the above is ongoing.

### SUMMARY

The present disclosure is to provide a light-emitting diode having both improved material stability and device lifespan and provided with excellent electric properties, high electric charge transport capability and light-emission capability, an electronic device including the same and a composition for manufacture of a light-emitting diode.

Additional aspects will be set forth in part in the detailed description that follows and, in part, will be apparent from the detailed description, or may be learned by practice of the presented embodiments herein.

It shall be clearly construed by those of ordinary skill in the art to which the present disclosure pertains that aspects of the present disclosure are not limited to the detailed description, and other undescribed technical objects may be clearly understood from the detailed description and appreciated by those of ordinary skill in the art to which the present disclosure pertains.

A light-emitting diode of an aspect includes a first electrode, a second electrode arranged on the first electrode, and one or more organic layers arranged between the first electrode and the second electrode. At least one organic layer among the one or more organic layers includes a first dopant, which is a fluorescence dopant, and a second dopant, which is a phosphorescence dopant. The first dopant includes a compound represented by Formula 1:

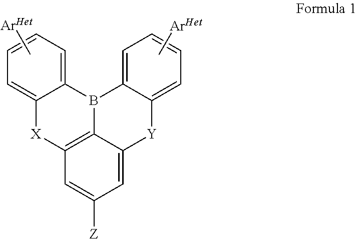

In Formula 1, each Ar^{Het} is independently hydrogen or a substituted or unsubstituted heteroaryl group of 2 to 60 carbons. Each Ar^{Het} is identical to or different from the other. However, at least one of Ar^{Het} is not hydrogen. X and Y are each independently O, S, Se, or NAr¹. Z is hydrogen, deuterium, a halogen, a cyano group, a substituted or unsubstituted silyl group, a substituted or unsubstituted amino group, a substituted or unsubstituted oxy group, a substituted or unsubstituted alkyl group of 1 to 20 carbons, a substituted or unsubstituted aryl group of 6 to 60 ring-forming carbons, or a substituted or unsubstituted heteroaryl group of 2 to 60 ring-forming carbons. Z is optionally bonded to an adjacent group to form a ring. Ar¹ is a substituted or unsubstituted aryl group of 6 to 60 carbons.

In one or more embodiments, the second dopant may include one or more organometallic compounds represented by Formula 2:

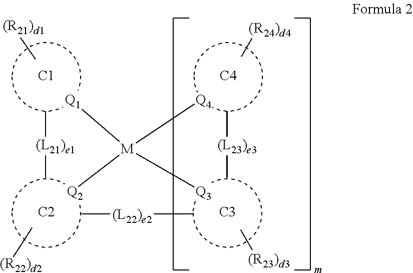

In Formula 2, M may be Pt, Pd, Cu, Os, Ir, Ru, or Rh. Q₁ to Q₄ may each independently be C or N. Ring C₁ to ring C₄ may each independently be a substituted or unsubstituted hydrocarbon ring group of 5 to 30 ring-forming carbons, or a substituted or unsubstituted heteroring group of 2 to 30 ring-forming carbons. R₂₁ to R₂₄ may each independently be hydrogen, deuterium, a halogen, a cyano group, a substituted or unsubstituted silyl group, a substituted or unsubstituted amino group, a substituted or unsubstituted oxy group, a substituted or unsubstituted alkyl group of 1 to 20 carbons, a substituted or unsubstituted aryl group of 6 to 60 ring-forming carbons, or a substituted or unsubstituted heteroaryl group of 2 to 60 ring-forming carbons. R₂₁ to R₂₄ may be optionally bonded to an adjacent group to form a ring. d1 through d4 may each independently be an integer of greater than or equal to 0 and less than or equal to 10. L₂₁ to L₂₃ may each independently be a direct linkage, O, or S. e1 through e3 may each independently be an integer of greater than or equal to 0 and less than or equal to 5. m may be an integer of greater than or equal to 0 and less than or equal to 3.

In one or more embodiments, the first dopant may be one or more of a compound represented by Formula 3 through Formula 6:

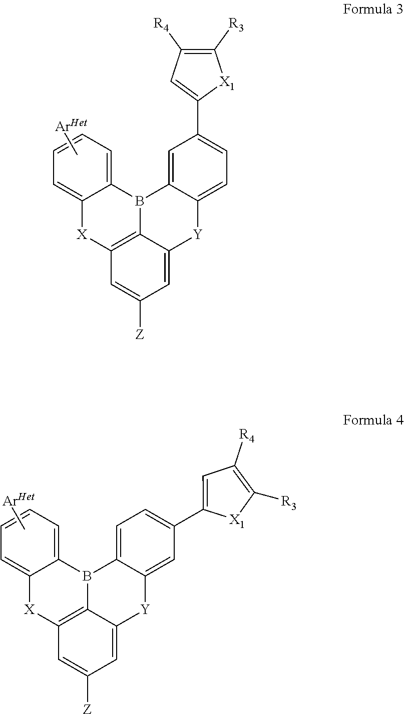

In Formula 3 and Formula 4, X₁ may be N, S, O, or Se; R₃ and R₄ may each independently be hydrogen, a substituted or unsubstituted heteroaryl group of 2 to 30 ring-forming carbons or bonded together to form a ring, and X, Y, and Z may be as defined for Formula 1,

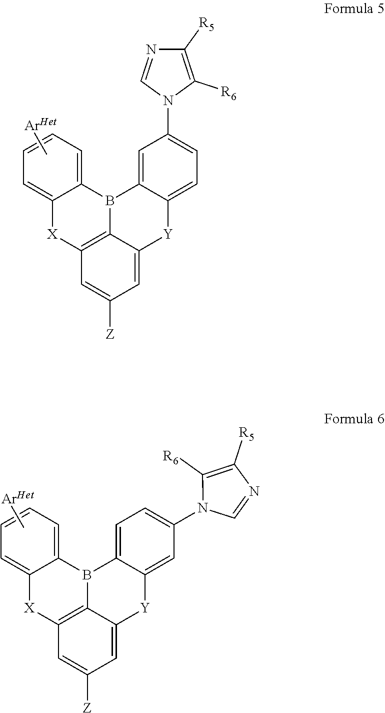

In Formula 5 and Formula 6, R₅ and R₆ may each independently be hydrogen, a substituted or unsubstituted heteroaryl group of 2 to 30 ring-forming carbons or bonded together to form a ring, and X, Y, and Z may be as defined for Formula 1.

In one or more embodiments, each Ar^{Het} may independently be hydrogen, a pyrrole group, a furan group, a thiophene group, a pyrazole group, an imidazole group, a thiazole group, a triazole group, an oxazole group, an isoxazole group, an indole group, an indazole group, a benzofuran group, a benzothiazole group, an indolizine group, or a pyrrolidine group.

In one or more embodiments, the compound represented by the Formula 1 may be one or more of Compound 1 through Compound 19:

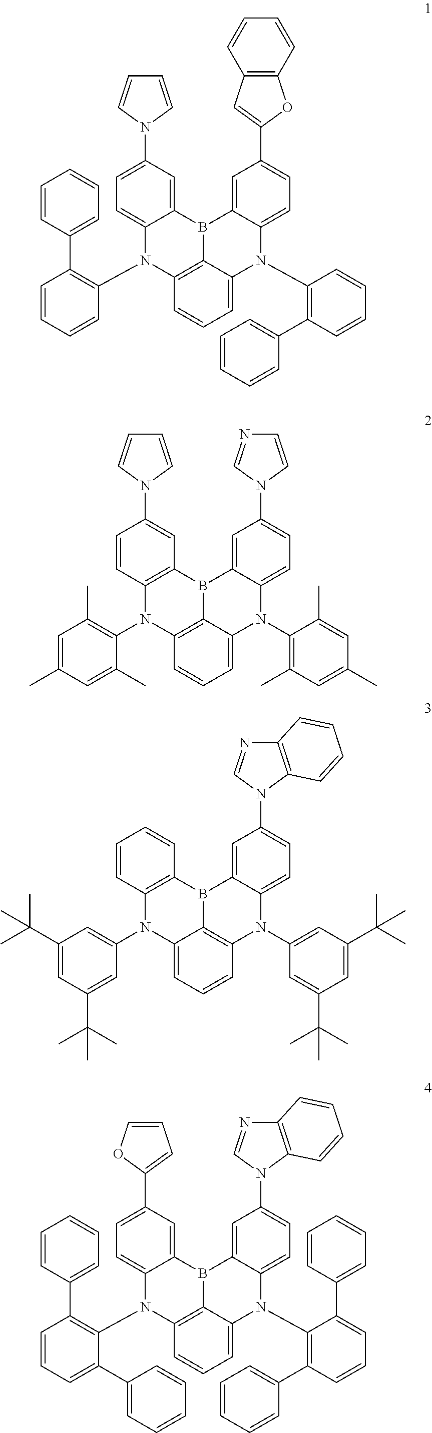

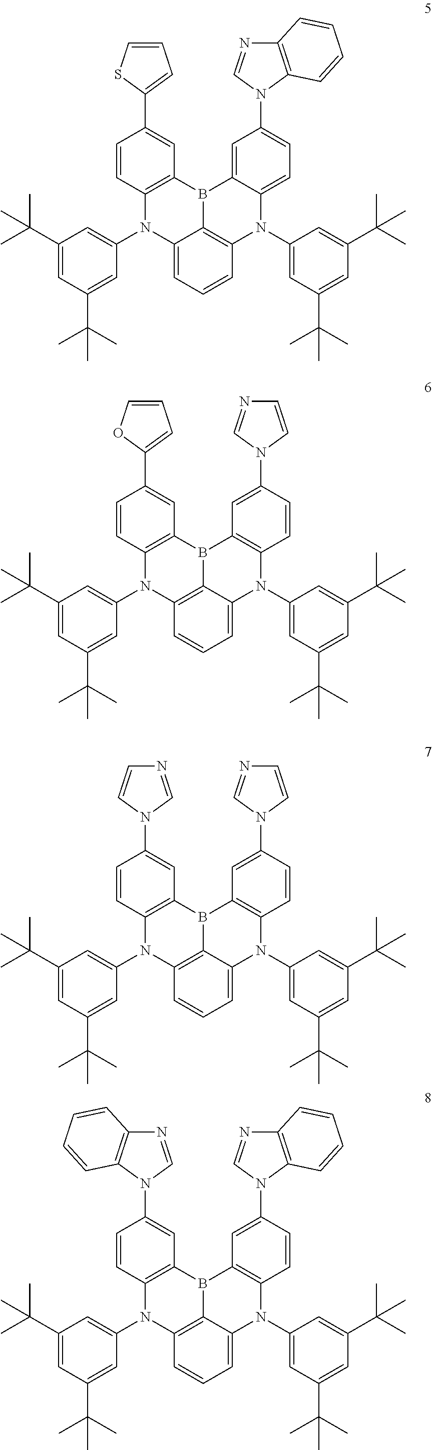

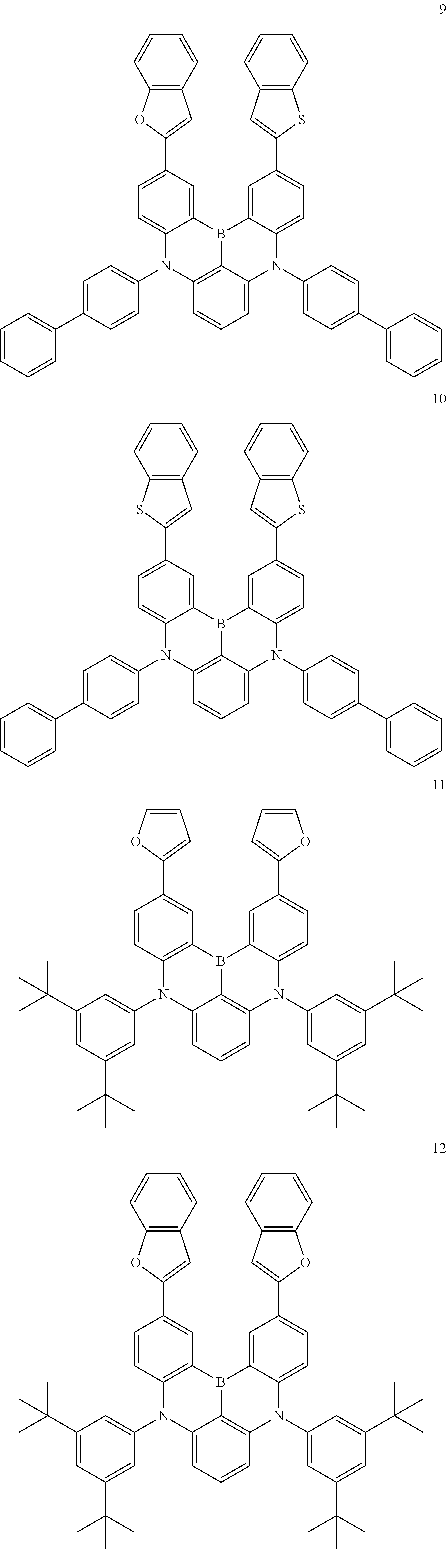

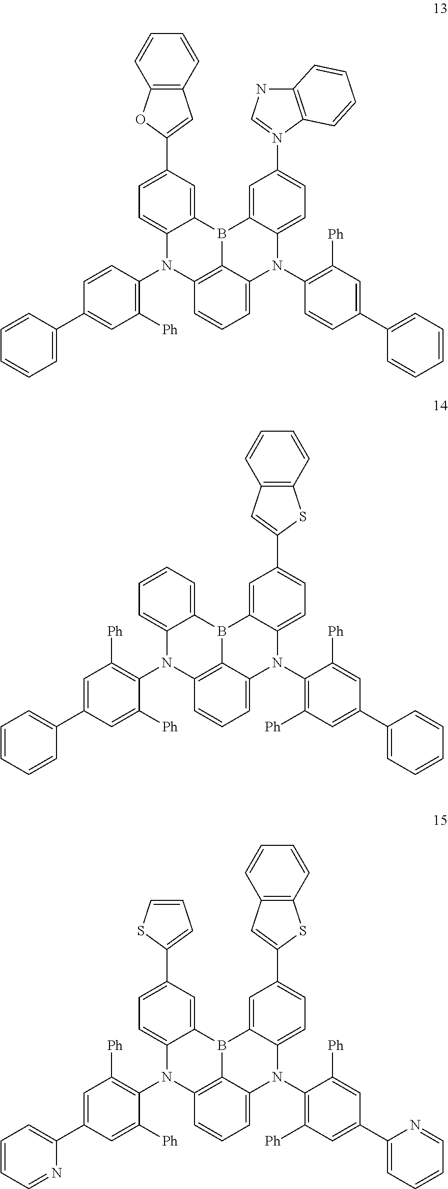

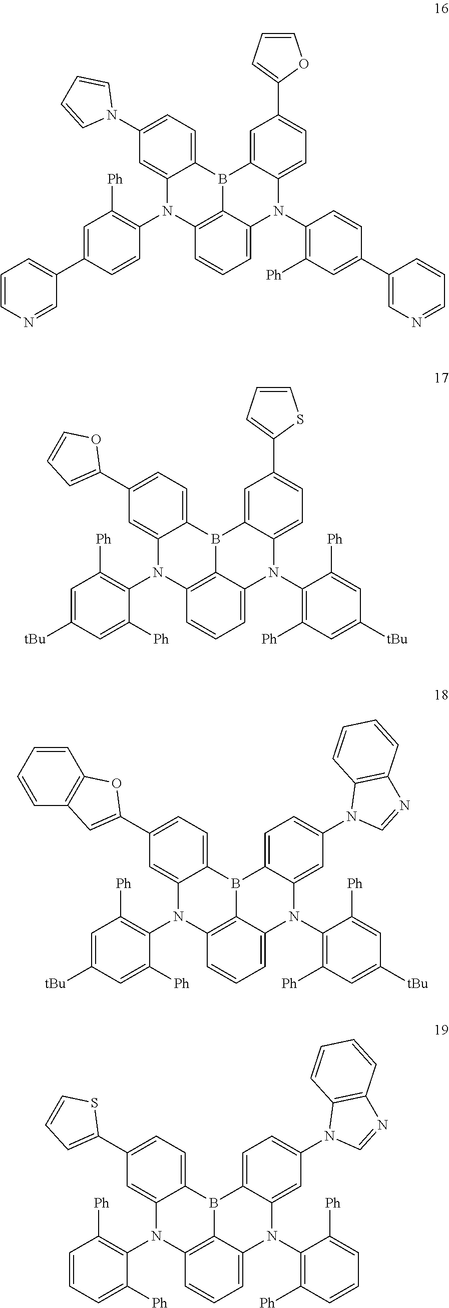

wherein “Ph” is phenyl and “tBu” is tertiary butyl.

In one or more embodiments, the second dopant may include one or more organometallic compounds represented by Formula 7:

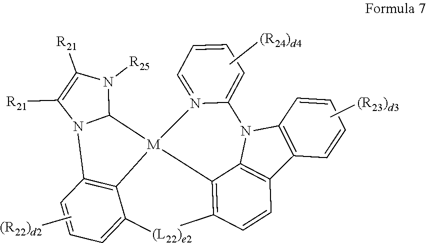

In Formula 7, M may be Pt, Pd, Cu, Os, Ir, Ru, or Rh; R₂₁ to R₂₅ may each independently be hydrogen, deuterium, a halogen, a cyano group, a substituted or unsubstituted silyl group, a substituted or unsubstituted amino group, a substituted or unsubstituted oxy group, a substituted or unsubstituted alkyl group of 1 to 20 carbons, a substituted or unsubstituted aryl group of 6 to 60 ring-forming carbons, or a substituted or unsubstituted heteroaryl group of 2 to 60 ring-forming carbons; R₂₁ to R₂₅ are optionally bonded to an adjacent group to form a ring; d2 through d4 may each independently be an integer of greater than or equal to 0 and less than or equal to 2; L₂₂ may be a direct linkage, O, or S; and e2 may be an integer of 1 or 2.

In one or more embodiments, a weight ratio of the first dopant to the second dopant may be about 1:8 to about 1:30.

In one or more embodiments, the first dopant may have an absorption wavelength of about 440 nanometers (nm) to about 455 nm, and a light-emission wavelength of about 455 nm to about 480 nm.

In one or more embodiments, the first dopant may have a full width at half maximum (FWHM) of less than or equal to about 40 nm.

In one or more embodiments, a thickness of an organic layer manufactured through co-deposition of the first dopant and the second dopant may be greater than or equal to about 100 angstroms (Å) and less than or equal to about 500 Å.

In one or more embodiments, a content of the first dopant may be about 0.01 to about 10 parts by weight based on 100 parts by weight of the light-emission layer, and a content of the second dopant may be about 10 to about 20 parts by weight based on 100 parts by weight of the light-emission layer.

In one or more embodiments, light emitted from the organic layer may have a maximum light-emission wavelength of greater than or equal to about 380 nm and less than or equal to about 500 nm.

In one or more embodiments, the organic layer may be a deep blue light-emission layer.

In one or more embodiments, light-emission quantum efficiency of a light-emission spectrum of the first dopant may be greater than or equal to about 50% and less than or equal to about 100%.

An electronic device according to an aspect may include a light-emitting diode, wherein the light-emitting diode includes a first electrode, a second electrode arranged on the first electrode, and one or more organic layers arranged between the first electrode and the second electrode. At least one organic layer among the one or more organic layers includes a first dopant, which is a fluorescence dopant, and a second dopant, which is a phosphorescence dopant. The first dopant includes a compound represented by Formula 1:

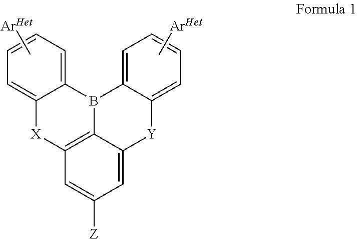

In Formula 1, each Ar^{Het} may independently be hydrogen or a substituted or unsubstituted heteroaryl group of 2 to 60 carbons. Each Ar^{Het} may be identical to or different from the other, provided that at least one of Ar^{Het} is not hydrogen. X and Y may each independently be O, S, Se, or NAr¹. Z may be hydrogen, deuterium, a halogen, a cyano group, a substituted or unsubstituted silyl group, a substituted or unsubstituted amino group, a substituted or unsubstituted oxy group, a substituted or unsubstituted alkyl group of 1 to 20 carbons, a substituted or unsubstituted aryl group of 6 to 60 ring-forming carbons, or a substituted or unsubstituted heteroaryl group of 2 to 60 ring-forming carbons. Z is optionally bonded to an adjacent group to form a ring. Ar¹ may be a substituted or unsubstituted aryl group of 6 to 60 carbons.

In one or more embodiments, the electronic device may include a display device, a processor configured to control the display device, a memory storing data necessary for operation of the display device or the processor, and a power module configured to generate or supply power.

A composition for producing a light-emitting diode according to an aspect includes a first dopant, which is a fluorescence dopant represented by Formula 1, and a second dopant, which is a phosphorescence dopant represented by Formula 2.

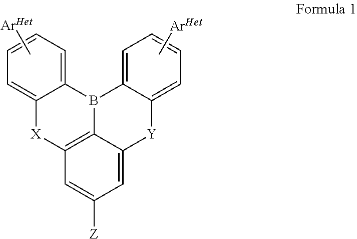

In Formula 1, each Ar^{Het} may independently be hydrogen or a substituted or unsubstituted heteroaryl group of 2 to 60 carbons. Each Ar^{Het} may be identical to or different from the other, provided that at least one Ar^{Het} is not hydrogen. X and Y may each independently be O, S, Se, or NAr¹. Z may be hydrogen, deuterium, a halogen, a cyano group, a substituted or unsubstituted silyl group, a substituted or unsubstituted amino group, a substituted or unsubstituted oxy group, a substituted or unsubstituted alkyl group of 1 to 20 carbons, a substituted or unsubstituted aryl group of 6 to 60 ring-forming carbons, or a substituted or unsubstituted heteroaryl group of 2 to 60 ring-forming carbons. Z is optionally bonded to an adjacent group to form a ring. Ar¹ may be a substituted or unsubstituted aryl group of 6 to 60 carbons.

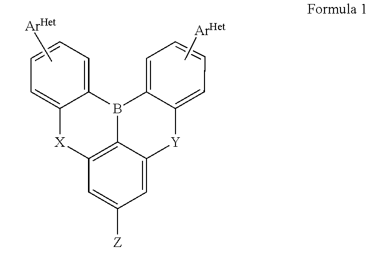

In Formula 2, M may be Pt, Pd, Cu, Os, Ir, Ru, or Rh. Q₁ to Q₄ may each independently be C or N. Ring C₁ to ring C₄ may each independently be a substituted or unsubstituted hydrocarbon ring group of 5 to 30 ring-forming carbons, or a substituted or unsubstituted heteroring group of 2 to 30 ring-forming carbons. R₂₁ to R₂₄ may each independently be hydrogen, deuterium, a halogen, a cyano group, a substituted or unsubstituted silyl group, a substituted or unsubstituted amino group, a substituted or unsubstituted oxy group, a substituted or unsubstituted alkyl group of 1 to 20 carbons, a substituted or unsubstituted aryl group of 6 to 60 ring-forming carbons, or a substituted or unsubstituted heteroaryl group of 2 to 60 ring-forming carbons. R₂₁ to R₂₄ are optionally bonded to an adjacent group to form a ring. d1 through d4 may each independently be an integer of greater than or equal to 0 and less than or equal to 10. L₂₁ to L₂₃ may each independently be a direct linkage, O, or S. e1 through e3 may be an integer of greater than or equal to 0 and less than or equal to 5. m may be an integer of greater than or equal to 0 and less than or equal to 3.

In one or more embodiments, the first dopant may be a compound represented by one of Formula 3 through Formula 6:

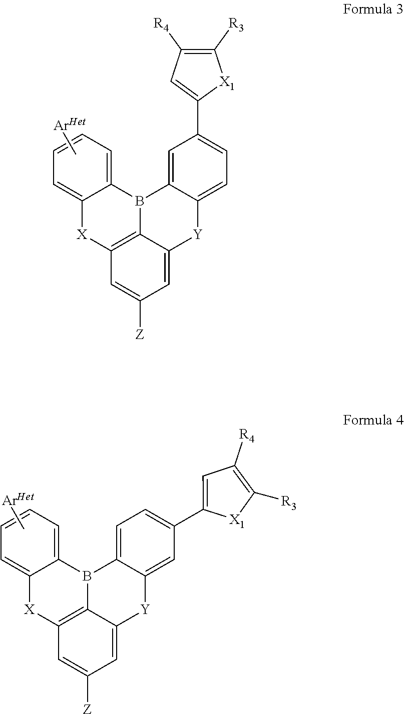

In Formula 3 and Formula 4, X₁ may be N, S, O, and Se. R₃ and R₄ may each independently be hydrogen, a substituted or unsubstituted heteroaryl group of 2 to 30 ring-forming carbons or bonded together to form a ring. X, Y, and Z may be as defined for Formula 1,

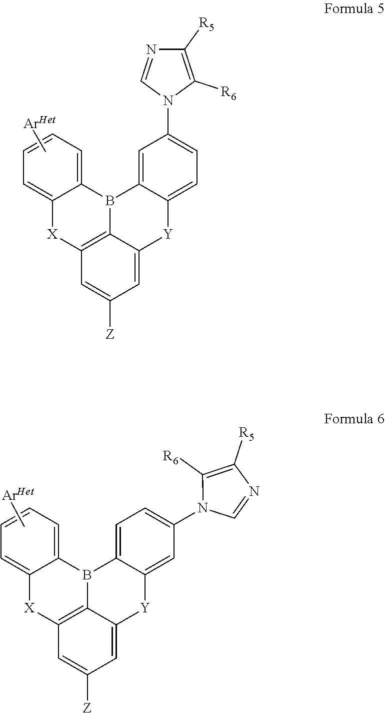

In Formula 5 and Formula 6, R₅ and R₆ may each independently be hydrogen, a substituted or unsubstituted heteroaryl group of 2 to 30 ring-forming carbons or bonded together to form a ring. X, Y, and Z may be as defined for Formula 1.

In one or more embodiments, the second dopant may be one or more organometallic compounds represented by Formula 7:

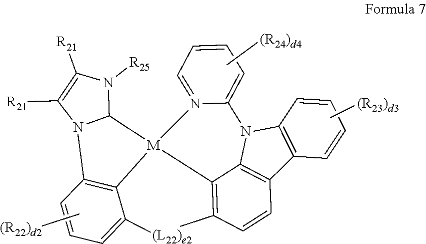

In Formula 7, M may be Pt, Pd, Cu, Os, Ir, Ru, or Rh. R₂₁ to R₂₅ may each independently be hydrogen, deuterium, a halogen, a cyano group, a substituted or unsubstituted silyl group, a substituted or unsubstituted amino group, a substituted or unsubstituted oxy group, a substituted or unsubstituted alkyl group of 1 to 20 carbons, a substituted or unsubstituted aryl group of 6 to 60 ring-forming carbons, or a substituted or unsubstituted heteroaryl group of 2 to 60 ring-forming carbons. R₂₁ to R₂₅ are optionally bonded to an adjacent group to form a ring. d2 through d4 may each independently be an integer of greater than or equal to 0 and less than or equal to 2. L₂₂ may be a direct linkage, O, or S. e2 may be an integer of 1 or 2.

In one or more embodiments, the first dopant may have an absorption wavelength of about 440 nm to about 455 nm, a light-emission wavelength of about 455 nm to about 480 nm, and a full width at half maximum (FWHM) of less than or equal to about 40 nm.

A light-emitting diode of one embodiment can provide a light-emitting diode suitable for an OLED device having a material improving both material stability and device lifespan, provided with excellent electric property, electric charge capability, and light-emitting capability, and having a high glass transition temperature to prevent crystallization.

However, effects of the present disclosure are not limited to the above effects but may be variously extended in a scope without departing from the spirit and scope of the present disclosure.

### BRIEF DESCRIPTION OF THE DRAWINGS

The accompanying drawings are included to provide a further understanding of the present disclosure and are incorporated in and constitute a part of this disclosure. The drawings illustrate embodiments of the present disclosure and, together with the detailed description, serve to explain principles of the disclosure. These and/or other features will become apparent and more readily appreciated from the following detailed description of one or more embodiments, taken in conjunction with the accompanying drawings, in which:

FIG. 1 is a plan view illustrating a display device according to one or more embodiments;

FIG. 2 is a cross-sectional view taken along the I-I′ line shown in FIG. 1;

FIG. 3 through FIG. 6 are cross-sectional views illustrating light-emitting diodes according to one or more embodiments;

FIG. 7 and FIG. 8 are cross-sectional views illustrating portions of display devices according to one or more embodiments;

FIG. 9 is a block diagram of an electronic device according to one or more embodiments; and

FIG. 10 through FIG. 12 are schematic diagrams of electronic devices according to various embodiments.

### DETAILED DESCRIPTION

References will now be made in further detail to exemplary embodiments, of which examples are illustrated in the accompanying drawings, where like reference numerals refer to like elements throughout the disclosure, and duplicative descriptions thereof may not be provided for conciseness. The presented embodiments may have a variety of forms and permutations, but the present disclosure shall by no means be construed as being limited to the described embodiments. Rather, the present disclosure shall be construed to encompass all forms, permutations, equivalents, and substitutes covered by the technical ideas and scope of the present disclosure. Accordingly, one or more embodiments are merely described in further detail, and by referring to the drawings, to explain certain features and aspects of the present disclosure and to convey the scope of the disclosure to those skilled in the art.

Unless otherwise defined, all technical terms and scientific terms used herein have the same meaning as they are generally understood by those of ordinary skill in the art to which the present disclosure pertains. However, if (e.g., when) the meanings do not match, a description, including a definition, of the present disclosure takes precedence.

Terms such as “first” and “second” may be used in describing one or more suitable elements, but the elements shall not be restricted to the terms. The terms may be used only to distinguish one element from the other. For instance, the first element may be named the second element, and vice versa, without departing the scope of the present disclosure. Unless clearly used otherwise, any expressions in a singular form may include a meaning of a plural form. For example, the singular forms “a,” “an,” “one,” and “the” are intended to include the plural forms as well, unless the context clearly indicates otherwise. The term “and/or” or “or” as used herein shall include the combination of a plurality of listed items or any of the plurality of listed items. Further, the utilization of “may” when describing embodiments of the present disclosure refers to “one or more embodiments of the present disclosure.”

When an element is described to be “on,” “placed on,” “arranged on,” “connected to,” or “coupled to” another element, it shall be construed as being on, placed on, arranged on, connected to, or coupled to the other element directly but also as possibly having another element arranged between the element and the other element. In contrast, if (e.g., when) one element is described to be “directly on,” “directly placed on,” “directly arranged on,” “directly connected to,” or “directly coupled to” another element, it shall be construed that there is no other element arranged between the element and the other element.

Herein, an expression such as “comprise(s)/comprising”, “include(s)/including”, or “has(have)/having” is intended to designate a characteristic, a number, a step (e.g., act or task), an operation, an element, a part, and/or one or more (e.g., any suitable) combinations thereof, and shall not be construed to preclude any possibility of presence or addition of one or more other characteristics, numbers, steps, operations, elements, parts, and/or one or more (e.g., any suitable) combinations thereof. Additionally, the terms “comprise(s)/comprising,” “include(s)/including,” “has(have)/having,” or other similar terms include or support the terms “consisting of” and “consisting essentially of,” indicating the presence of stated features, integers, steps, operations, elements, components, and/or groups, without or essentially without the presence of other features, integers, steps, operations, elements, components, and/or groups thereof.

When a component is described to be arranged “on (or below)” an element or “above (or below)” an element, it shall be construed not only as being arranged directly on (or below) the element but also as possibly having another element arranged between the component and the element.

Herein, any reference to “and/or” shall be construed to include one or more combinations that can be defined by relevant elements. A size and a thickness of each configuration illustrated in a drawing is shown as an example for convenience, and embodiments of the present disclosure are not limited thereto.

As used herein, [symbol] may each refer to a binding site to an adjacent atom.

As used herein, a “direct linkage” may refer to a chemical bond, such as a single bond.

As used herein, examples of halogens may include fluorine, chlorine, bromine, and iodine.

As used herein, a “substituted or unsubstituted” group may be a group unsubstituted or substituted with at least one substituent that may be deuterium, halogens, a nitro group, an amino group, a cyano group, a silyl group, an oxy group, a thio group, a sulfinyl group, a sulfonyl group, a carbonyl group, a boron group, an alkyl group, an alkenyl group, an alkynyl group, an alkoxy group, a phosphine sulfide group, a phosphine oxide group, a hydrocarbon ring group, an aryl group, or a heterocyclic group. In addition, each of the substituents presented as examples above may be substituted or unsubstituted. For example, a biphenyl group may be interpreted as an aryl group or as a phenyl group substituted with a phenyl group.

As used herein, the phrase “forming a ring by combining with an adjacent group” and/or the like may refer to forming a substituted or unsubstituted hydrocarbon ring or a substituted or unsubstituted heterocycle by combining with an adjacent group. The hydrocarbon ring includes an aliphatic hydrocarbon ring and/or an aromatic hydrocarbon ring. The heterocycle includes an aliphatic heterocycle and/or an aromatic heterocycle. The carbon ring and the heterocycle may each be monocyclic or a polycyclic. In addition, the formed ring may be combined with another ring to form a spiro structure.

As used herein, the phrase “an adjacent group” may refer to a substituent connected to an atom which is directly connected to another atom substituted with another substituent; a substituent connected to an atom which is substituted with another substituent; or a substituent sterically positioned at the nearest position to another substituent. For example, two methyl groups in 1,2-dimethylbenzene may be interpreted as an “adjacent group” to each other.

As used herein, an “alkyl group” may have a linear chain or a branched chain. The number of carbons in the alkyl group may be 1 to 30, 1 to 20, or 1 to 10. Non-limiting examples of an alkyl group may include methyl, ethyl, propyl, n-propyl, isopropyl, butyl, n-butyl, isobutyl, tert-butyl, sec-butyl, 1-methyl-butyl, 1-ethyl-butyl, pentyl, n-pentyl, isopentyl, neopentyl, tert-pentyl, hexyl, n-hexyl, 1-methylpentyl, 2-methylpentyl, 3,3-dimethylbutyl, 2-ethylbutyl, heptyl, n-heptyl, 1-methylhexyl, octyl, n-octyl, tert-octyl, 1-methylheptyl, 2-ethylhexyl, 2-propylpentyl, n-nonyl, 2,2-dimethylheptyl, 1-ethyl-propyl, 1,1-dimethyl-propyl, isohexyl, 2-methylhexyl, 4-methylhexyl, 5-methylhexyl, or the like.

As used herein, a “cycloalkyl group” may refer to a cyclic alkyl group. The number of carbons in the cycloalkyl group may be 3 to 50, 3 to 30, or 3 to 10. Non-limiting examples of the cycloalkyl group may include cyclopropyl, cyclobutyl, cyclopentyl, cyclohexyl, 4-methylcyclohexyl, 4-t-butylcyclohexyl, cycloheptyl, cyclooctyl, cyclononyl, cyclodecyl, norbornyl, 1-adamantyl, 2-adamantyl, isobornyl, bicycloheptyl, or the like.

As used herein, an “alkenyl group” may refer to a hydrocarbon group including one or more carbon-carbon double bonds in the middle and/or at the terminal of an alkyl group having 2 or more carbons. An alkenyl group may have a linear chain or a branched chain. The number of carbons in the alkenyl group may be, but is not limited to, 2 to 30, 2 to 20, or 2 to 10. Non-limiting examples of the alkenyl group may include 1-butenyl, 1-pentenyl, 1,3-butadienyl, styrenyl, or the like.

As used herein, an “alkynyl group” may refer to a hydrocarbon group including one or more carbon-carbon triple bonds in the middle and/or at the terminal of an alkyl group having 2 or more carbons. The number of carbons in the alkynyl group may be, but is not limited to, 2 to 30, 2 to 20, or 2 to 10. Non-limiting examples of the alkynyl group may include ethynyl, propynyl, or the like.

As used herein, a “carbocyclic ring” refers to a monocyclic or polycyclic group having carbons only as ring-forming atoms and having 3 to 60 carbons. A carbocyclic ring having 3 to 60 carbons may include an aromatic carbocyclic group or a non-aromatic carbocyclic group. Particularly, the carbocyclic group having 3 to 60 carbons may include a non-aromatic carbocyclic group.

As used herein, a “heterocyclic ring” refers to a cyclic group having 1 to 60 carbons and further including at least one heteroatom as a ring-forming atom other than a carbon as ring-forming atom(s). A heteroatom may include one or more of B, O, N, P, Si, S, Se, and Ge.

As used herein, a hydrocarbon ring may be a functional group or any substituent group derived from an aromatic hydrocarbon ring, or any functional group or any substituent group derived from an aromatic hydrocarbon ring, and may include at least one heteroatom selected from B, O, N, P, Si, S, Se, and Ge as an atom. In case that two or more heteroatoms are included, the two or more heteroatoms may be identical to or different from one another.

As used herein, an “aryl group” refers to a functional group or a substituent derived from an aromatic hydrocarbon ring. The aryl group may be a monocyclic aryl group or a polycyclic aryl group. The aryl group may have 6 to 60, 6 to 30, 6 to 20, or 6 to 15 ring-forming carbons. Non-limiting examples of the aryl group may include a phenyl group, a fluorenyl group, an anthracenyl group, a naphthyl group, a terphenyl group, a biphenyl group, a sexiphenyl group, a triphenylenyl group, a (triphenylsilyl)phenyl group, a benzofluoranthenyl group, or the like.

As used herein, a “heteroaryl group” may include at least one of B, O, N, P, Si, S, Se, or Ge as a ring-forming atom. When the heteroaryl group includes two or more heteroatoms, the two or more heteroatoms may be identical to or different from each other. The heteroaryl group may be a monocyclic heteroring or a polycyclic heteroring. The heteroaryl group may have 2 to 60 ring-forming carbons, and 2 to 30, 2 to 20, or 2 to 10 ring-forming carbons. Non-limiting examples may include a furan group, a pyrrole group, an imidazole group, a pyridine group, a pyrimidine group, a triazine group, a pyridazine group, a quinoline group, an isoquinoline group, a pyridopyrimidine group, a benzocarbazole group, a benzofuran group, an oxazole group, or the like.

As used herein, a “heteroring group” (i.e., a heterocyclic group) may refer to any functional group or substituent derived from a ring including at least one of B, O, N, P, Si, S, Se, or Ge as a ring-forming heteroatom. The heteroring group may include an aliphatic heteroring group and/or an aromatic heteroring group. The aromatic heteroring group may be a heteroaryl group. The aliphatic heteroring and the aromatic heteroring may each be a monocyclic or a polycyclic.

As used herein, if (e.g., when) the heteroring group includes two or more heteroatoms, the two or more heteroatoms may be identical to or different from each other. The heteroring group may be a monocyclic heteroring or a polycyclic heteroring and interpreted as a concept including a heteroaryl group. The heteroring group may have 2 to 30, 2 to 20, or 2 to 10 ring-forming carbons.

As used herein, an aliphatic heteroring group may include at least one of B, O, N, P, Si, S, Se, and Ge as a ring-forming heteroatom. The aliphatic heteroring group may have 2 to 30, 2 to 20, or 2 to 10 ring-forming carbons. Non-limiting examples of the aliphatic heteroring group may include a thiirane group, a pyrrolidine group, a piperidine group, a tetrahydrofuran group, 1,4-dioxane group, or the like.

As used herein, the above description of the aryl group may be applied to an arylene group, except that the arylene group is a polyvalent group (e.g., a divalent group). The above description of the heteroaryl may be applied to a heteroarylene group, except that the heteroarylene group is a polyvalent group (e.g., a divalent group). A polyvalent group may refer to, but not limited to, a trivalent or quadrivalent group and be applied with the above description.

As used herein, a “silyl group” may include an alkyl silyl group and/or an aryl silyl group. Non-limiting examples of the silyl group may include a trimethylsilyl group, a triethylsilyl group, a t-butyldimethylsilyl group, a vinyldimethylsilyl group, a propyldimethylsilyl group, a triphenylsilyl group, a diphenylsilyl group, a phenylsilyl group, or the like.

As used herein, a “thio group” may include an alkyl thio group and/or an aryl thio group. A thio group may indicate a group in which a sulfur atom is bonded to an alkyl or an aryl group defined above. Non-limiting examples of the thio group may include a methylthio group, an ethylthio group, a propylthio group, a pentylthio group, a hexylthio group, an octylthio group, a dodecylthio group, a cyclopentylthio group, a cyclohexylthio group, a phenylthiol group, a naphthylthio group, or the like.

As used herein, an “oxy group” may indicate a group in which an oxygen atom is bonded to an alkyl or an aryl group defined above. The oxy group may include an alkoxy group and/or an aryl oxy group. An alkoxy group may be linear, branched, or cyclic. The number of carbon atoms in the alkoxy group is not particularly limited, but may be, for example, 1 to 20, or 1 to 10. Non-limiting examples of the oxy group may include a methoxy, an ethoxy, a n-propoxy, an isopropoxy, a butoxy, a pentyloxy, a hexyloxy, an octyloxy, a nonyloxy, a decyloxy, a benzyloxy, or the like.

As used herein, a “boron group” may refer to a group in which a boron atom is bonded to an alkyl or an aryl group defined above. The boron group may include an alkyl boron group and/or an aryl boron group. Non-limiting examples of the boron group may include a dimethylboron group, a diethylboron group, a t-butylmethylboron group, a diphenylboron group, a phenylboron group, or the like.

As used herein, an amino group refers to a group in which a nitrogen atom is bonded to an alkyl group and/or an aryl group as defined herein. The number of carbon atoms in an amino group is not particularly limited, but may be 1 to 30. The amino group may include an alkyl amino group and/or an aryl amino group. Non-limiting examples of the amino group may include a methylamine group, a dimethylamine group, a phenylamine group, a diphenylamine group, a naphthylamine group, a 9-methyl-anthracenylamine group, a triphenylamine group, or the like.

As used herein, a “fluorenyl group” may be substituted, and two substituents may be combined to form a spiro structure with the fluorenyl group.

As used herein, a term “about,” or similar terms, is not intended to denote a precise value, but rather indicates an approximate value that may account for inherent variations in measurements or calculations as understood by a person ordinarily skilled in the art.

As used herein, the term “about” includes the stated value, and may refer to a range of values that accounts for acceptable variations in consideration of variations related with measurement subject and specific quantity measurement (i.e. limitation due to a measurement system) as determined by a person ordinarily skilled in the art. For example, the term “about” may refer to a range within one or more standard deviations, or within ±30%, 20%, 10%, or 5% of the stated value.

As used herein, unless otherwise defined in the context, the terms, such as “use,” “using,” and “used,” may be considered synonymous with the terms “utilize,” “utilizing,” and “utilized,” respectively.

All numerical ranges recited herein may include all subranges of the same numerical values included in the stated range. For example, a range of “1.0 to 10.0” may include all sub-ranges between the stated minimum value of 1.0 and the stated maximum value of 10.0 (inclusive). That is, the range may include all sub-ranges having a minimum value greater than or equal to 1.0 and a maximum value smaller than or equal to 10.0, such as 2.4 to 7.6.

All maximum numerical limitations recited herein may include all lower numerical limits as if such lower numerical limitations were expressly recited. All minimum numerical limitations recited herein may include all greater numerical limitations as if such greater numerical limitations were expressly recited. All numerical limits recited herein may include all better numerical ranges in the wider numerical limitations as if the narrower numerical limitations were expressly described.

Therefore, the applicant may rightfully amend the present disclosure, including the claims, to expressly recite all subranges within the ranges disclosed herein.

A display equipment/device, an electronic device, a device to manufacture the above, or related equipment/device or element described may be implemented in any suitable way. Embodiments of the present disclosure may be implemented by utilizing a suitable hardware, a firmware (e.g. application-specific integrated circuit), a software, or a combination of a software, a firmware and a hardware. For example, various elements of a device may be formed on one integrated circuit (IC) chip, or on an individual IC chip. In addition, various elements of a device may be implemented on a flexible printed circuit film, a tape carrier package (TCP), a printed circuit board (PCB) or formed on one substrate. Furthermore, various elements of a device may be a process or a thread executed in one or more processors in one or more computing devices and interact with another system element to execute a computer program instruction and execute various functions described in the present disclosure. A computer program instruction may be stored in a memory implemented in a computing device by using a standard memory device, such as a random access memory (RAM). A computer program instruction may also be stored in other non-volatile computer-readable media, such as a CD-ROM and a flash drive. In addition, a person ordinarily skilled in the art will recognize that the functions of various computing devices may be combined or integrated into a single computing device, or that the functions of a specific computing device may be distributed to one or more other computing devices, without departing from the scope of the embodiments.

As used herein, each suitable feature of different embodiments may be partially or wholly combined or combined with one another, and technically linked to operate in various appropriate ways. Unless otherwise expressly or implicitly stated, each embodiment may be implemented independently or in combination with others in a suitable manner.

Hereinafter, certain example embodiments will be described in further detail with reference to the accompanying drawings. In descriptions with reference to the accompanying drawings, a same or corresponding element will be described with a same reference numerals, and redundant descriptions thereof will be omitted.

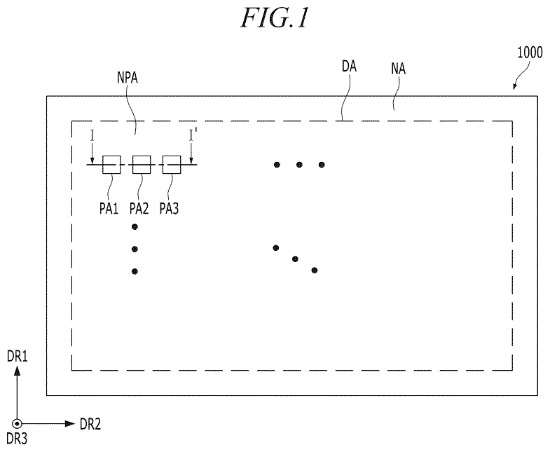

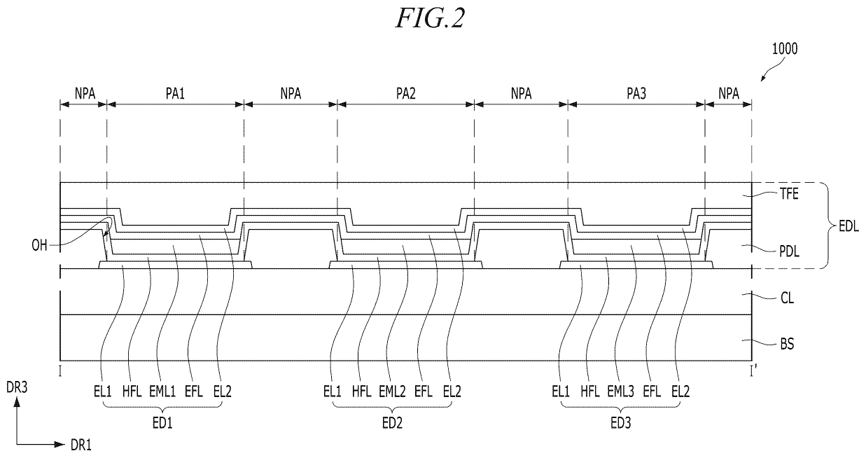

FIG. 1 is a plan view illustrating a display device according to one or more embodiments, and FIG. 2 is a cross-sectional view taken along the I-I′ line shown in FIG. 1.

A first direction through a third direction DR1, DR2, DR3 may be defined. The first direction DR1 and the second direction DR2 may be directions defined on a plane of the display device 1000 shown in FIG. 1 and intersecting each other. The third direction DR3 may be a direction of thickness of the display device defined in FIG. 2.

Referring to FIG. 2, a display device 1000 may include a substrate BS, a circuit layer CL, and a display device layer EDL.

The circuit layer CL and the display device layer EDL may be arranged on the substrate BS.

The substrate BS may include, glass, ceramic, a metal, or a polymer resin such as a polyimide. Yet, embodiments are not limited thereto, and the substrate BS may be an inorganic layer, an organic layer, or a composite material layer, and may be constituted with a single layer or a multilayer.

The circuit layer CL may be arranged on the substrate BS and include a plurality of wires and a plurality of transistors. In one or more embodiments, the circuit layer CL may include pixel transistors configured to drive light-emitting diodes ED1, ED2, and ED3 of the display device layer EDL. The circuit layer CL may include surrounding transistors arranged on a surrounding area NA and configured to output signals to control pixel transistors.

The display device layer EDL may include a pixel defining film PDL, light-emitting diodes ED1, ED2, and ED3, and an encapsulation layer TFE.

The pixel defining film PDL may include at least one insulating material that is a polyimide, a polyamide, an acryl resin, a benzocyclobutene-containing resin, or a phenol resin.

Light-emitting diodes ED1, ED2, ED3 may each include a first electrode EL1, a hole functional layer HFL, a respective light-emission layer EML1, EML2, or EML3, an electron functional layer EFL, and a second electrode EL2.

The hole functional layer HFL may be configured to facilitate movement of a hole from the first electrode EL1 to the respective light-emission layer EML1, EML2, or EML3, and the electron functional layer EFL may be configured to facilitate movement of an electron from the second electron EL2 to the respective light-emission layer EML1, EML2, or EML3. FIG. 2 exemplarily illustrates that the hole functional layer HFL is arranged between the first electrode EL1 and the respective light-emission layer EML1, EML2, or EML3, and the electron functional layer EFL is arranged between the second electrode EL2 and the respective light-emission layer EML1, EML2, or EML3. However, the present disclosure is not limited to what is illustrated in the figure, and the positions of the hole functional layer HFL and the electron functional layer EFL may be exchanged based on whether each of the first electrode EL1 and the second electrode EL2 is positively charged or negatively charged.

FIG. 2 illustrates one or more embodiments where a light-emission layer EML1, EML2, EML3 of light-emitting diodes ED1, ED2, ED3 is arranged in an opening part OH defined in a pixel definition film PDL, and a hole functional layer HFL, an electron functional layer EFL, and a second electrode EL2 are provided as a common layer in all light-emitting diodes ED1, ED2, and ED3. However, the present disclosure is not limited thereto, and unlike FIG. 2, at least one of the hole functional layer HFL and the electron functional layer EFL may be patterned and provided in the opening part OH defined in the pixel definition film PDL.

At least some of the light-emitting diodes ED1, ED2, and/or ED3 may be configured to emit light in different wavelength ranges. For example, a first light-emitting diode ED1 may be configured to emit a red light, a second light-emitting diode ED2 may be configured to emit a green light, and a third light-emitting diode ED3 may be configured to emit a blue light. However, embodiments are not limited thereto, and the first light-emitting diode through the third light-emitting diode ED1, ED2, and ED3 may be configured to emit light of a same wavelength range, for example a blue light.

A configuration of the light-emitting diodes ED1, ED2, and ED3 and a material of a layer consisting of each of the light-emitting diodes ED1, ED2, and ED3 according to various embodiments will be described below.

The encapsulation layer TFE may be configured to seal off the light-emitting diodes ED1, ED2, and ED3 to protect the light-emitting diodes ED1, ED2, and ED3 from moisture, oxygen, and/or foreign substances. In one or more embodiments, the encapsulation layer TFE may be constituted with a single layer. In one or more embodiments, the encapsulation layer TFE may be constituted with multiple layers including an encapsulation organic film and an encapsulation inorganic film.

The encapsulation organic film may include one or more of acrylic compounds, epoxy compounds, and/or the like. In one or more embodiments, the encapsulation organic film may contain, but may not be limited to, one or more of photo-polymerizable organic materials. The encapsulation inorganic film may include, but may not be limited to, silicon nitride, silicon oxynitride, silicon oxide, titanium oxide, and/or aluminum oxide.

Referring to FIG. 1 and FIG. 2, the display device 1000 may be defined with a display area DA and a surrounding area NA defined outside of the display area. The display area DA may be an area configured to display an image and the surrounding area NA may be an area not configured to display an image. In certain embodiments, the surrounding area NA may not be provided.

Pixel areas PA1, PA2, and PA3 and a non-pixel areas NPA may be defined in the display area DA. As light-emitting diodes ED1, ED2, and ED3 may be arranged to correspond to the pixel areas PA1, PA2, and PA3, respectively, the pixel areas may be areas configured to display emitted light. The non-pixel areas NPA may be areas defined among the pixel areas PA1, PA2, and PA3 and correspond to the pixel defining film PDL.

Although it is illustrated in FIG. 1 and FIG. 2 that the pixel areas PA1, PA2, and PA3 have the same area, embodiments of the present disclosure are not limited to what are illustrated in FIG. 2, for example, in one or more embodiments, some of the pixel areas PA1, PA2, and PA3 may have different areas.

An optical layer arranged on the display device layer EDL may be further included in the display device 1000. The optical layer may be configured to reduce reflected light of external light. The optical layer may include a polarizing layer or a color filter layer.

A display device 1000 according to one or more embodiments may further include a touch sensor layer arranged on the display device layer EDL. The touch sensor layer may detect a coordination of a touch where a touch occurs. The touch sensor layer may be arranged between the display device layer EDL and the optical layer.

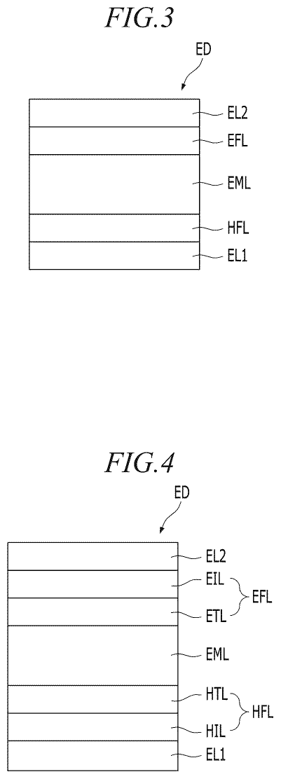

FIG. 3 through FIG. 6 are cross-sectional views illustrating a light-emitting diode according to one or more embodiments.

The light-emitting diode ED according to one or more embodiments illustrated in FIG. 3 may include a first electrode EL1, a hole functional layer HFL, a light-emission layer EML, an electron functional layer EFL, and a second electrode EL2 successively laminated.

In the light-emitting diode ED according to one or more embodiments illustrated in FIG. 4, the hole functional layer HFL may include a hole injection layer HIL and a hole transport layer HTL, and the electron functional layer EFL may include an electron transport layer ETL and an electron injection layer EIL.

In the light-emitting diode ED according to one or more embodiments illustrated in FIG. 5, the hole functional layer HFL may include a hole injection layer HIL, a hole transport layer HTL, and an electron block layer EBL, and the electron functional layer EFL may include a hole block layer HBL, an electron transport layer ETL, and an electron injection layer EIL.

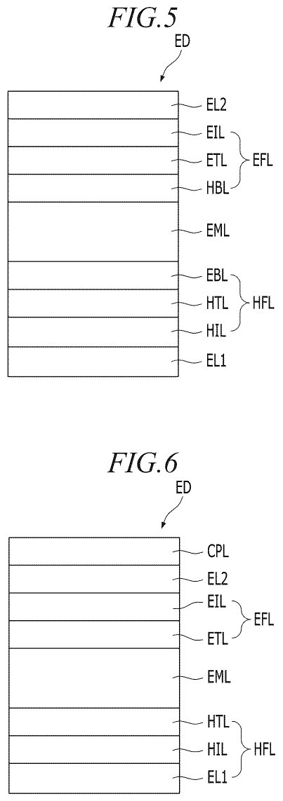

In one or more embodiments illustrated in FIG. 6, the light-emitting diode ED may further include a capping layer CPL arranged on the second electrode EL2 in comparison to the structure shown in FIG. 4.

A light-emitting diode according to one or more embodiments may include a first electrode, a second electrode arranged on the first electrode, and one or more organic layers arranged between the first electrode and the second electrode. At least one organic layer among the one or more organic layers may include a first dopant, which is a fluorescence dopant, and a second dopant, which is a phosphorescence dopant. The first dopant may include a compound represented by Formula 1 as described herein.

### First Electrode EL1

The first electrode EL1 may be conductive. The first electrode EL1 may be formed of a metallic material, a metallic alloy, or a conductive compound. The first electrode EL1 may be an anode or a cathode.

The first electrode may be a reflective electrode, a semi-transmissive electrode, or a transmissive electrode. If (e.g., when) the first electrode EL1 is a transmissive electrode, material(s) such as indium tin oxide (ITO), indium zinc oxide (IZO), zinc oxide (ZnO), indium tin zinc oxide (ITZO) may be included. If (e.g., when) the first electrode EL1 is a semi-transmissive electrode or a reflective electrode, the first electrode EL1 may include silver (Ag), magnesium (Mg), copper (Cu), aluminum (Al), platinum (Pt), palladium (Pd), gold (Au), nickel (Ni), neodymium (Nd), iridium (Ir), chromium (Cr), lithium (Li), calcium (Ca), LiF/Ca (lamination structure of lithium fluoride (LiF) and Ca), LiF/Al (lamination structure of LiF and Al), molybdenum (Mo), titanium (Ti), tungsten (W), and/or a (e.g., any suitable) combination and/or mixture thereof (e.g., a mixture of Ag and Mg)). In one or more embodiments, the first electrode EL1 may have a multilayer structure including a reflective film or a semi-transmissive film including one or more of the aforementioned materials and a transparent conductive film including ITO (indium tin oxide), IZO (indium zinc oxide), ZnO (zinc oxide), ITZO (indium tin zinc oxide), and/or the like. For example, in one or more embodiments, the first electrode EL1 may have a triple layer structure of ITO/Ag/ITO or a multiple layer structure of a triple layer structure of ITO/Al/ITO, but embodiments are not limited to this configuration.

### Organic Layer

One or more organic layers are included or arranged between the first electrode and the second electrode. The one or more organic layers may include a light-emission layer EML and further include a hole functional layer HFL between a first electrode and the light-emission layer EML, and an electron functional layer EFL between the light-emission layer and a second electrode.

### Hole Functional Layer (HFL)

The hole functional layer HFL may be provided on a first electrode EL1. The hole functional layer HFL may include at least one of a hole injection layer HIL, a hole transport layer HTL, a buffer layer, a light-emission auxiliary layer, and an electron blocking layer EBL.

The electron functional layer HFL may have a single layer structure composed of a single layer including (e.g., consisting of) a single material, a single layer structure composed of a single layer including (e.g., consisting of) a plurality of different materials, or a multilayer structure having a plurality of layers including (e.g., consisting of) a plurality of different materials.

For example, the hole functional layer HFL may have a structure, in which constituting layers are sequentially stacked from the first electrode EL1, of a hole injection layer HIL/hole transport layer HTL, a hole injection layer HIL/hole transport layer HTL/buffer layer, a hole injection layer HIL/buffer layer, a hole transport layer HTL/buffer layer, or a hole injection layer HIL/hole transport layer HTL/electron block layer EBL, but embodiments are not limited thereto.

The hole functional layer HFL may be manufactured by utilizing a method selected from among vacuum deposition, spin coating, Langmuir-Blodgett (LB) casting, ink-jet printing, laser induced thermal imaging (LITI), or the like, but embodiments are not limited thereto.

In one or more embodiments, the hole functional layer HFL may include a compound represented by Formula H-1, a compound represented by Formula H-2, or a (e.g., any suitable) combination thereof:

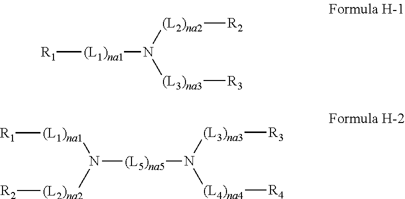

In Formula H-1 and Formula H-2, the L₁ through L₅ may each independently be a direct linkage, a substituted or unsubstituted arylene group having 6 to 30 ring-forming carbons, or a substituted or unsubstituted heteroarylene group having 2 to 30 ring-forming carbons.

The na1 through na4 may each independently be an integer of greater than or equal to 0 and less than or equal to 5.

na5 may be an integer of greater than or equal to 1 and less than or equal to 10.

In Formula H-1 and Formula H-2, the R₁ through R₄ each independently are a hydrogen, a deuterium, a halogen, a substituted or unsubstituted alkyl group having 1 to 20 carbons, a cycloalkyl group having 3 to 10 carbons, a substituted or unsubstituted heterocycloalkyl group having 1 to 10 carbons, a substituted or unsubstituted cycloalkenyl group having 3 to 10 carbons, a substituted or unsubstituted heterocycloalkenyl group having 1 to 10 carbons, a substituted or unsubstituted aryl group having 6 to 60 carbons, a substituted or unsubstituted aryloxy group having 6 to 60 carbons, a substituted or unsubstituted arylthio group having 6 to 60 carbons, or a substituted or unsubstituted heteroaryl group having 1 to 60 carbons. For example, R₁ through R₄ may each independently be, but are not limited to, a phenyl group, a biphenyl group, a terphenyl group, a naphthyl group, a fluorenyl group, a spiro-bifluorenyl group, a benzofluorenyl group, a dibenzofluorenyl group, a phenanthrenyl group, a fluoranthenyl group, a triphenylenyl group, a pyrenyl group, a perylenyl group, a pentaphenyl group, a thiophenyl group, a furanyl group, a carbazolyl group, an indolyl group, an isoindolyl group, a benzofuranyl group, a benzothiophenyl group, a dibenzofuranyl group, a dibenzothiophenyl group, a benzocarbazolyl group, a dibenzocarbazolyl group, a dibenzosilolyl group, or a pyridinyl group.

R₁ and R₂ may be optionally connected to each other through a single bond, and/or R₃ and R₄ may be optionally connected to each other through a single bond.

In one or more embodiments, the compound may be a carbazole-containing compound including a substituted or unsubstituted carbazole group bonded to at least one of R₁ through R₄, or the compound may be a fluorenyl-containing compound including a substituted or unsubstituted fluorenyl group bonded to at least one of R₁ through R₄.

A compound represented by Formula H-1 and Formula H-2 may be represented by N-([1,1′-Biphenyl]-4-yl)-9,9-dimethyl-N-(4-(9-phenyl-9H-carbazol-3-yl)phenyl)-9H-fluoren-2-a mine (BCFN) among compounds provided in device manufacture examples of the present disclosure, but embodiments are not limited thereto.

The hole functional layer HFL may include at least one of 4,4′,4″-tris {N,-(2-naphthyl)-N-phenylamino}-triphenylamine (2-TNATA), Poly(3,4-ethylenedioxythiophene)/Poly(4-styrenesulfonate) (PEDOT/PSS), 4,4′,4″-tris(3-methylphenylphenylamino)triphenylamine (m-MTDATA), 4,4′4″-Tris(N,N-diphenylamino)triphenylamine (TDATA), a phthalocyanine compound, such as copper phthalocyanine, N,N′-diphenyl-N,N′-bis-[4-(phenyl-m-tolyl-amino)-phenyl]-biphenyl-4,4′-diamine (DNTPD), Polyaniline/Dodecylbenzenesulfonic acid (PANI/DBSA), N,N′-di(naphthalen-1-yl)-N,N′-diphenyl-benzidine (NPB), triphenylamine-containing polyetherketone (TPAPEK), 4-Isopropyl-4′-methyldiphenyliodonium Tetrakis(pentafluorophenyl)borate, or dipyrazino[2,3-f: 2′,3′-h] quinoxaline-2,3,6,7,10,11-hexacarbonitrile (HAT-CN), but embodiments are not limited thereto.

In one or more embodiments, the hole functional layer HFL may include at least one of a carbazole-containing derivative, such as polyvinyl carbazole and/or N-phenyl carbazole, a fluorene-containing derivative, a triphenylamine-containing derivative, such as 4,4′4″-tris(N-carbazolyl)triphenylamine (TCTA) or N,N′-bis(3-methylphenyl)-N,N′-diphenyl-[1,1′-biphenyl]-4,4′-diamine (TPD), N,N′-di(naphthalen-1-yl)-N,N′-diphenyl-benzidine (NPB), 4,4′-Cyclohexylidene bis[N,N-bis(4-methylphenyl)benzenamine] (TAPC), 4,4′-Bis[N,N′-(3-tolyl)amino]-3,3′-dimethylbiphenyl (HMTPD), and/or 1,3-Bis(N-carbazolyl)benzene (mCP).

In one or more embodiments, the hole functional layer HFL may include, for example, 1,3-bis(1,8-dimethyl-9H-carbazol-9-yl)benzene (mDCP), 9-(4-tert-Butylphenyl)-3,6-bis(triphenylsilyl)-9H-carbazole (CzSi), or 9-phenyl-9H-3,9′-bicarbazole (CCP), but embodiments are not limited thereto.

The hole functional layer HFL may have a thickness of about 50 angstroms (Å) to about 10000 Å, e.g., about 100 Å to about 5000 Å. If (e.g., when) the hole functional layer HFL includes a hole injection layer HIL, a hole transport layer HTL, or any combination thereof, the hole injection layer HIL may have a thickness of about 100 Å to about 9000 Å, e.g., about 100 Å to about 1000 Å, and the hole transport layer may have a thickness of about 50 Å to about 2000 Å, e.g., about 100 Å to about 1500 Å. When the thicknesses of the hole functional layer HFL, the hole injection layer HIL, and the hole transport layer HTL satisfy their respective above-described ranges, satisfactory level of hole transport properties may be obtained without a substantial increase in driving voltage.

In one or more embodiments, the hole functional layer HFL may further include, in addition to one or more of the above-described materials, a charge-generation material to increase conductivity. The charge-generation material may be uniformly (e.g., substantially uniformly) or non-uniformly dispersed in the hole functional layer HFL.

The charge-generation material may be, for example, a p-dopant

According to one or more embodiments, the p-dopant may include at least one of a halogenated metal compound (e.g., a metal halide), a quinone derivative, a metal oxide, or a cyano group-containing compound, but embodiments are not limited thereto. For example, the p-dopant may include a halogenated metal compound, such as CuI and/or RbI, a quinone derivative, such as tetracyanoquinodimethane (TCNQ) or 2,3,5,6-tetrafluoro-7,7,8,8-tetracyanoquinodimethane (F4-TCNQ), a cyano-group containing compound, such as dipyrazino[2,3-f: 2′3′-h]quinoxaline-2,3,6,7,10,11-hexacarbonitrile (HATCN) or 4-[[2,3-bis[cyano-(4-cyano-2,3,5,6-tetrafluorophenyl)methylidene] cyclopropylidene]-cyanomethyl]-2,3,5,6-tetrafluorobenzonitrile (NDP9), and/or a metal oxide, such as a tungsten oxide and/or a molybdenum oxide, but embodiments are not limited thereto.

As described above, the hole functional layer HFL may further include at least one of a buffer layer and an electron blocking layer EBL in addition to a hole injection layer HIL and a hole transport layer HTL. The buffer layer may be configured to compensate a resonance distance according to a wavelength of emitted light to increase light-emission efficiency. A material included in the buffer layer may be used as a material to be included in the hole functional layer HFL. The electron blocking layer EBL is a layer that is configured to prevent or reduce the injection of electrons from the electron functional layer EFL to the hole functional layer HFL.

The emission auxiliary layer is a layer configured to compensate an optical resonance distance according to a wavelength of light emitted from the light-emitting layer to increase light-emitting efficiency, and the electron blocking layer EBL is a layer configured to prevent or reduce leakage of an electron from the light-emitting layer to the hole functional layer HFL. A material that may be included in the described hole functional layer HFL may be included in the light-emission auxiliary layer and the light blocking layer EBL. The light-emission layer EML may be provided on the hole functional layer HFL.

### Light-Emission Layer (EML)

The light-emission layer EML may have a single layer structure including (e.g., consisted of) a single layer including (e.g., consisting of) a single material, a single layer structure including (e.g., consisted of) a single layer including a plurality of different materials, or a multi-layer structure including (e.g., consisted of) a plurality of layers including a plurality of different materials.

In case that the organic light-emitting diode is a full-color organic light-emitting diode, the light-emission layer may be patterned into a red light-emission layer, a green light-emission layer, and/or a blue-light-emission layer for an individual sub pixel. In addition, the light-emission layer may have a lamination structure in which two or more layers selected from the red light-emission layer, the green light-emission layer, and the blue light-emission layer are in contact or spaced apart, or a structure, in which two or more materials among a red light emission material, a green light emission material, and a blue light emission material are mixed without layer separation, to emit white light.

The light-emission layer EML may include a host and a dopant.

### HT Host

The light-emission layer EML may include a compound represented by Formula HTH-1 as a HT host:

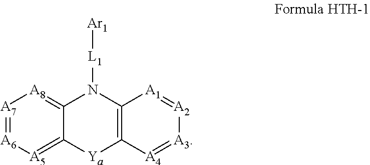

In Formula HTH-1, A₁ through A₈ may each independently by N or CR₁.

For example, A₁ through A₈ may all be CR₁. In another embodiment, any one of A₁ through A₈ may be N, and others may be CR₁.

In Formula HTH-1, Yₐ may be a direct linkage, O, S, C₂R₃, SiR₄R₅, NR₆, or BR₇. For example, it may refer to that two 6-membered rings (e.g., two benzene rings) coupled to the nitrogen atom of Formula HTH-1 may be connected via a direct linkage, O, S,

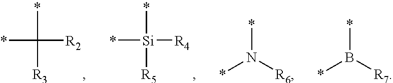

In Formula HTH-1, if (e.g., when) Yₐ is a direct linkage, the compound represented by Formula HTH-1 may include a carbazole moiety.

In Formula HTH-1, L₁ may be a direct linkage, a substituted or unsubstituted arylene group of 6 to 50 ring-forming carbons, or a substituted or unsubstituted heteroarylene group of 2 to 50 ring-forming carbons. For example, in one or more embodiments, L₁ may be a direct linkage, a substituted or unsubstituted phenylene group, a divalent carbazole group, or a divalent biphenyl group, but embodiments are not limited thereto.

In Formula HTH-1, Ar₁ may be a substituted or unsubstituted aryl group of 6 to 30 ring-forming carbons or a substituted or unsubstituted heteroarylene group of 2 to 30 ring-forming carbons. For example, in one or more embodiments, Ar₁ may be a substituted or unsubstituted phenyl group, a biphenyl group, a carbazole group, a dibenzothiophene group, or a dibenzofuran group, but embodiments are not limited thereto.

In Formula HTH-1, R₁ through R₇ may each independently be hydrogen, deuterium, a halogen, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group of 1 to 20 carbons, a substituted or unsubstituted alkenyl group of 2 to 20 ring-forming carbons, a substituted or unsubstituted aryl group of 6 to 50 ring-forming carbons, or a substituted or unsubstituted heteroaryl group of 2 to 50 ring-forming carbons. In another embodiment, R₁ through R₇ may each bond to an adjacent group to form a ring. For example, R₁ through R₇ may each independently be hydrogen, deuterium, an unsubstituted methyl group, or an unsubstituted phenyl group.

In one or more embodiments, a hole transport host represented by Formula HTH-1 may be represented by HT-1 through HT-5, but embodiments are not limited thereto:

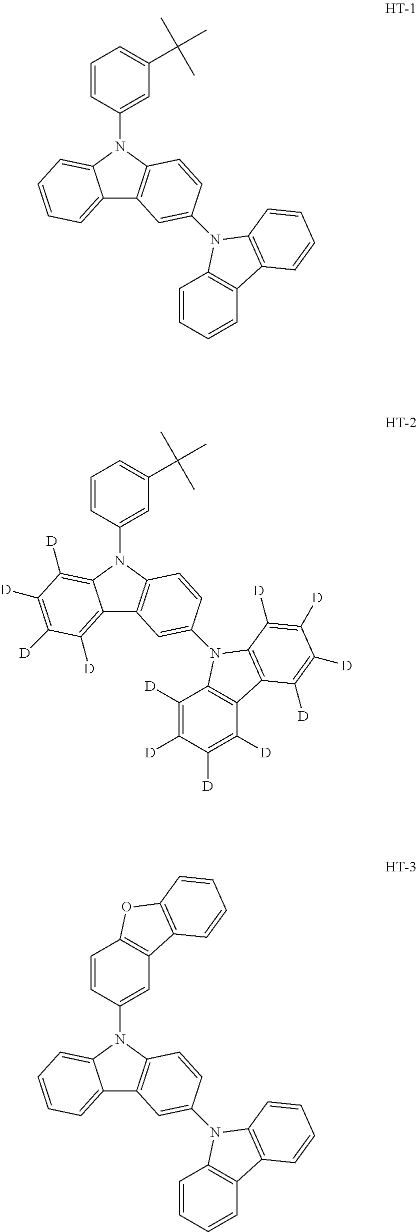 [SMILES: CC(C)(C)c1cccc(-n2c3ccccc3c3cc(-n4c5ccccc5c5ccccc54)ccc32)c1 ; [2H]c1c([2H])c([2H])c2c(c1[2H])c1cc(-n3c4c([2H])c([2H])c([2H])c([2H])c4c4c([2H])c([2H])c([2H])c([2H])c43)ccc1n2-c1cccc(C(C)(C)C)c1 ; c1ccc2c(c1)oc1ccc(-n3c4ccccc4c4cc(-n5c6ccccc6c6ccccc65)ccc43)cc12]

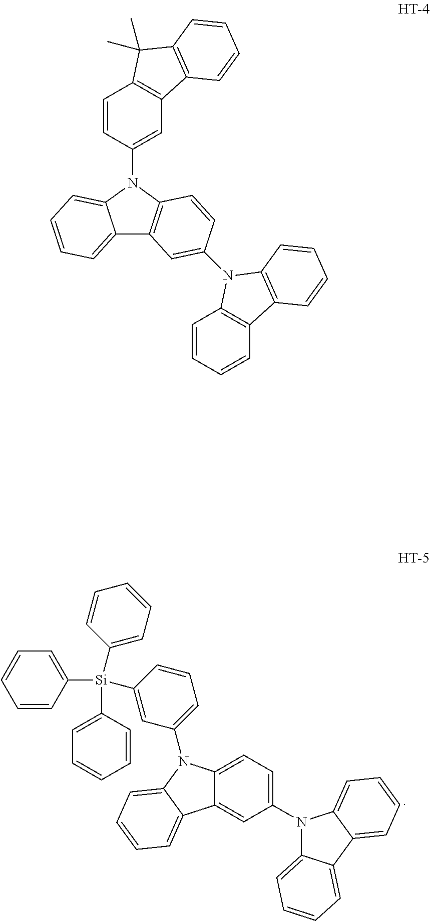 [SMILES: CC1(C)c2ccccc2-c2cc(-n3c4ccccc4c4cc(-n5c6ccccc6c6ccccc65)ccc43)ccc21 ; c1ccc([Si](c2ccccc2)(c2ccccc2)c2cccc(-n3c4ccccc4c4cc(-n5c6ccccc6c6ccccc65)ccc43)c2)cc1]

### ET Host

The light-emission layer EML may further include a compound represented by Formula ETH-1 as an ET host:

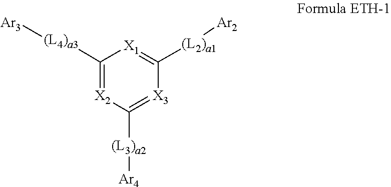

In Formula ETH-1, X₁ may be N or CR₉, X₂ may be N or CR₁₀, X₃ may be N or CR₁₁, and at least one of X₁ through X₃ may be N, and the R₉ through R₁₁ may be a hydrogen, a deuterium, a halogen, a hydroxyl group, a cyano group, a nitro group, a substituted or unsubstituted alkyl group having 1 to 20 carbons, a substituted or unsubstituted alkenyl group having 2 to 20 carbons, a substituted or unsubstituted alkoxy group having 1 to 20 carbons, a substituted or unsubstituted alkynyl group having 2 to 20 carbons, a substituted or unsubstituted aryl group having 6 to 50 ring-forming carbons, or a substituted or unsubstituted heteroaryl group having 2 to 50 ring-forming carbons.

L₂ through L₄ may each independently be a direct linkage, a substituted or unsubstituted arylene group having 6 to 30 ring-forming carbons, or a substituted or unsubstituted heteroarylene group having 2 to 30 ring-forming carbons. In one or more embodiments, in case that the a₁ through a₃ each is an integer greater than or equal to 2, L₂ through L₄ may each independently be a substituted or unsubstituted arylene group having 6 to 30 ring-forming carbons, or a substituted or unsubstituted heteroarylene group having 2 to 30 ring-forming carbons.

a1 through a3 may each independently be an integer of greater than or equal to 0 and less than or equal to 10.

The Ar² through Ar⁴ may each independently be a hydrogen, a deuterium, a substituted or unsubstituted alkyl group having 1 to 20 carbons, a substituted or unsubstituted aryl group having 6 to 30 ring-forming carbons, or a substituted or unsubstituted heteroaryl group having 2 to 30 ring-forming carbons. For example, Ar² through Ar⁴ may each independently be a substituted or unsubstituted phenyl group, or a substituted or unsubstituted carbazole group.

In the light-emission layer EML, an electron transport host compound represented by Formula ETH-1 may be represented by one of ET-1 through ET-3, but embodiments are not limited thereto:

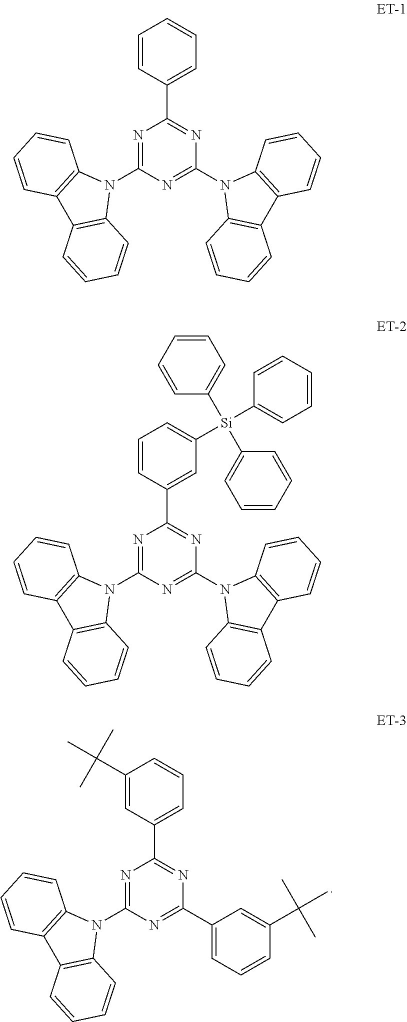 [SMILES: c1ccc(-c2nc(-n3c4ccccc4c4ccccc43)nc(-n3c4ccccc4c4ccccc43)n2)cc1 ; c1ccc([Si](c2ccccc2)(c2ccccc2)c2cccc(-c3nc(-n4c5ccccc5c5ccccc54)nc(-n4c5ccccc5c5ccccc54)n3)c2)cc1 ; CC(C)(C)c1cccc(-c2nc(-c3cccc(C(C)(C)C)c3)nc(-n3c4ccccc4c4ccccc43)n2)c1]

In a light-emitting diode of one or more embodiments, the light-emission layer EML may include an anthracene derivative, a fluoranthene derivative, a chrysene derivative, a pyrene derivative, a dihydrobenzanthracene derivative, or a triphenylene derivative. For example, in one or more embodiments, the light-emission layer EML may include an anthracene derivative and/or a pyrene derivative.

A compound represented by Formula EM-1 may be used as a fluorescence host material.

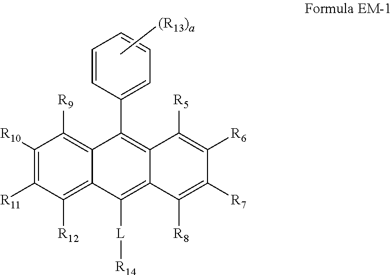

In Formula EM-1, L may be a direct linkage, a substituted or unsubstituted arylene group having 6 to 30 ring-forming carbons, or a substituted or unsubstituted heteroarylene group having 2 to 30 ring-forming carbons. Non-limiting examples of L may be a phenylene group, a biphenylene group, a terphenylene group, a naphthalene group, a phenanthrene group, a pyrene group, a spiro-fluorenylene group, a fluorenylene group, a dibenzofuranylene group, a dibenzothiophenylene group, or a carbazolylene group, but embodiments are not limited thereto.

R₅ through R₁₄ may each independently be hydrogen, deuterium, a halogen, a substituted or unsubstituted oxy group, a substituted or unsubstituted thio group, a substituted or unsubstituted silyl group, a substituted or unsubstituted alkyl group of 1 to 30 carbons, a substituted or unsubstituted alkenyl group of 2 to 30 carbons, a substituted or unsubstituted aryl group of 6 to 30 ring-forming carbons, or a substituted or unsubstituted heteroaryl group of 2 to 30 ring-forming carbons. In some embodiments, R₅ through R₁₄ may be bonded to an adjacent group to form a ring.

In Formula EM-1, a may be an integer between 0 and 5, inclusive.

An anthracene compound represented by Formula EM-1 may be represented by one of E1 through E12, but embodiments are not limited thereto:

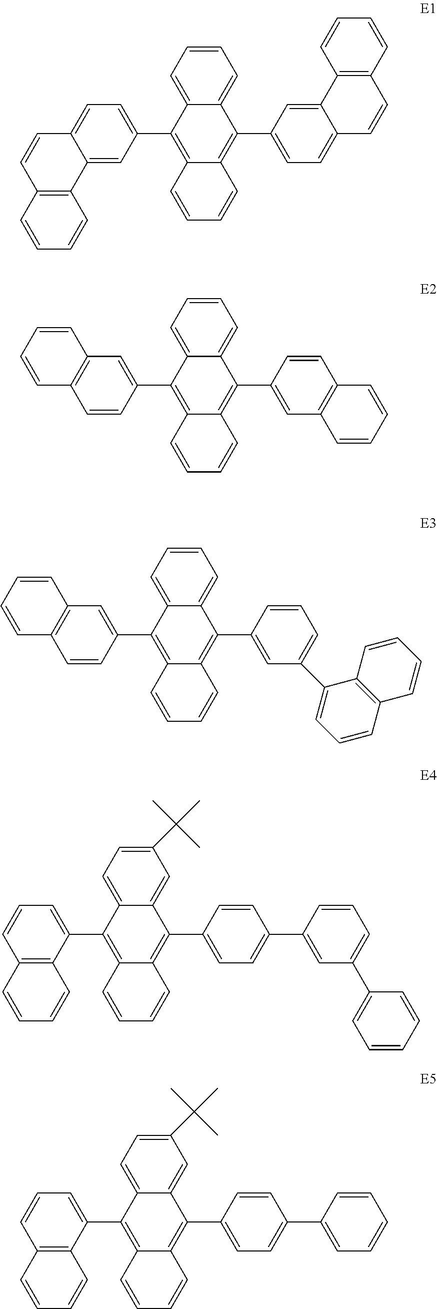

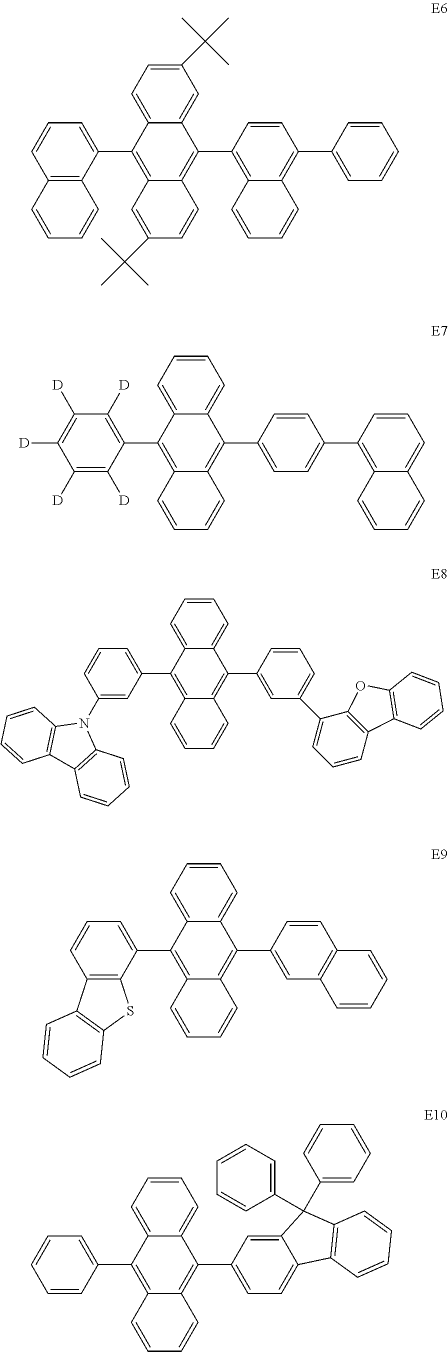

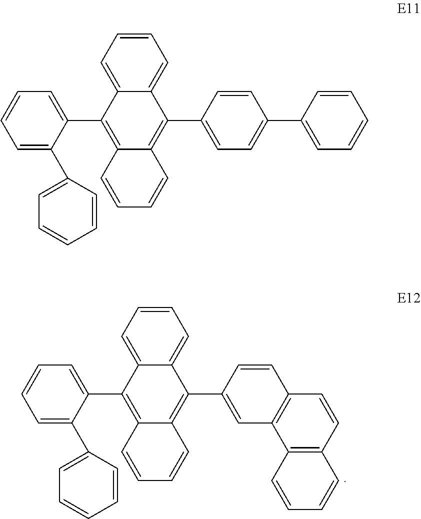

The light-emission layer EML according to one or more embodiments may include a compound represented by Formula EM-2 or Formula EM-3. The compound represented by Formula EM-2 or Formula EM-3 may be used as a phosphorescence host material.

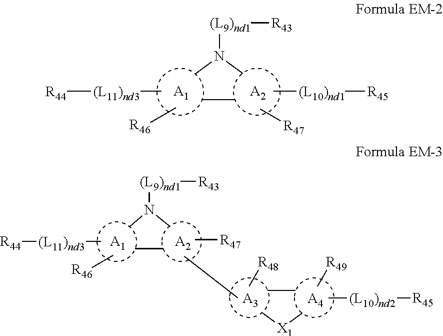

In Formula EM-2 and Formula EM-3, each of rings A₁ through A₄ may independently include, for example, a substituted or unsubstituted aryl group of 6 to 30 ring-forming carbons or a substituted or unsubstituted heteroaryl group of 2 to 30 ring-forming carbons. Non-limiting examples thereof may include a benzene group, a naphthalene group, a phenanthrene group, a fluoranthene group, a triphenylene group, a pyrene group, a pyridine group, a pyrimidine group, an indene group, a fluorene group, a spiro-bifluorene group, a benzofluorene group, a dibenzofluorene group, an indole group, a carbazole group, a benzocarbazole group, a dibenzocarbazole group, a furan group, a benzofuran group, a dibenzofuran group, a benzonaphthofuran group, a benzothiophene group, a dibenzothiophene group, a benzonaphthothiophene group, or a dinaphthothiophene group.

nd₁ through nd₃ may independently be 0 to 2, X₁ may be O, S, N-L₁₂-R₅₀, CR₅₁R₅₂, or SiR₅₃R₅₄, and L₉ through L₁₂ may each independently be a direct linkage, a substituted or unsubstituted arylene group of 6 to 30 ring-forming carbons, or a substituted or unsubstituted heteroarylene group of 2 to 30 ring-forming carbons.

R₄₃ through R₅₄ may each independently be hydrogen, deuterium, a halogen, a substituted or unsubstituted amine group, a substituted or unsubstituted thio group, a substituted or unsubstituted oxy group, a substituted or unsubstituted alkyl group of 1 to 20 carbons, a substituted or unsubstituted alkenyl group of 2 to 20 carbons, a substituted or unsubstituted aryl group of 6 to 30 ring-forming carbons, or substituted or unsubstituted heteroaryl group of 2 to 30 ring-forming carbons.

The host may include at least one of Compound H1 through H24, but embodiments are not limited thereto:

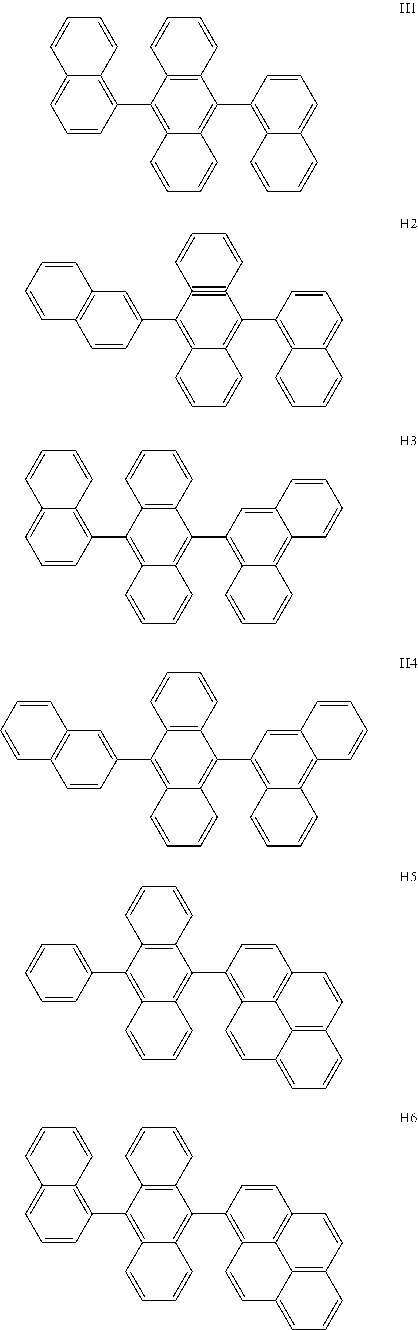

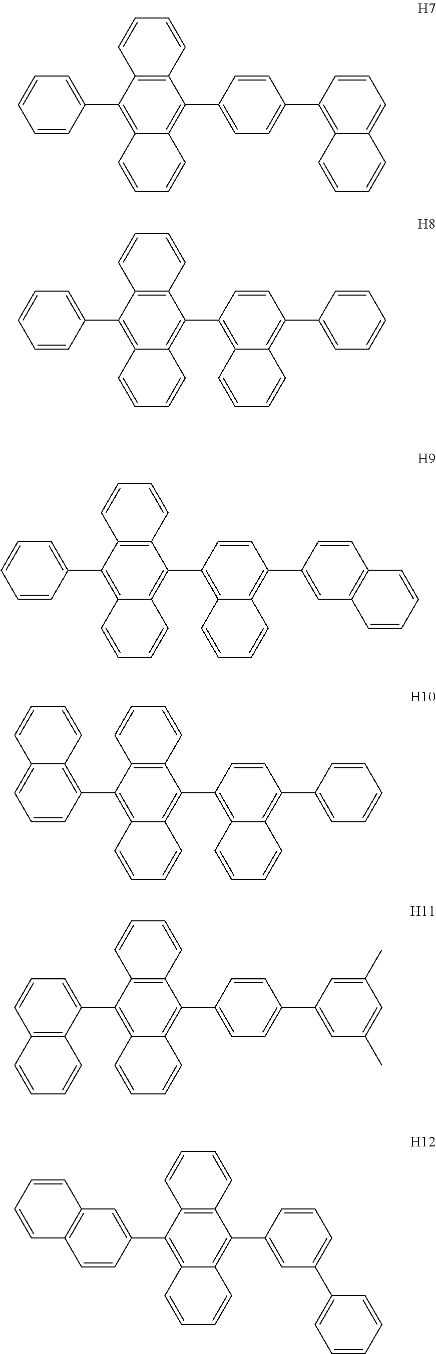

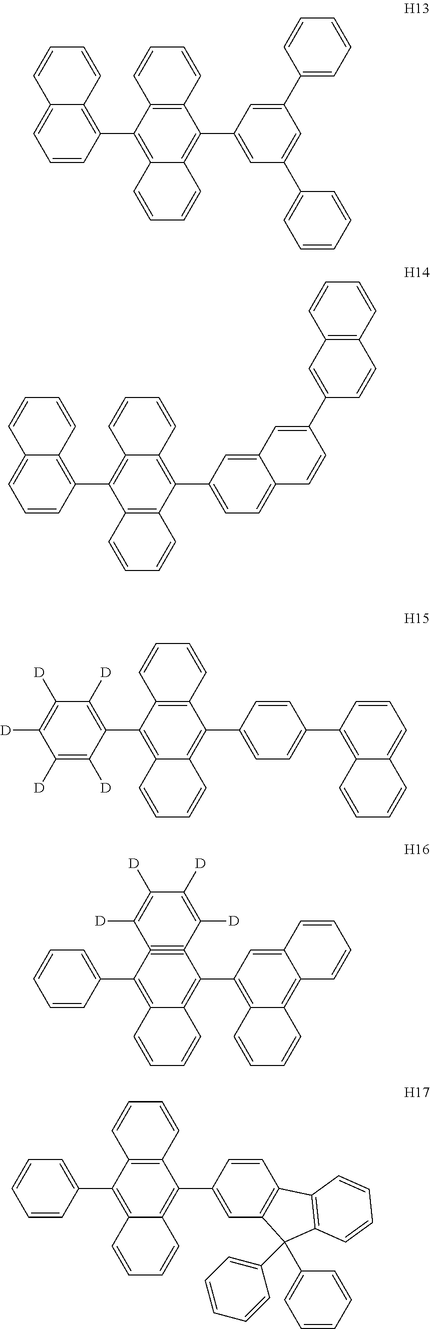

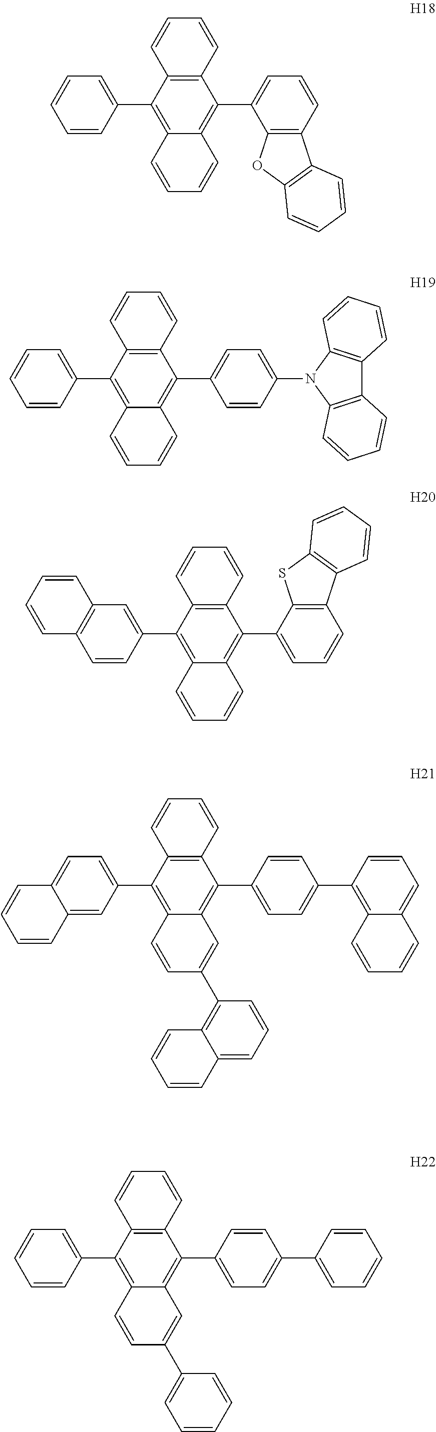

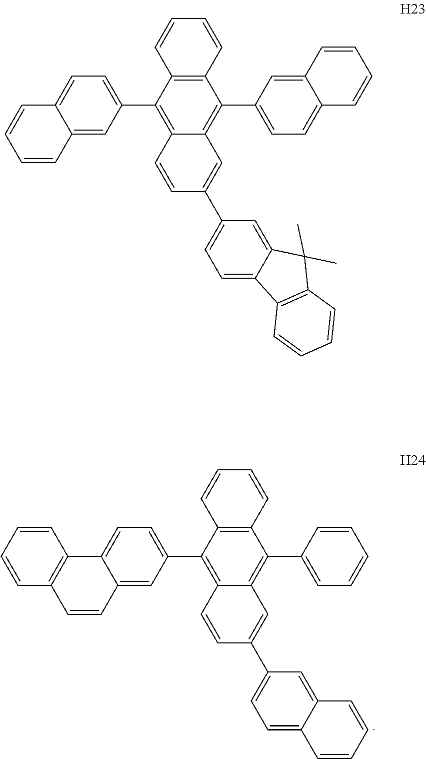

The light-emission layer EML may further include a material ordinarily known in the field as a host material. For example, the light-emission layer EML may include at least one of bis(4-(9H-carbazol-9-yl) phenyl) diphenylsilane (BCPDS), (4-(1-(4-(diphenylamino) phenyl) cyclohexyl) phenyl) diphenyl-phosphine oxide (POPCPA), bis[2-(diphenylphosphino)phenyl] ether oxide (DPEPO), 4,4′-bis(N-carbazolyl)-1,1′-biphenyl (CBP), 1,3-bis(carbazol-9-yl)benzene (mCP), 2,8-bis(diphenylphosphoryl)dibenzo[b,d]furan (PPF), 4,4′4″-tris(N-carbazolyl)triphenylamine (TCTA) or 1,3,5-tris(1-phenyl-1H-benzo[d]imidazole-2-yl)benzene (TPBi). However, embodiments are not limited thereto, and for example, tris(8-hydroxyquinolinato)aluminum (Alq₃), 9,10-di(naphthalene-2-yl)anthracene (ADN), 2-tert-butyl-9,10-di(naphth-2-yl)anthracene (TBADN), distyrylarylene (DSA), 4,4′-bis(9-carbazolyl)-2,2′-dimethylbiphenyl (CDBP), 2-methyl-9,10-bis(naphthalen-2-yl)anthracene (MADN), hexaphenyl cyclotriphosphazene (CP1), 1,4-bis(triphenylsilyl)benzene (UGH2), hexaphenylcyclotrisiloxane (DPSiO₃), or octaphenylcyclotetrasiloxane (DPSiO₄) may be used as a host material.

A host according to one or more embodiments may use an exciplex host, which is a mixed-type host having properties of both electron transport and hole transport in the OLED light-emission layer by combining a hole transport host and an electron transport host. An exciplex host refers to a charge-transfer complex formed in an excited state due to charge transfer of different materials, which is an electron donor and an electron acceptor. The exciplex host may be used as a host of a light-emission layer in an OLED (organic light-emitting diode). The exciplex host maximizes a device efficiency by balancing a hole and an electron to improve charge balance and reduces an electric charge injection barrier to lower a driving voltage. In addition, it may be suitable for thermally activated delayed fluorescence (TADF) and energy transfer with a phosphorescence dopant due to high triplet energy. Although embodiments are not limited thereto, TCTA or CBP may be used as a hole transport host, and (4,6-bis(3,5-di(pyridin-3-yl)phenyl)-2-methylpyrimidine (B3PYMPM) or (4,4′-bis(N-carbazolyl)-1,1′-biphenyl (CBP) as an electron transport host may be combined to manufacture the exciplex host. In addition, an exciplex host by combination of meta-IBI and DBTTrz may be used, but embodiments are not limited thereto.

### Fluorescence Dopant

The light-emission layer EML may include a compound represented by Formula F-a. The compound represented by Formula F-a may be a fluorescence dopant material or a delayed fluorescence material.

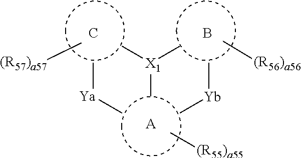

In Formula F-a, the rings A through C may each independently be a substituted or unsubstituted aromatic cyclic hydrocarbon of 6 to 60 ring-forming carbons, or a substituted or unsubstituted aromatic heterocycle of 2 to 60 ring-forming carbons.

The Yₐ and Y_{b} may each independently be O, S, Se, CR₅₈R₅₉, NR₆₀, or SiR₆₁R₆₂.

X₁ may be B, P, or P═O, and in Formula F-a, X₁ may be preferably be boron (B).

The R₅₅ through R₆₂ may be the same or different, and each may be independently a hydrogen atom, a deuterium atom, a substituted or unsubstituted alkyl group of 1 to 30 carbon atoms, a substituted or unsubstituted aryl group of 6 to 60 carbon atoms, a substituted or unsubstituted arylamino group, a substituted or unsubstituted cycloalkyl group of 3 to 30 carbon atoms, a substituted or unsubstituted heteroaryl group of 2 to 60 carbon atoms, a substituted or unsubstituted alkoxy group of 1 to 30 carbon atoms, a substituted or unsubstituted aryloxy group of 6 to 30 carbon atoms, a substituted or unsubstituted arylthiol group of 6 to 30 carbon atoms, a substituted or unsubstituted alkylsilyl group of 1 to 30 carbon atoms, a substituted or unsubstituted arylsilyl group of 5 to 30 carbon atoms, a nitro group, a cyano group, or a halogen group.

The a₅₅ through a₅₇ may each independently be an integer of greater than or equal to 0 and less than or equal to 20.

An organic layer according to one or more embodiments includes a first dopant, which is a fluorescence dopant, and a second dopant, which is a phosphorescence dopant. The first dopant includes a compound represented by Formula 1:

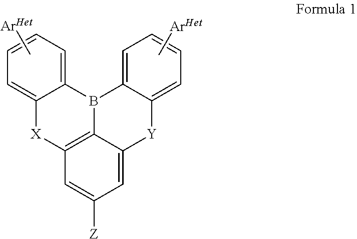

In Formula 1, each Ar^{Het} is hydrogen or a substituted or unsubstituted heteroaryl group of 2 to 60 carbons. Each Ar^{Het} may be identical to or different from the other, provided that at least one of Ar^{Het} is not hydrogen. X and Y are each independently O, S, Se, or NAr¹. Z is hydrogen, deuterium, a halogen, a cyano group, a substituted or unsubstituted silyl group, a substituted or unsubstituted amino group, a substituted or unsubstituted oxy group, a substituted or unsubstituted alkyl group of 1 to 20 carbons, a substituted or unsubstituted aryl group of 6 to 60 ring-forming carbons, or a substituted or unsubstituted heteroaryl group of 2 to 60 ring-forming carbons. Z is optionally bonded to an adjacent group to form a ring. Ar¹ is a substituted or unsubstituted aryl group of 6 to 60 carbons.

In one or more embodiments, the first dopant may be one or more of a compound represented by Formula 3 through Formula 6:

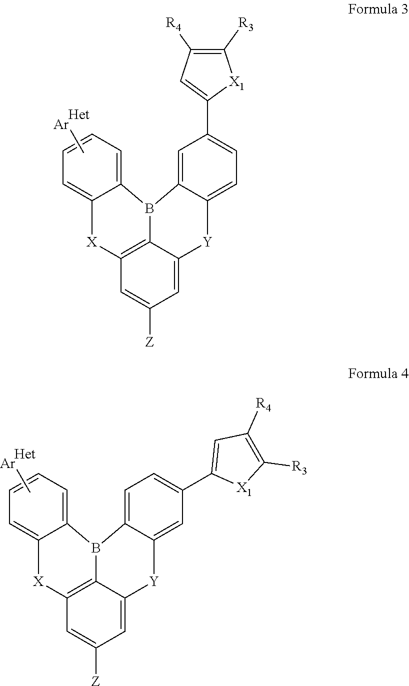

In Formula 3 and Formula 4, X₁ may be N, S, O, or Se; R₃ and R₄ may each independently be hydrogen, a substituted or unsubstituted heteroaryl group of 2 to 30 ring-forming carbons or bonded together to form a ring, and X, Y, and Z may be as defined for Formula 1,

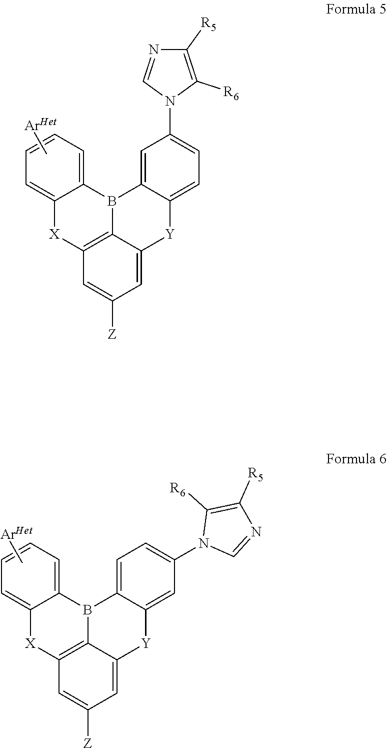

In Formula 5 and Formula 6, R₅ and R₆ may each independently be hydrogen, a substituted or unsubstituted heteroaryl group of 2 to 30 ring-forming carbons or bonded together to form a ring, and X, Y, and Z may be as defined for Formula 1.

In one or more embodiments, the Ar^{Het} may be a group consisting of hydrogen, a pyrrole group, a furan group, a thiophene group, a pyrazole group, an imidazole group, a thiazole group, a triazole group, an oxazole group, an isoxazole group, an indole group, an indazole group, a benzofuran group, a benzothiazole group, an indolizine group, or a pyrrolidine group.

In one or more embodiments of the present disclosure, the compound represented by the Formula 1 may be a compound represented by one or more of Compound 1 through Compound 19:

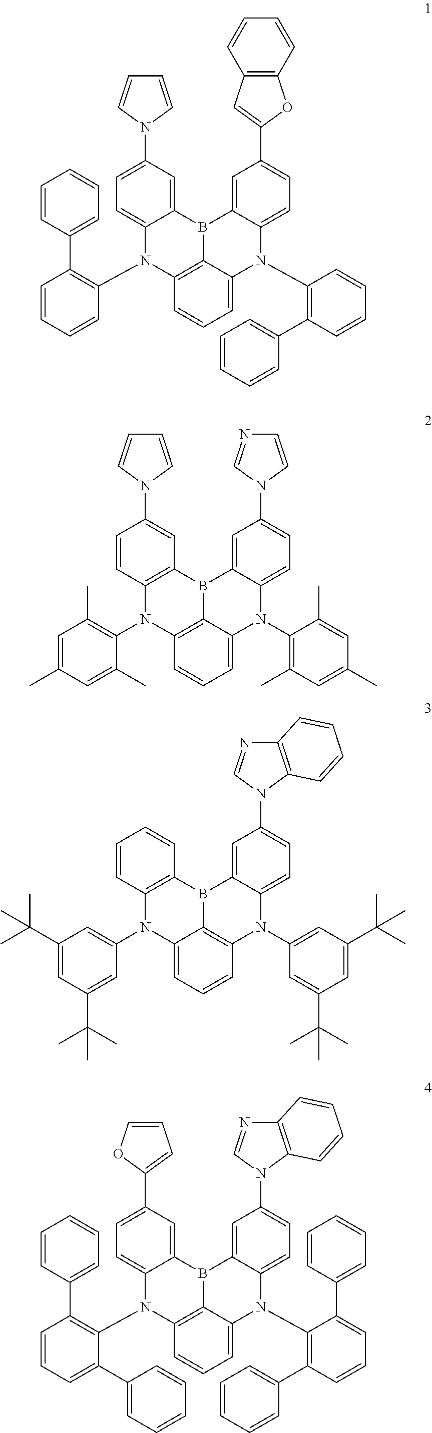

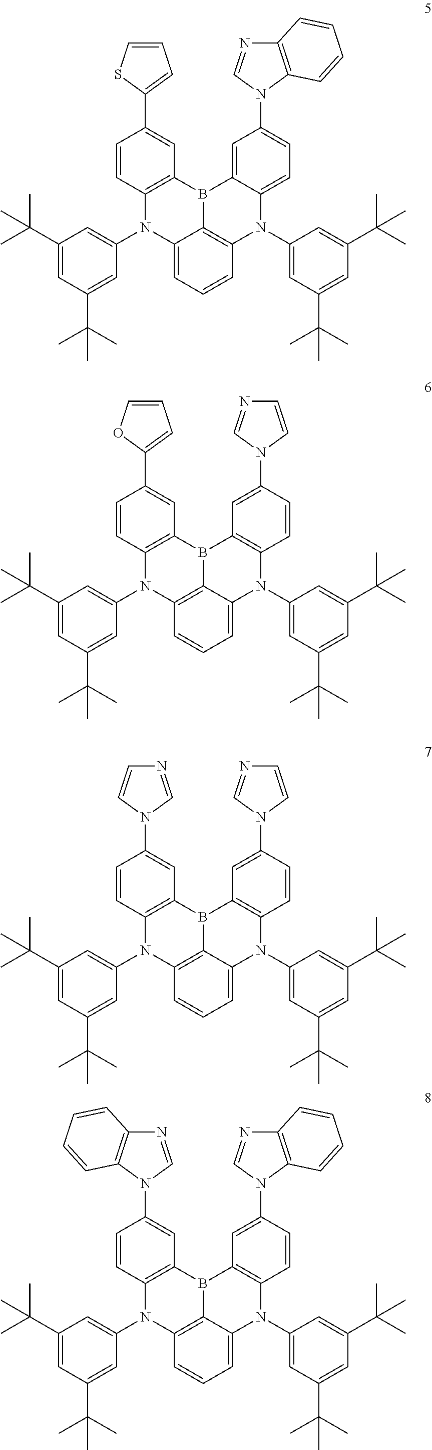

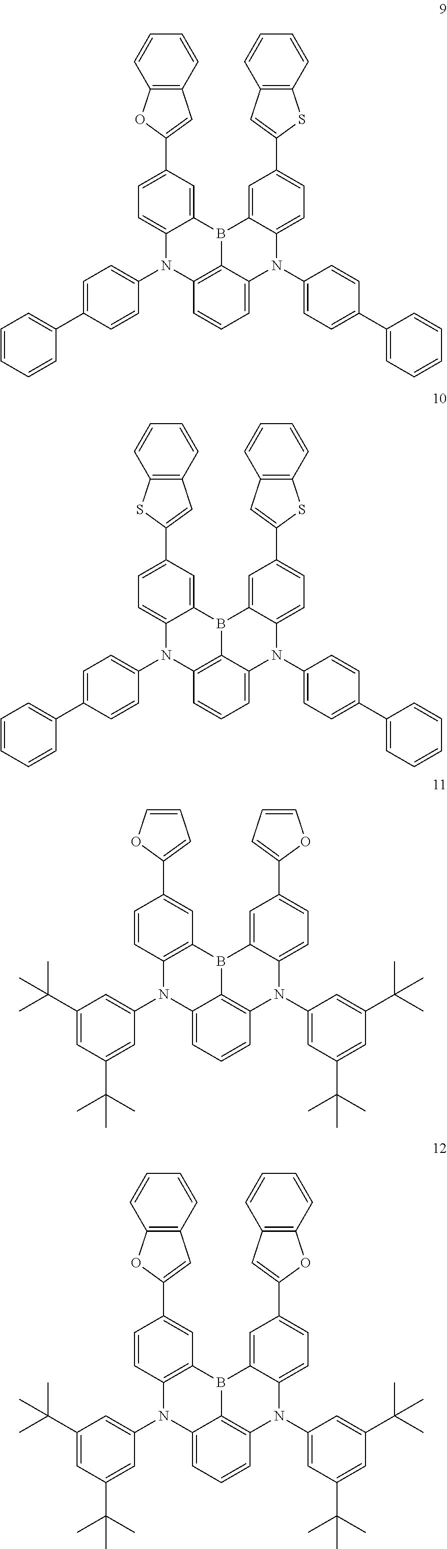

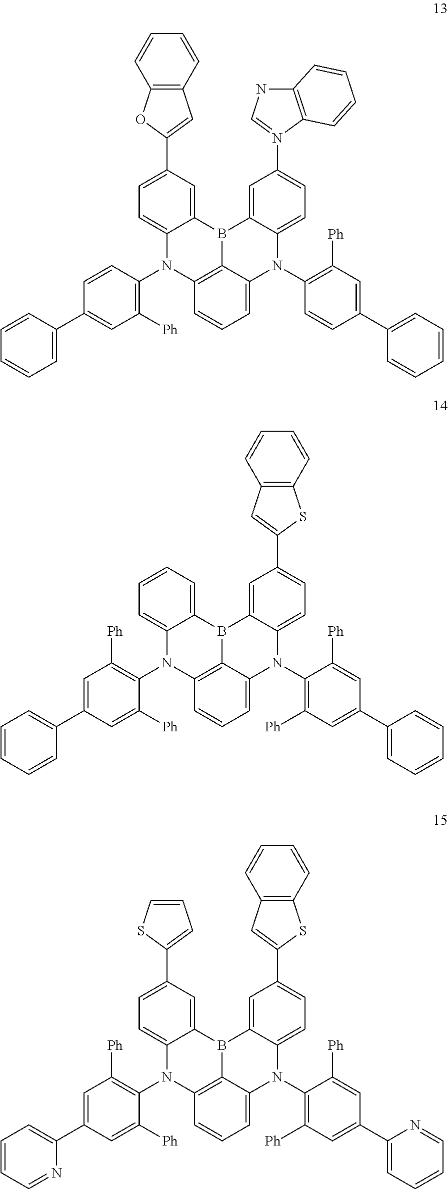

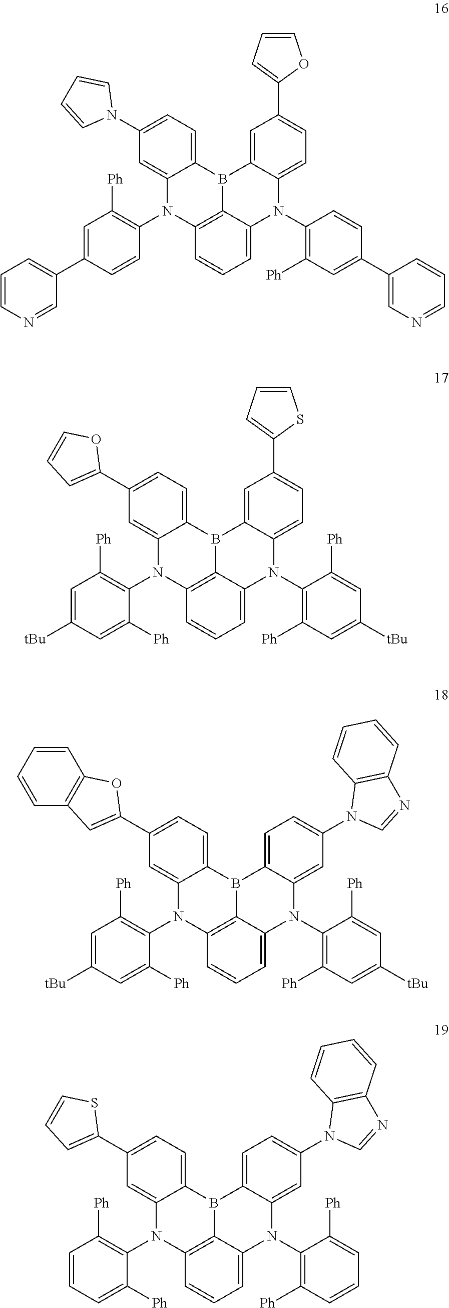

wherein “Ph” is phenyl and “tBu” is tertiary butyl.

### Phosphorescence Dopant

An organic layer according to one or more embodiments may include a compound represented by Formula M-a and Formula M-b below. The compound represented by Formula M-a and/or Formula M-b may be used as a phosphorescence dopant.

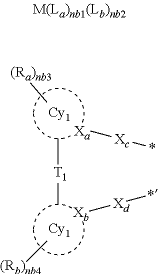

In Formula M-a and Formula M-b, M may be a transition metal (e.g., Iridium (Ir), Platinum (Pt), Gold (Au), Titanium (Ti), Hafnium (Hf), Tantalum (Ta), Tungsten (W), Rhenium (Re), or Osmium (Os)), and La may be a ligand represented by Formula M-b. nb1 may be an integer greater than or equal to 1 and smaller than or equal to 3, and if (e.g., when) nb1 is 2 or greater, 2 or more La(s) may be same or different. Lb may be an organic ligand such as a halogen ligand (e.g. Cl and/or F), a diketone ligand (e.g. acetylacetonate, 1,3-diphenyl-1,3-propanedionate, 2,2,6,6-tetramethyl-3,5-heptanedionate, and/or hexafluoroacetonate), or a carboxylic acid ligand (e.g. picolinate, dimethyl-3-pyrazolcarboxylate, and/or benzoate), but embodiments are not limited thereto.

nb₂ may be an integer of greater than or equal to 0 and less than or equal to 4, and if (e.g., when) nb₂ is 2 or greater, the 2 or more Lb(s) may be same or different.

T₁ may be a direct linkage, *—O—*, *—S—*, *—N(Q₁) *—C(═O)—*, *C(Q₁)-C(Q₂)-*, *—C(Q₁)═*, *—C(Q₁)(Q₂)-*, or *═C(Q₁)-*, each of Xₐ and X_{b} may independently be C or N, each of X_{c} and X_{d} may independently be a chemical linkage (e.g. a coordination bond or a covalent bond), O, S, N(Q₃), B(Q₃), P(Q₃), C(Q₃)(Q₄), or Si(Q₃)(Q₄). Each of ring Cy₁ and ring Cy₂ may independently be a substituted or unsubstituted carbocyclic ring of 3 to 60 carbons or a substituted or unsubstituted heterocyclic ring of 1 to 60 carbons. Each of Rₐ and Rb may independently be hydrogen, deuterium, a halogen atom, a hydroxyl group, a cyano group, a substituted or unsubstituted silyl group, a substituted or unsubstituted thio group, a substituted or unsubstituted oxy group, a substituted or unsubstituted amino group, a substituted or unsubstituted boron group, a substituted or unsubstituted alkyl group of 1 to 20 carbons, a substituted or substituted alkenyl group of 2 to 20 carbons, a substituted or unsubstituted aryl group of 6 to 60 carbons, or a substituted or unsubstituted heteroaryl group of 2 to 60 carbons.

Each of Q₁ to Q₄ may independently be hydrogen, deuterium, a halogen, a hydroxyl group, a cyano group, a nitro group, a substituted or unsubstituted alkyl group of 1 to 30 carbons, a substituted or unsubstituted alkenyl group of 2 to 30 carbons, a substituted or unsubstituted alkynyl group of 2 to 30 carbons, a substituted or unsubstituted alkoxy group of 1 to 30 carbons, a substituted or unsubstituted aryl group of 6 to 60 carbons, or a substituted or unsubstituted heteroaryl group of 2 to 60 carbons. Each of nb₃ and nb₄ may independently be an integer of between 0 and 10, inclusive. In Formula M-b, if (e.g., when) nb₁ is 2 or greater, 2 rings Cy₁ among the 2 or more La(s) may be optionally linked to each other via T₂, which is a linking group, and/or two rings Cy₂ may be optionally linked to each other via T₃, which is a linking group. Descriptions about T₂ and T₃ each refers to descriptions about Ti as described herein. In Formula M-b, each of * and *′ may be a binding site to M of Formula M-a. The compound represented by Formula M-a or Formula M-b may be represented by PS-1 or PS-2, but the present disclosure is not limited thereto.

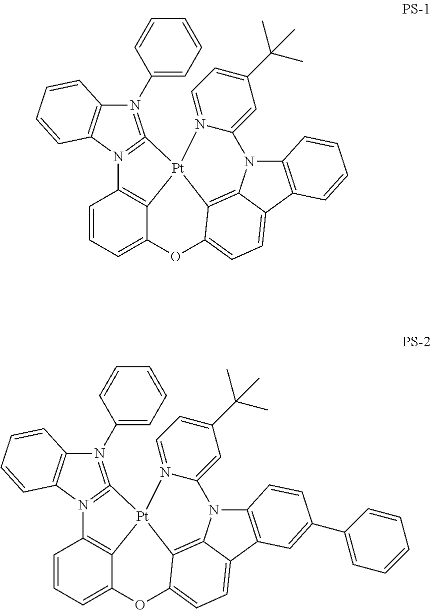

In one or more embodiments of the present disclosure, the organic layer may include a second dopant, which is a phosphorescence dopant, and the second dopant may include one or more species of an organometallic compound represented by Formula 2. Although embodiments are not limited thereto, the organic layer may be a light-emission layer EML.

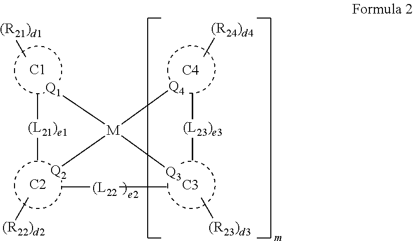

In Formula 2, M may be Pt, Pd, Cu, Os, Ir, Ru, or Rh. Q₁ to Q₄ may each independently be C or N. Ring C₁ to ring C₄ may each independently be a substituted or unsubstituted hydrocarbon ring group of 5 to 30 ring-forming carbons, or a substituted or unsubstituted heteroring group of 2 to 30 ring-forming carbons. R₂₁ to R₂₄ may each independently be hydrogen, deuterium, a halogen, a cyano group, a substituted or unsubstituted silyl group, a substituted or unsubstituted amino group, a substituted or unsubstituted oxy group, a substituted or unsubstituted alkyl group of 1 to 20 carbons, a substituted or unsubstituted aryl group of 6 to 60 ring-forming carbons, or a substituted or unsubstituted heteroaryl group of 2 to 60 ring-forming carbons. R₂₁ to R₂₄ are optionally bonded to an adjacent group to form a ring. d1 through d4 may each independently be an integer of greater than or equal to 0 and less than or equal to 10. L₂₁ to L₂₃ may each independently be a direct linkage, O, or S. e1 through e3 is each independently an integer of greater than or equal to 0 and less than or equal to 5. m may be an integer of greater than or equal to 0 and less than or equal to 3.

The organometallic compound represented by the Formula 2 may be synthesized using known organic synthesis methods. The synthesis method of organometallic compound can be understood by a person ordinarily skilled in the art and with reference to embodiments described herein.

As a light-emitting diode includes an organometallic compound represented by Formula 2 or an organometallic compound including platinum (Pt), it may have improved light-emission efficiency and improved lifespan.

The organometallic compound represented by Formula 2 may be used between a pair of electrodes of a light-emitting diode. For example, an organic layer including a light-emission layer interposed between a first electrode EL1 and a second electrode EL2 may be included, and the organic layer may include an organometallic compound represented by Formula 2.

In one or more embodiments, a light-emitting diode ED may further include a second compound, a third compound, a fourth compound configured to emit delayed fluorescence, or any combination thereof, and the organometallic compound, the second compound, the third compound, and the fourth compound in the light-emitting diode ED may each be different from one another.

A highest occupied molecular orbital (HOMO) energy level of the organometallic compound represented by Formula 2 may be greater than or equal to about −5.30 electron volts (eV) and less than or equal to about −5.10 eV, or greater than or equal to about −5.25 eV and less than or equal to about −5.15 eV.

A lowest unoccupied molecular orbital (LUMO) energy level of the organometallic compound represented by Formula 2 may be greater than or equal to about −2.15 eV and less than or equal to about −1.75 eV, or greater than or equal to about −2.10 eV and less than or equal to about −1.85 eV.

The HOMO and LUMO energy level may be evaluated through cyclic voltammetry analysis for the organometallic compound.

The organometallic compound represented by Formula 2 may be configured to emit a blue light having a maximum light-emission wavelength greater than or equal to about 430 nm and less than or equal to about 480 nm.

In one or more embodiments, the blue light may be a deep blue light.

In another embodiment, the CIEx coordinate of the blue light (e.g., a bottom emission CIEx coordinate) may be greater than or equal to about 0.130 and less than or equal to about 0.140.

In yet another embodiment, the CIEy coordinate of the blue light (e.g., a bottom emission CIEy coordinate) may be greater than or equal to about 0.120 and less than or equal to about 0.200.

The phosphorescence dopant as a sensitizer may be configured to effectively collect an generated exciton and covert it to a light-emitting material, thereby maximizing light-emission efficiency.

In addition, energy may be transferred to a light-emitting material through Forster fluorescence resonance energy transfer (FRET) or Dexter energy transfer mechanism to facilitate energy transfer of the light-emission layer and exciton recombination through the above. Utilizing the above, color purity achieved by the light-emission layer may be improved, and long-term device stability may be maintained.

The light-emission layer EML is included in the organic layer. In one or more embodiments may further include perylene or its derivative (e.g., 2, 5, 8, 11-tetra-t-butylperylene (TBP)), pyrene or its derivative (e.g., 1,1-dipyrene, 1,4-dipyrenylbenzene, and 1,4-bis(N,N-diphenylamino)pyrene), a styryl derivative (e.g., 1,4-bis[2-(3-N-ethylcarbazoryl)vinyl]benzene (BCzVB), 4-(di-p-tolylamino)-4′-[(di-p-tolylamino)styryl]stilbene (DPAVB), or N-(4-((E)-2-(6-((E)-4-(diphenylamino)styryl)naphthalen-2-yl) vinyl)phenyl)-N-phenylbenzenami ne (NBDAVBi)), 4,4′-bis[2-(4-(N,N-diphenylamino)phenyl)vinyl]biphenyl (DPAVBi), or the like as a dopant material.

The light-emission layer EML may further include a known phosphorescence dopant material. For example, a metal complex including iridium (Ir), platinum (Pt), osmium (Os), gold (Au), titanium (Ti), zirconium (Zr), hafnium (Hf), europium (Eu), terbium (Tb), or thulium (Tm) may be used as the phosphorescence dopant. Particularly, iridium(III)bis(4,6-difluorophenylpyridinato-N,C2′)picolinate (FIrpic), bis(2,4-difluorophenylpyridinato)-tetrakis(1-pyrazolyl)borate iridium(III) (Fir6), or platinum octaethyl porphyrin (PtOEP) may be further included as a phosphorescence dopant, but embodiments are not limited thereto.

In one or more embodiments of the present disclosure, the second dopant may include one or more organometallic compounds represented by Formula 7:

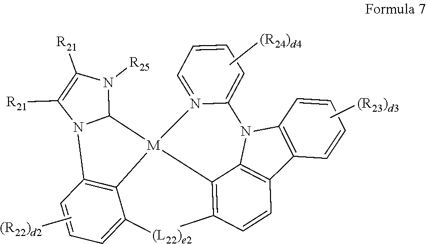

In Formula 7, M may be Pt, Pd, Cu, Os, Ir, Ru, or Rh. R₂₁ to R₂₅ may each independently be hydrogen, deuterium, a halogen, a cyano group, a substituted or unsubstituted silyl group, a substituted or unsubstituted amino group, a substituted or unsubstituted oxy group, a substituted or unsubstituted alkyl group of 1 to 20 carbons, a substituted or unsubstituted aryl group of 6 to 60 ring-forming carbons, or a substituted or unsubstituted heteroaryl group of 2 to 60 ring-forming carbons. R₂₁ to R₂₅ are optionally bonded to an adjacent group to form a ring. d2 through d4 may each independently be an integer of greater than or equal to 0 and less than or equal to 2. L₂₂ may be a direct linkage, O, or S. e2 may be an integer of 1 or 2.

In one or more embodiments, a weight ratio of the first dopant to the second dopant may be about 1:8 to about 1:30. As described above, the first dopant may refer to a fluorescence dopant, and the second dopant may be a phosphorescence dopant functioning as a phosphorescence sensitizer. Although it is not limited thereto, in case that the weight ratio of the first dopant to the second dopant is less than about 1:8, inherent quantum efficiency of the fluorescence dopant (utilizing only 25% of singlet) is limited compared to the phosphorescence dopant (utilizing 100% of triplet). Therefore, as the proportion of the fluorescence dopant increases, overall emission efficiency may decrease. In addition, due to inefficiency in the energy transfer process, light-emission performance may be deteriorated, and uniformity of light-emission spectrum and color purity may be deteriorated, which may negatively affect color reproducibility. In case that the weight ratio of the first dopant to the second dopant is greater than about 1:30, the phosphorescence dopant (functioning as a sensitizer) may emit light and high energy may be released, thereby maintaining accelerated degradation. In addition, spin mixing or quenching may occur during the energy transfer process between the fluorescence dopant and the phosphorescence dopant, thereby leading to a reduction in overall emission efficiency. Furthermore, as Full Width at Half Maximum of light-emission spectrum increases, color purity, color stability, and driving stability of a device may be deteriorated. Accordingly, a ratio of the fluorescence dopant to the phosphorescence dopant may be carefully considered in terms of light-emission efficiency, color purity, and device stability.

In one or more embodiments, the first dopant may have an absorption wavelength of greater than or equal to about 440 nm and less than or equal to about 455 nm, and light-emission wavelength of greater than or equal to about 455 nm and less than or equal to about 480 nm. The absorption wavelength and light-emission wavelength respectively refer to characteristics of a light-emitting device in absorbing and emitting light. These characteristics may vary depending on a bandgap of materials of a light-emitting device and a design of the device.

An absorption wavelength of the first dopant may be important in terms of its relationship with bandgap energy, efficient energy conversion, and minimizing Stokes shift. When the absorption wavelength of the first dopant is optimized to the bandgap, the energy conversion efficiency is increased. A high-efficiency light-emitting device may be designed utilizing the above.

The light-emission wavelength may determine color purity of a light-emitting device, and in case that an emission wavelength of the first dopant is optimized, quantum efficiency may be maximized. This may decrease energy loss of a light-emitting device and contribute to performance improvement.

In the aspect as above, although embodiments are not limited thereto, an absorption wavelength of the first dopant may be greater than or equal to about 420 nm and less than or equal to 460 nm, more suitably greater than or equal to about 440 nm and less than or equal to about 455 nm. In case that the absorption wavelength of the first dopant is outside of the above range of the absorption wavelength, energy transfer efficiency and light-emission efficiency may be deteriorated, and color purity deterioration and light-emission quenching effects may be shown. The light-emission wavelength of the first dopant may be greater than or equal to about 450 nm and less than or equal to about 480 nm, more suitably greater than or equal to about 455 nm and less than or equal to about 475 nm, but embodiments are not limited thereto. In case that the light-emission wavelength of the first dopant is outside of the above range of the light-emission wavelength, color purity deterioration, light-emission efficiency reduction, shortened device lifespan, and light-emission quenching effects may be shown.

In one or more embodiments, the first dopant may have a full width at half maximum (FWHM) less than or equal to about 40 nm. The full width at half maximum may refer to an interval between two wavelengths in a light-emission spectrum corresponding to half of maximum emission intensity. This represents a width of emission spectrum, and the narrower the full width at half maximum, the more emitted light is concentrated at a specific wavelength, allowing implementation of purer color. Although it is not limited thereto, a full width at half maximum of the first dopant may be less than or equal to about 40 nm, preferably less than or equal to about 30 nm.

When a full width at half maximum of the first dopant is less than or equal to about 40 nm, color purity and electric emission efficiency are improved, and interference between signals may be reduced. An optimized full width at half maximum may improve applicability in various fields.

In one or more embodiments, the first dopant and the second dopant may be co-deposited to form an organic layer having a thickness of greater than or equal to about 100 Å and less than or equal to about 500 Å. In case that a thickness of the organic layer including the first dopant and the second dopant according to one or more embodiments is optimized, an electron and a hole may recombine in a balanced manner to increase light-emission efficiency. In addition, by optimizing a thickness of a light-emission layer, heat generation and current density may be lowered to enhance thermal stability of a light-emitting diode and extend its lifespan.

Although embodiments are not limited thereto, in case that thicknesses of the first dopant and the second dopant are less than about 100 Å, recombination may not sufficiently occur, and in case that the thicknesses are greater than about 500 Å, loss of an electron or a hole may occur. In addition, a concentration and recombination site of dopants in the light-emission layer may be optimized to increase color purity of a specific color and improve an injection and transfer efficiency of an electron. Accordingly, a driving voltage may be lowered, and energy efficiency of a light-emitting diode may be improved to implement a high-quality display.

In one or more embodiments, a content of the first dopant may be greater than or equal to about 0.01 parts by weight and less than or equal to about 10 parts by weight per 100 parts by weight of the light-emission layer, and a content of the second dopant may be greater than or equal to about 10 parts by weight and less than or equal to about 20 parts by weight per 100 parts by weight of the light-emission layer. A content of a fluorescence dopant or a phosphorescence dopant may have a significant impact on determining, for example, light-emission efficiency, color purity of an OLED light-emitting diode, and stability of a light-emitting diode. In addition, controlling a content of the first dopant or the second dopant may simultaneously improve electric power efficiency and lifespan of a light-emitting diode by optimizing electric charge balance.

Although it is not limited thereto, in case that a content of the first dopant or the second dopant is less than the above range, an interaction with an exciton may be limited, and light-emission efficiency may deteriorate.

In addition, in case that a content of the first dopant or the second dopant exceeds the above range, concentration quenching phenomenon may occur, causing an exciton to decay into a non-light-emitting state and deterioration of light-emitting efficiency. Particularly, in case that a concentration of a dopant increases, energy is transferred to a nearby dopant due to a proximity between emission centers, and repeated absorption and emission of energy occur. During the process, some energy may be lost, resulting in a decrease in light-emission efficiency. Furthermore, in case that a content of the first dopant or the second dopant exceeds the above range, a light-emission wavelength range may become broad, or light having a different wavelength may be emitted, resulting in deterioration of color purity.

As a result, in case that a content of the first dopant or the second dopant exceeds the above range, color purity of a light-emission layer may be lowered, color deviation may be caused, and electric charge balance may be disrupted, resulting in reduced light-emission efficiency and lifespan of a device. Particularly, in case that a content of the second dopant exceeds the above range, a phosphorescence dopant including a high concentration of rare metals may lead to increased costs of materials, thereby raising costs for manufacturing a light-emitting diode.

In one or more embodiments, the organic light may emit light having a maximum light-emission wavelength of greater than or equal to about 380 nm and less than about 500 nm. Although embodiments are not limited thereto, the maximum light-emission wavelength range may be greater than or equal to about 390 nm and less than or equal to about 500 nm, or greater than or equal to about 400 nm and less than or equal to about 480 nm. The maximum light-emission wavelength range of the organic layer may be a factor in determining the light-emission performance or color quality of a light-emitting diode, such as an OLED. Particularly, a light-emitting diode having a maximum light-emission wavelength as described herein has an advantage of achieving high-efficiency blue light-emission and high-quality white OLEDs. In addition, as deep blue color may be achieved, a high-quality display may be manufactured.

In one or more embodiments, the organic layer may be a deep blue light-emission layer. Although embodiments are not limited thereto, the light-emitting diode may include a light-emission layer configured to emit a deep blue light with a maximum light-emission wavelength of greater than or equal to about 430 nm and less than or equal to about 450 nm.

In one or more embodiments, light-emission quantum efficiency of the light-emission spectrum of the first dopant may be greater than or equal to about 50% and less than or equal to about 100%. The light-emission quantum efficiency may refer to an efficiency indicator representing a ratio at which an electron (or a hole) injected from a light-emitting diode is converted into a photon and may serve as an important criterion for evaluating energy conversion performance of a device. A light-emitting diode having the light-emission layer according to one or more embodiments may be a high-efficiency light-emitting diode through high light-emission quantum efficiency.

### Quantum Dot

A light-emitting diode may be manufactured as a hybrid light-emitting diode by disposing or combining a quantum dot and a light-emitting diode material, such as a phosphorescence dopant and a fluorescence dopant, in a light-emission layer.

The quantum dot may refer to a crystal of a semiconductor compound. A color of light emitted may be controlled depending on a size of the crystal. Accordingly, the quantum dot may exhibit various light-emission colors, such as blue, red, and green.

The diameter of the quantum dot may be, for example, greater than or equal to about 1 nm and less than or equal to about 10 nm.

In addition, a shape of the quantum dot may particularly be spherical, pyramidal, multi-arm, or cubic nanoparticle, or may be provided in the form of a nanotube, a nanowire, a nanofiber, or a nanosheet. However, embodiments are not limited thereto.

The quantum dot may be a Group III-VI compound, a Group II-VI compound, a Group III-V compound, a Group I-III-VI compound, a Group IV-VI compound, a Group IV atom, a Group IV compound, or a combination thereof.

### Electronic Functional Layer EFL

In a light-emitting diode ED according to one or more embodiments illustrated in FIG. 3 through FIG. 6, the electron functional layer EFL may be provided on the light-emission layer EML.

The electron functional layer EFL may include at least one of a hole blocking layer HBL, an electron transport layer ETL, or an electron injection layer EIL, but embodiments are not limited thereto.

The electron functional layer EFL may have a single layer including (e.g., consisting of) a single material, a single layer including (e.g., consisting of) a plurality of different materials, or a multilayer structure having a plurality of layers including (e.g., consisting of) a plurality of different materials.

For example, in one or more embodiments, the electron functional layer EFL may have a single layer structure of an electron injection layer EIL or an electron transport layer ETL, or a single layer structure including (e.g., consisting of) an electron injection material and/or an electron transport material. In one or more embodiments, the electron functional layer EFL may have a single layer structure including (e.g., consisting of) a plurality of different materials, or a structure, in which constituting layers are sequentially stacked from the light-emitting layer EML, of an electron transport layer ETL/electron injection layer EIL, or a hole blocking layer HBL/electron transport layer ETL/electron injection layer EIL, but embodiments are not limited thereto. A thickness of the electron functional layer EFL may be, for example, from about 1000 Å to about 1500 Å.

The electron functional layer EFL may be manufactured by utilizing a method selected from among vacuum deposition, spin coating, Langmuir-Blodgett (LB) casting, ink-jet printing, laser induced thermal imaging (LITI), or the like, but embodiments are not limited thereto.

The electron functional layer EFL may include a compound represented by Formula ET-1:

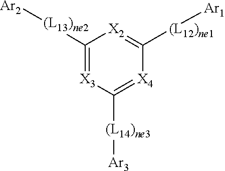

In Formula ET-1, Ar₁ through Ar₃ may each independently be hydrogen, deuterium, a halogen, a substituted or unsubstituted alkyl group having 1 to 20 carbons, a substituted or unsubstituted aryl group having 6 to 60 ring-forming carbons, or a substituted or unsubstituted heteroaryl group having 2 to 60 ring-forming carbons. Non-limiting examples of Ar₁ through Ar₃ may be a phenyl group, a naphthyl group, a biphenyl group, a phenanthrene group, a fluorene group, a spirofluorene group, a terphenyl group, a pyridine group, a carbazole group, or an isoquinoline group.

At least one of X₂ through X₄ may be N, and the rest may be CR_{c}.

R_{c} may be hydrogen, deuterium, a halogen, a substituted or unsubstituted alkyl group having 1 to 20 carbons, a substituted or unsubstituted aryl group having 6 to 30 ring-forming carbons, or a substituted or unsubstituted heteroaryl group having 2 to 30 ring-forming carbons.

In Formula ET-1, ne1 through ne3 may each independently be an integer of greater than or equal to 0 and less than or equal to 5.

In Formula ET-1, L₁₂ through L₁₄ may each independently be a direct linkage, a substituted or unsubstituted arylene group having 6 to 30 ring-forming carbons, or a substituted or unsubstituted heteroarylene group having 2 to 30 ring-forming carbons.

In one or more embodiments, the electron functional layer EFL may include an anthracene-containing compound. However, embodiments are not limited thereto, and the electron functional layer EFL may include, for example, at least one of 2,9-dimethyl-4,7-diphenyl-1,10-phenanthroline (BCP), tris(8-hydroxyquinolinato)aluminum (Alq₃), bis(2-methyl-8-quinolinolato-N1,O8)-(1,1′-biphenyl-4-olato)aluminum (BAlq), 1,3,5-tri[(3-pyridyl)-phen-3-yl]benzene, 2,4,6-tris(3′-(pyridin-3-yl)biphenyl-3-yl)-1,3,5-triazine, 2-(4-(N-phenylbenzimidazol-1-yl)phenyl)-9,10-dinaphthylanthracene, 1,3,5-tri(1-phenyl-1H-benzo[d]imidazol-2-yl)benzene (TPBi), 4,7-diphenyl-1,10-phenanthroline (Bphen), 3-(biphenyl-4-yl)-4-phenyl-5-tert-butylphenyl-1,2,4-triazole (TAZ), 4-(naphthalen-1-yl)-3,5-diphenyl-4H-1,2,4-triazole (NTAZ), 2-(biphenyl-4-yl)-5-(4-tert-butylphenyl)-1,3,4-oxadiazole (tBu-PBD), berylliumbis(benzoquinolin-10-olate) (Bebq2), 9,10-di(naphthalen-2-yl)anthracene (AND), 1,3-bis[3,5-di(pyridin-3-yl)phenyl]benzene (BmPyPhB), or any combination thereof.

The compound represented by Formula ET-1 in the electron functional layer EFL may be represented by, for example, TSPO1 or TPBi, but embodiments are not limited thereto.

In one or more embodiments, the electron functional layer EFL (e.g. the electron transport layer ETL in the electron functional layer EFL) may include a metal-containing material in addition to one or more of the afore-described materials.

For example, the metal-containing material may include a Li complex. The Li complex may include, for example, a compound of ET-D1 (LiQ) or ET-D2:

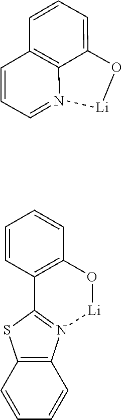

In one or more embodiments, the electron functional layer EFL may include an electron injection layer EIL configured to allow easy injection of an electron from the second electrode EL2. The electron injection layer may make direct contact with the second electrode.

The electron functional layer EFL may have a single layer including (e.g., consisting of) a single material, a single layer including (e.g., consisting of) a plurality of different materials, or a multilayer structure having a plurality of layers including (e.g., consisting of) a plurality of different materials.

The electron functional layer EFL (e.g., electron injection layer EIL) may include an alkaline earth metal, a rare earth metal, an alkali metal, an alkaline earth metal-containing compound, a rare earth metal-containing compound, an alkali metal-containing compound, an alkaline earth metal complex, a rare earth metal complex, an alkali metal complex, or any combination thereof, or further include an organic material (e.g. a compound represented by Formula EM-2 or Formula EM-3).

The alkaline earth metal may include Mg, Ca, Sr, Ba, or any combination thereof.

The rare earth metal may include Sc, Y, Ce, Tb, Yb, Gd, or any combination thereof.

The alkaline metal may include Li, Na, K, Rb, Cs, or any combination thereof.

In one or more embodiments, the electron functional layer EFL may include a halogenated metal, such as LiF, NaCl, CsF, RbCl, RbI, CuI, or KI, a lanthanide metal such as Yb, or a co-deposition material of a halogenated metal and a lanthanide metal. For example, the co-deposition material of a halogenated metal and a lanthanide metal may include KI:Yb, RbI:Yb, and/or LiF:Yb. In one or more embodiments, a metal oxide, such as Li₂O and/or BaO, 8-hydroxyl-Lithium quinolate (LiQ), and/or the like may be used for the electron functional layer EFL, but embodiments are not limited thereto. In one or more embodiments, the electron functional layer EFL may also include a mixture material of an electron transport material and an insulating organo-metal salt. The insulating organo-metal salt may be a material having an energy band gap of about 4 eV or greater. The insulating organo-metal salt may include, for example, a metal acetate, a metal benzoate, a metal acetoacetate, a metal acetylacetonate, and/or a metal stearate.

The electron functional layer EFL may further include at least one of 2,9-dimethyl-4,7-diphenyl-1,10-phenanthroline (BCP), diphenyl(4-(triphenylsilyl)phenyl)phosphine oxide (TSPO1), or 4,7-diphenyl-1,10-phenanthroline (Bphen) in addition to one or more of the afore-described materials, but embodiments are not limited thereto.

Compounds of the electron functional layer EFL may be included in at least one of the electron injection layer EIL, the electron transport layer ETL, or the hole blocking layer HBL in the electron functional layer EFL.

If (e.g., when) the electron functional layer EFL may include an electron transport layer ETL, the electron transport layer ETL may have a thickness of about 100 Å to about 1000 Å, such as about 150 Å to about 500 Å. If (e.g., when) the thickness of the electron transport layer ETL satisfies the range described above, satisfactory level of electron transport properties may be obtained without a substantial increase in a driving voltage. If (e.g., when) the electron functional layer EFL includes an electron injection layer EIL, the electron injection layer EIL may have a thickness of about 1 Å to about 100 Å, such as about 3 Å to about 90 Å. If (e.g., when) the thickness of the electron injection layer EIL satisfies the range described above, satisfactory level of electron injection properties may be obtained without a substantial increase in a driving voltage.

### Second Electrode EL2

The second electrode EL2 may be provided on an electron functional layer EFL. The second electrode EL2 may be a common electrode. The second electrode EL2 may be, but is not limited to, a cathode or an anode. For example, when the first electrode EL1 is an anode, the second electrode EL2 may be a cathode, and when the first electrode EL1 is a cathode, the second electrode EL2 may be an anode. Here, an alloy, a metal, an electrically conductive compound having a low work function, or any combination thereof may be used as a material for the second electrode EL2.

The second electrode EL2 may include lithium (Li), silver (Ag), magnesium (Mg), aluminum (Al), aluminum-lithium (Al—Li), calcium (Ca), magnesium-indium (Mg—In), magnesium-silver (Mg—Ag), ytterbium (Yb), silver-ytterbium (Ag—Yb), ITO, IZO, or any combination thereof. The second electrode EL2 may be a transmissive electrode, a semi-transmissive electrode, or a reflective electrode.

In one or more embodiments, the second electrode EL2 may be connected to an auxiliary electrode. In cases that the second electrode EL2 is connected to the auxiliary electrode, a resistance of the second electrode EL2 may be decreased.

In one or more embodiments, the second electrode EL2 may have a single layer structure of a single layer or a multi-layer structure of a plurality of layers.

### Capping Layer CPL

A first capping layer may be arranged on an outer side of the first electrode EL1, and/or a second capping layer may be arranged on an outer side of the second electrode EL2.

In one or more embodiments, light generated from the light-emitting layer of the light-emitting diode ED may be extracted toward the outside through the first electrode EL1, which is a semi-transmissive electrode or a transmissive electrode, and the first capping layer; in one or more embodiments, light generated from the light-emitting layer of the light-emitting diode ED may be extracted toward the outside through the second electrode EL2, which is a semi-transmissive electrode or a transmissive electrode, and the second capping layer.

In one or more embodiments, the capping layer CPL may independently be an organic capping layer including an organic material, an inorganic capping layer including an inorganic material, or a composite capping layer including an organic material and an inorganic material.

In one or more embodiments, the capping layer CPL may be an organic layer or an inorganic layer. For example, if (e.g., when) the capping layer CPL includes an inorganic material, the inorganic material may include an alkali metal compound, such as LiF, an alkaline earth metal compound, such as MgF₂, SiON, SiNₓ, SiO_{y}, and/or the like.

For example, if (e.g., when) the capping layer CPL includes an organic material, the organic material may include an amine compound, such as a monoamine or a diamine. For example, the organic material may include TPD, α-NPD, β-NPB, m-MTDATA, N4,N4,N4′,N4′-tetra(biphenyl-4-yl)biphenyl-4,4′-diamine (TPD15), or 4,4′4″-tris(N-carbazolyl)triphenylamine (TCTA). However, embodiments are not limited thereto, and the capping layer CPL may include Alq₃, CuPc, an epoxy resin, or an acrylate, such as a methacrylate. However, embodiments are not limited thereto.

In one or more embodiments, the capping layer CPL may have a refractive index of about 1.6 or greater. For example, the refractive index of the capping layer CPL with respect to light in a wavelength range of 550 nm to 660 nm may be about 1.6 or greater, about 1.8 or greater, or about 2.0 or greater.

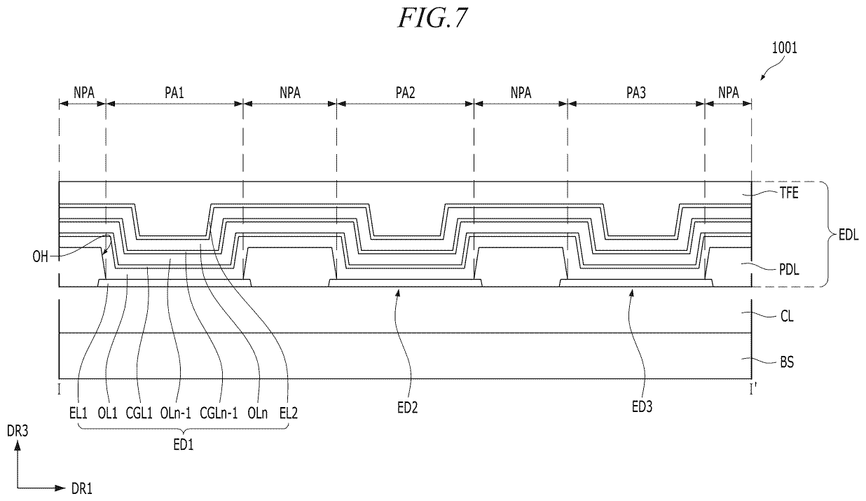

FIG. 7 is a cross-sectional view illustrating a portion of a display device according to one embodiment of the present disclosure.

A display device 1001 will be described with reference to a first light-emitting diode ED1 among a plurality of light-emitting diodes ED1, ED2, and ED3. The first light-emitting diode ED1 may include n light-emitting structures (OL1, . . . , OLn−1, and OLn) laminated between a first electrode EL1 and a second electrode EL2, and n−1 charge generating layers (CGL1, . . . , and CGLn−1). Here, n may be a natural number.

Each of the light-emitting structures OL1, . . . , OLn−1, and OLn may include a hole functional layer HFL and an electron functional layer EFL. Light-emitting layer EML1 (in FIG. 2) may be arranged between the hole functional layer HFL and the electron functional layer EFL. For example, the first light-emitting diode ED1 included in the display device 1001 of one or more embodiments may be a light-emitting diode having a tandem structure including a plurality of light-emission layers.

The charge generation layers CGL1, . . . , and CGLn−1 may be each respectively interposed between neighboring light-emitting structures OL1, . . . , OLn−1, and OLn. The charge generation layers CGL1, . . . , and CGLn−1 may each include a p-type (kind) charge generation layer and/or an n-type (kind) charge generation layer.

FIG. 7 illustrates the display device 1001 including three light-emitting structures OL1, OLn−1, and OLn and two charge generation layers CGL1 and CGLn−1 if (e.g., when) n is 2. However, unlike what is illustrated in FIG. 7, in one or more embodiments, if (e.g., when) n is 1, the n−1-th light-emitting structure OLn−1 and n−1-th charge generation layer CGLn−1 may not be provided, and n-th light-emitting structure OLn may make direct contact with the first charge generation layer CGL1. In addition, unlike what is illustrated in FIG. 7, in one or more embodiments, if (e.g., when) n is 3 or greater, a light-emitting structure and a charge generation layer may be sequentially added between the first charge generation layer CGL1 and n−1-th light-emitting structure OLn−1.

In one or more embodiments, the light-emitting structures OL1, . . . , OLn−1, and OLn included in the first light-emitting diode ED1 may be configured to emit light in substantially the same wavelength range. However, embodiments are not limited thereto, and at least some selected from among the light-emitting structures OL1, . . . , OLn−1, and OLn included in the first light-emitting diode ED1 may be to emit light with a different wavelength from the others.

In one or more embodiments, each of the light-emitting structures OL1, . . . , OLn−1, and OLn may allow each of the light-emitting diodes ED1, ED2, and ED3 including the light-emitting structures OL1, . . . , OLn−1, and OLn, respectively, to emit light in different ranges of wavelength. For example, the first light-emitting structure OL1 included in the first light-emitting diode ED1 and the first light-emitting structure OL1 included in the second light-emitting diode ED2 may be to emit light in different ranges of wavelength. However, embodiments are not limited thereto, for example, each of the light-emitting structures OL1, . . . , OLn−1, and OLn may allow each of the light-emitting diodes ED1, ED2, and ED3 including the light-emitting structures OL1, . . . , OLn−1, and OLn, respectively, to emit light in substantially the same wavelength range.

Although it is illustrated in FIG. 7 that all (e.g., each) of the light-emitting diodes ED1, ED2, and ED3 have the same structure, embodiments are not limited to what is illustrated in the drawing. In one or more embodiments, some of the light-emitting diodes ED1, ED2, and ED3 may include k light-emitting structures (k is a natural number), and the others may include m light-emitting structures (m is a natural number different from k).

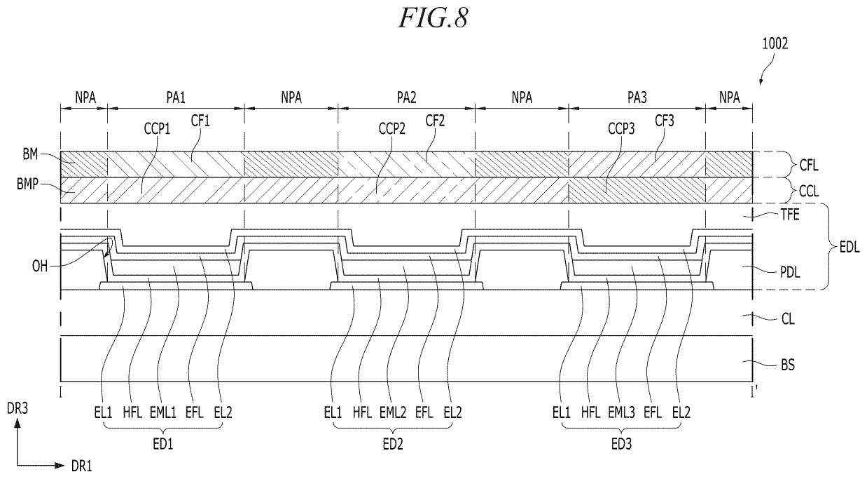

FIG. 8 is a cross-sectional view illustrating a portion of a display device in accordance with one or more embodiments.

A display device 1002 according to one or more embodiments in FIG. 8 will be described based on a difference from the display device 1000 described with reference to FIG. 2. An undescribed configuration follows the descriptions of FIG. 2.

The display device 1002 may include a light controlling layer CCL and a color filter layer CFL arranged on the display device layer EDL.

The light controlling layer CCL may include a plurality of light controlling parts CCP1, CCP2, and CCP3. FIG. 8 illustrates that the light controlling parts CCP1, CCP2, and CCP3 may be separated from one another and a partition pattern BMP may be arranged between the light controlling parts. Nonetheless, embodiments are not limited to what is illustrated in FIG. 8, for example, in one or more embodiments, edges of the light controlling parts may overlap with one another or edges of the light controlling parts may overlap with the partition pattern.

The light controlling layer CCL may include a first through a third light controlling parts CCP1 through CCP3 overlapping with the first through the third light-emitting diodes ED1 through ED3, respectively.

At least one selected from among the first through the third light controlling parts CCP1 through CCP3 may transform a wavelength of incident light (e.g. a blue light) and then emit light of different color (e.g. a red light or a green light). In addition, at least one selected from among the first through the third light controlling parts CCP1 through CCP3 may be configured to transmit incident light (e.g. a blue light) without transforming its wavelength.

In one or more embodiments, at least one selected from among the first through the third light controlling parts CCP1 through CCP3 may include a light converter, such as a quantum dot or a phosphor. The light converter may transform the wavelength of light provided and then emit the transformed (converted) light. The first through the third light controlling parts CCP1 through CCP3 may each further include a scatterer and a base resin configured to disperse the scatterer.

In one or more embodiments, the light controlling layer CCL may further include a barrier layer configured to prevent or reduce penetration of moisture and/or oxygen.

The color filter layer CFL may be arranged on the light controlling layer CCL.

The color filter layer CFL may include a plurality of color filters CF1, CF2, and CF3. FIG. 8 illustrates that the color filters CF1, CF2, and CF3 are spaced and/or apart (e.g., spaced apart or separated) and have a blocking part BM arranged between the color filters. However, embodiments are not limited to what is illustrated in FIG. 8, and in one or more embodiments, edges of the color filters may overlap with one another, and edges of the color filters may overlap with the blocking part.

The color filter layer CFL may include a first through a third color filters CF1 through CF3 overlapping with the first through the third light-emitting diodes ED1 through ED3, respectively.

The first through the third color filters CF1 through CF3 may selectively pass light with a selected color. However, embodiments are not limited thereto, and at least one selected from among the first through the third color filters CF1 through CF3 may be provided as transparent or translucent.

An electronic device according to one or more embodiments may include a light-emitting diode including a first electrode, a second electrode arranged on the first electrode, and one or more organic layers arranged between the first electrode and the second electrode, wherein at least one organic layer among the one or more organic layers includes a first dopant, which is a fluorescence dopant, and a second dopant, which is a phosphorescence dopant, and wherein the first dopant includes a compound represented by Formula 1:

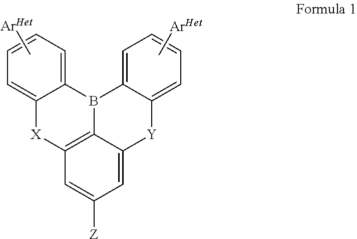

In Formula 1, each Ar^{Het} is independently hydrogen or a substituted or unsubstituted heteroaryl group of 2 to 60 carbons. Each Ar^{Het} is identical to or different from the other, provided that at least one of Ar^{Het} is not hydrogen. X and Y are each independently O, S, Se, or NAr¹. Z is hydrogen, deuterium, a halogen, a cyano group, a substituted or unsubstituted silyl group, a substituted or unsubstituted amino group, a substituted or unsubstituted oxy group, a substituted or unsubstituted alkyl group of 1 to 20 carbons, a substituted or unsubstituted aryl group of 6 to 60 ring-forming carbons, or a substituted or unsubstituted heteroaryl group of 2 to 60 ring-forming carbons. Z is optionally bonded to an adjacent group to form a ring. Ar¹ is a substituted or unsubstituted aryl group of 6 to 60 carbons.

In one or more embodiments, the first dopant may include a compound of one or more among compounds represented by Formula 3 through Formula 6:

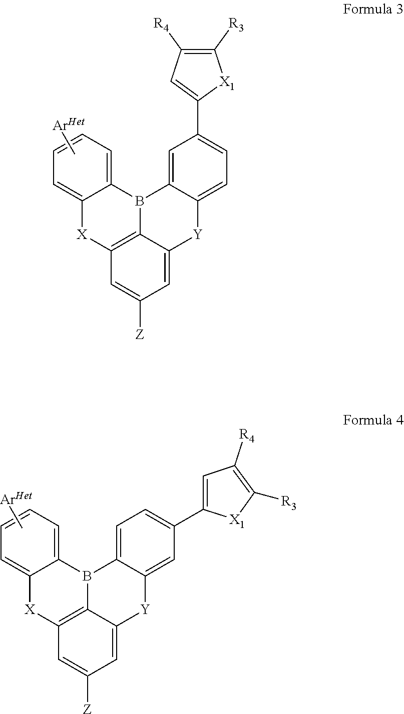

In Formula 3 and Formula 4, X₁ is N, S, O, or Se, R₃ and R₄ may each independently be hydrogen, a substituted or unsubstituted heteroaryl group of 2 to 30 ring-forming carbons or bonded together to form a ring, and X, Y, and Z may be as defined for Formula 1,

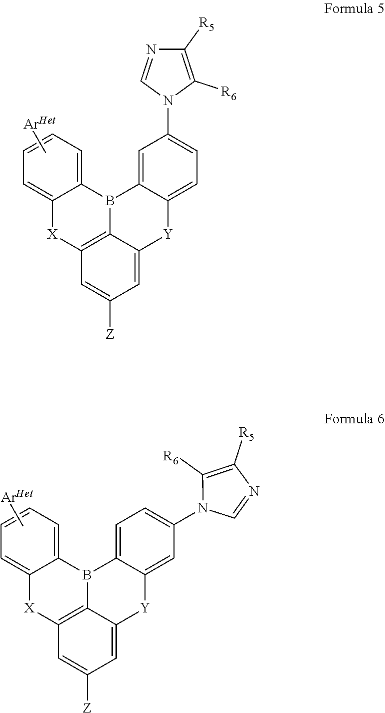

In Formula 5 and Formula 6, R₅ and R₆ may each independently be hydrogen, a substituted or unsubstituted heteroaryl group of 2 to 30 ring-forming carbons or bonded together to form a ring, and X, Y, and Z may be as defined for Formula 1.

In one or more embodiments, the second dopant may include one or more organometallic compounds represented by Formula 7:

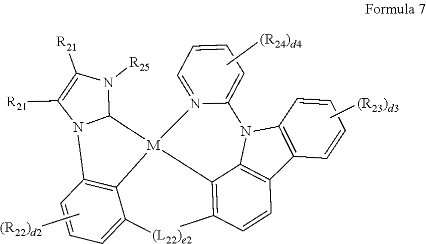

In Formula 7, M may be Pt, Pd, Cu, Os, Ir, Ru, or Rh. R₂₁ to R₂₅ may each independently be hydrogen, deuterium, a halogen, a cyano group, a substituted or unsubstituted silyl group, a substituted or unsubstituted amino group, a substituted or unsubstituted oxy group, a substituted or unsubstituted alkyl group of 1 to 20 carbons, a substituted or unsubstituted aryl group of 6 to 60 ring-forming carbons, or a substituted or unsubstituted heteroaryl group of 2 to 60 ring-forming carbons. R₂₁ to R₂₅ are optionally bonded to an adjacent group to form a ring. d2 through d4 may each independently be an integer of greater than or equal to 0 and less than or equal to 2. L₂₂ may be a direct linkage, O, or S. e2 may be an integer of 1 or 2.

The electronic device according to one or more embodiments may include a display device, a processor configured to control the display device, a memory configured to store data necessary for operation of the display device or the processor, and a power module configured to generate or supply power.

An electronic device according to the above embodiment may be applicable to various electronic devices. An electronic device according to one or more embodiments may include an electronic device described below, and further include a module or a device having an additional function in addition to the electronic device.

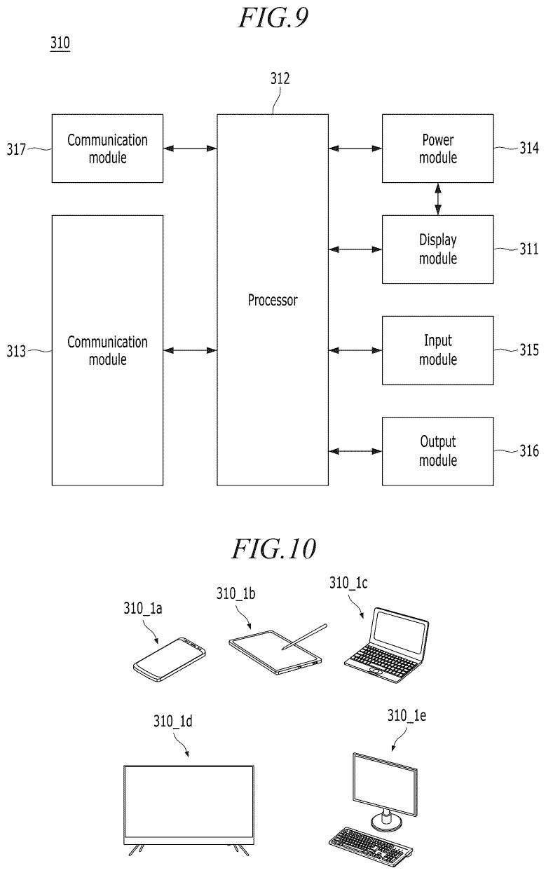

FIG. 9 is a block diagram of an electronic device according to one or more embodiments. Referring to FIG. 9, an electronic device 310 according to one or more embodiments may include a display module 311, a processor 312, a memory 313, and a power module 314. The electronic device 310 may further include an input module 315, an output module 316, and/or a communication module 317.

The electronic device 310 may be configured to output various information in a form of an image through the display module 311. In case that the processor 312 operates an application stored in the memory 313, the application may be configured to provide image information to a user through the display module 311. The power module 314 may include a power supply module, such as a power adaptor or a batter device, and a power conversion module configured to convert power supplied from the power supply module to generate power necessary for operation of the electronic device 310. The input module 315 may provide input information to the processor 312 and/or the power module 311. The output module 316 (or non-image output module) may be configured to receive acoustic, haptic, or light-emission information in addition to image provided from the processor to provide the information to a user. The communication module 317 is a module configured to transmit and receive information between the electronic device 310 and an external device and includes a receiver and a transmitter.

At least one of the above-described components of the electronic device 310 may be included within the electronic device according to the above-described embodiments. Additionally, certain individual modules included functionally within a single module may be provided within the display device while other individual modules may be provided outside the electronic device. For instance, the display device may include the display module 311, and the processor 312, memory 313, and power module 314 may be provided as other devices within the electronic device 310 but not within the display device.

FIG. 10 through FIG. 12 are schematic diagrams of electronic devices according to various embodiments. FIG. 10 through FIG. 12 illustrate examples of various electronic devices applied with electronic devices according to one or more embodiments.

As examples of an electronic device, FIG. 10 illustrates a smartphone 310_1a, a tablet PC 310_1b, a laptop 310_1c, a TV 310_1d, and a desktop monitor 310_1e.

A smartphone 310_1A may include an input module, such as a touch sensor, and a communication module in addition to a display module 311. A smartphone 310_1a may be configured to process information received from the communication module or other input modules to display information through the display module of the electronic device. Similar to the smartphone 310_1a, a tablet PC 310_1b, a laptop 310_1c, a TV 310_1d, a desktop monitor 310_1e may also include a display module and an input module, and in some embodiments, a communication module may be further included.

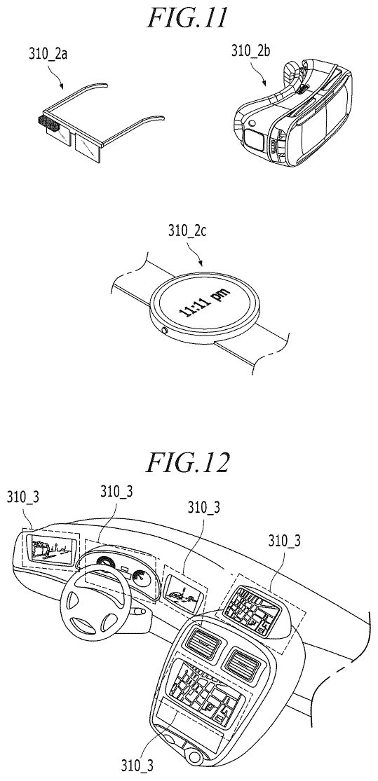

FIG. 11 illustrates an example in which an electronic device including a display module is applied to a wearable electronic device. Examples of a wearable electronic device may be smart glasses 310_2a, a head-mounted display 310_2b, or a smart watch 310_2c.

Smart glasses 310_2a and a head-mounted display 310_2b may include a display module configured to emit a display image and a reflector configured to reflect a display screen towards eyes of a user. Accordingly, an image of virtual reality or augmented reality may be provided to a user.

A smart watch 310_2C may include a biometric sensor as an input device and be configured to provide biometric information recognized through the biometric sensor to a user through a display module.

FIG. 12 illustrates an example in which an electronic device including a display module is applied to a vehicle. For example, an electronic device 310_3 may be applied to, for example, a vehicle instrument panel, center fascia, center information display (CID) arranged on a dashboard of a vehicle, or a room mirror display replacing a side mirror.

An electronic device applicable with an electronic device according to one or more embodiments may include devices mainly for displaying an image and devices displaying information through a display module. In case that a display module allows penetration of light, an electronic device according to one or more embodiments may be applicable to an electronic device, such as a smart window, or a transparent electronic device displaying an image along with a background. For example, an electronic device according to one or more embodiments may be applicable to one or more suitable electronic devices, such as a plane panel display, a curved display, a television, a billboard, a computer monitor, a medical monitor, a head mounted display (HMD), a light for indoor light, an outdoor light or signal light, a wearable device, a foldable device, a rollable device, a bendable device, a flexible device, a curved device, an electronic organizer, an electronic book, a portable multimedia player (PMP), a personal digital assistance (PDA), a laser printer, a telephone, a portable phone, a tablet PC, a portable terminal, a laptop computer, a digital camera, a viewfinder, a camcorder, a 3D display, a virtual reality display, an augmented reality display, a video wall including multiple displays tiled together, a vehicle, an outdoor electronic device, a theater screen, a stadium screen, a billboard, a screen, a signboard, and a game console, and various home appliances displaying information through a display module, such as a refrigerator, a washing machine, a dryer, an air conditioner, or a robot vacuum cleaner. However, types of an electronic device according to one or more embodiments are not limited to the above examples, and an electronic device according to one or more embodiments may be applicable to various undescribed electronic devices.

A composition for producing a light-emitting diode according to one or more embodiments may include a first dopant, which is a fluorescence dopant, represented by Formula 1, and a second dopant, which is a phosphorescence dopant, represented by Formula 2:

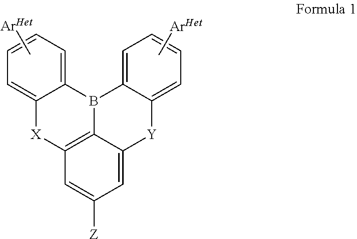

In Formula 1, each Ar^{Het} is hydrogen or a substituted or unsubstituted heteroaryl group of 2 to 60 carbons. Each Ar^{Het} may be identical to or different from the other, provided that at least one of Ar^{Het} is not hydrogen. X and Y are each independently be O, S, Se, or NAr¹. Z is hydrogen, deuterium, a halogen, a cyano group, a substituted or unsubstituted silyl group, a substituted or unsubstituted amino group, a substituted or unsubstituted oxy group, a substituted or unsubstituted alkyl group of 1 to 20 carbons, a substituted or unsubstituted aryl group of 6 to 60 ring-forming carbons, or a substituted or unsubstituted heteroaryl group of 2 to 60 ring-forming carbons. Z is optionally bonded to an adjacent group to form a ring. Ar¹ is a substituted or unsubstituted aryl group of 6 to 60 carbons.

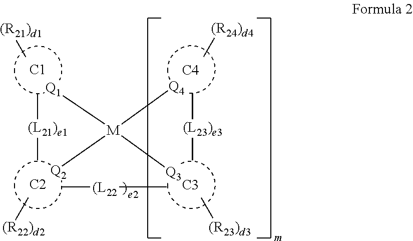

In Formula 2, M may be Pt, Pd, Cu, Os, Ir, Ru, or Rh. Q₁ to Q₄ may each independently be C or N. Ring C₁ to ring C₄ may each independently be a substituted or unsubstituted hydrocarbon ring group of 5 to 30 ring-forming carbons, or a substituted or unsubstituted heteroring group of 2 to 30 ring-forming carbons. R₂₁ to R₂₄ may each independently be hydrogen, deuterium, a halogen, a cyano group, a substituted or unsubstituted silyl group, a substituted or unsubstituted amino group, a substituted or unsubstituted oxy group, a substituted or unsubstituted alkyl group of 1 to 20 carbons, a substituted or unsubstituted aryl group of 6 to 60 ring-forming carbons, or a substituted or unsubstituted heteroaryl group of 2 to 60 ring-forming carbons. R₂₁ to R₂₄ are optionally bonded to an adjacent group to form a ring. d1 through d4 may each independently be an integer of greater than or equal to 0 and less than or equal to 10. L₂₁ to L₂₃ may each independently be a direct linkage, O, or S. e1 through e3 may be an integer of greater than or equal to 0 and less than or equal to 5. m may be an integer of greater than or equal to 0 and less than or equal to 3.

According to one or more embodiments, the first dopant may be a compound represented by one or more of Formula 3 through Formula 6:

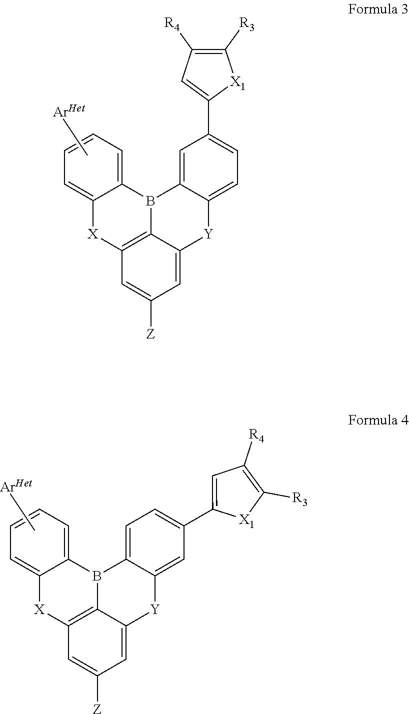

In Formula 3 and Formula 4, X₁ may be N, S, O, or Se. R₃ and R₄ may each independently be hydrogen, a substituted or unsubstituted heteroaryl group of 2 to 30 ring-forming carbons or bonded together to form a ring. X, Y, and Z may be as defined for Formula 1,

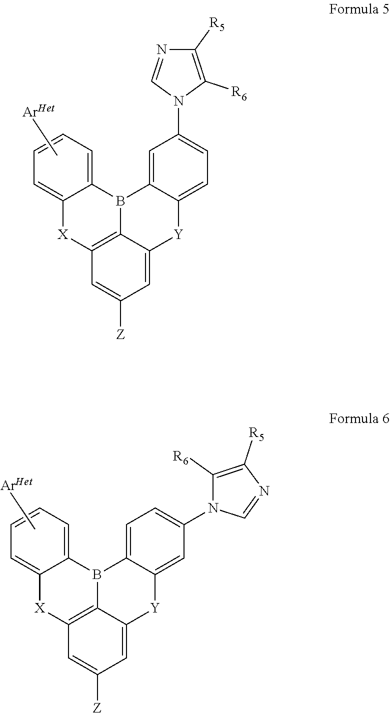

In Formula 5 and Formula 6, R₅ and R₆ may each independently be hydrogen, a substituted or unsubstituted heteroaryl group of 2 to 30 ring-forming carbons or bonded together to form a ring. X, Y, and Z may be as defined for Formula 1.

In one or more embodiments, the second dopant may be a compound of one or more species among compounds represented by Formula 7:

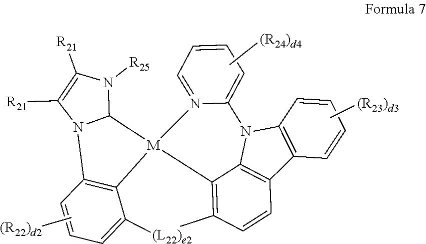

In Formula 7, M may be Pt, Pd, Cu, Os, Ir, Ru, or Rh. R₂₁ to R₂₅ may each independently be hydrogen, deuterium, a halogen, a cyano group, a substituted or unsubstituted silyl group, a substituted or unsubstituted amino group, a substituted or unsubstituted oxy group, a substituted or unsubstituted alkyl group of 1 to 20 carbons, a substituted or unsubstituted aryl group of 6 to 60 ring-forming carbons, or a substituted or unsubstituted heteroaryl group of 2 to 60 ring-forming carbons. R₂₁ to R₂₅ are optionally bonded to an adjacent group to form a ring. d2 through d4 may each independently be an integer of greater than or equal to 0 and less than or equal to 2. L₂₂ may be a direct linkage, O, or S. e2 may be an integer of 1 or 2.

In one or more embodiments, the first dopant may have an absorption wavelength of about 440 nm to about 455 nm, a light-emission wavelength of about 455 nm to about 480 nm, and a full width at half maximum (FWHM) less than or equal to about 40 nm.

Hereinafter, exemplary embodiments and comparative examples are described. A light-emitting diode according to one or more embodiments will be described in further detail. In addition, the following embodiments are merely for understanding of the present disclosure, and a scope of the present disclosure is not limited thereto.

### EXAMPLES

### Experimental Example

### Synthesis Example

Synthesis methods of Compound 1, Compound 3, Compound 7, Compound 12, Compound 14, and Compound 18 among compounds according to one or more embodiments of the present disclosure are described.

### Synthesis Example 1. Synthesis of Compound 1

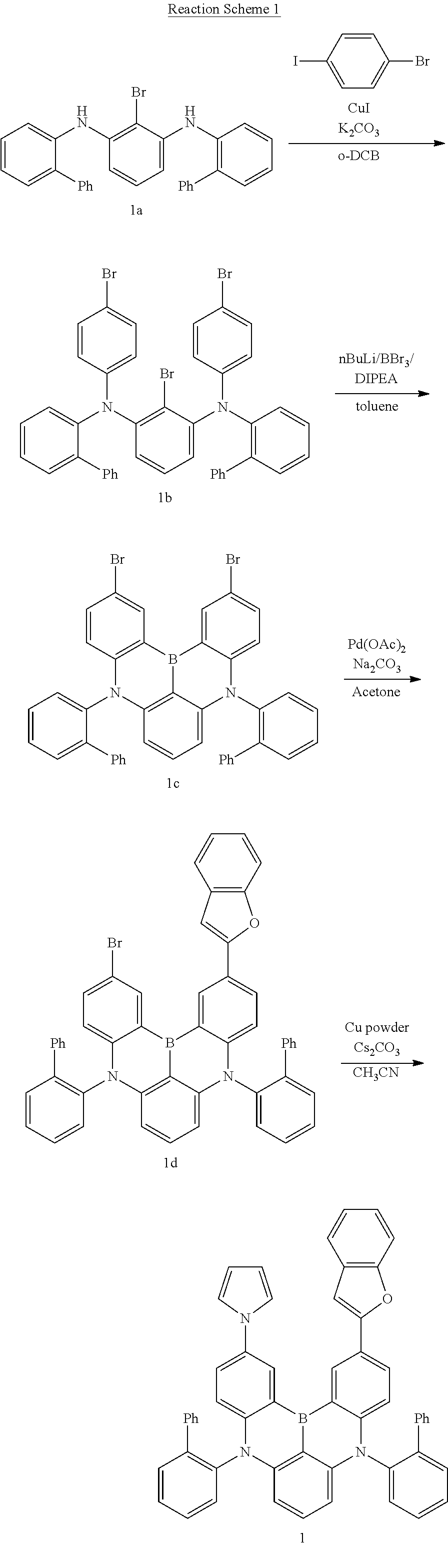

Compound 1a (0.9 grams (g), 1.83 millimoles (mmol)), 4-iodo-1-bromobenzene (2.59 g, 9.1 mmol), CuI (0.17 g, 0.9 mmol), and K₂CO₃ (0.76 g, 5.5 mmol) were added in o-dichlorobenzene (1 milliliter (mL)), and the mixture was stirred at a temperature of 200 °C for 48 hours. After cooling the reaction mixture to a room temperature, an organic solvent was concentrated under a vacuum environment, and the remaining solid was purified through column chromatography (eluents: hexane/dichloromethane) using silica gel to obtain Compound 1b. (Yield: 1.2 g, 82%)

A toluene solution (20 mL) of the compound 1b (1.4 g, 1.75 mmol) was cooled to a temperature of −78 °C, and n-butyl lithium (n-BuLi) (1.1 equivalents) was added. The reaction mixture was slowly heated to a room temperature and stirred for 3 hours. After the stirring, the reaction mixture was cooled to a temperature of −30 °C. Boron tribromide (BBr₃, 0.5 mL, 5.25 mmol) was added to the reaction mixture, and the mixture was heated to a temperature of 50 °C and stirred overnight. After cooling the reaction flask to 0 °C, N,N-diisopropylethylamine (DIPEA, 3 equivalents) was added, and the resulting mixture was heated to a temperature of 110 °C and stirred for 3 hours. After cooling to a room temperature, the contents were diluted with a dichloromethane solvent and filtered through a Celite filter, and the solution was concentrated and purified through column chromatography to obtain Compound 1c as a yellow solid. (Yield: 0.4 g, 32%)

A mixture of Compound 1c (1.34 g, 1.84 mmol), benzofuran-2-yl boronic acid (0.2 g, 1.23 mmol), palladium(II) acetate (Pd(OAc)₂) (0.01 g, 0.037 mmol), and Na₂CO₃ (0.26 g, 2.46 mmol) was dissolved in acetone (30.0 mL) and stirred overnight at 70 °C under a nitrogen atmosphere. After cooling the reaction mixture to a room temperature, it was filtered through a Celite filter and concentrated under a reduced pressure, and the resulting residue was purified through silica gel column chromatography to obtain Compound 1d. (Yield: 0.58 g, 61%)

A mixture of Compound 1d (0.72 g, 0.93 mmol), 1H-pyrrole (0.093 g, 1.40 mmol), copper powder (0.01 g, 0.18 mmol), and Cs₂CO₃ (0.60 g, 1.86 mmol) were dissolved in CH₃CN (30.0 mL) and stirred overnight at 80 °C under a nitrogen atmosphere. After cooling the reaction mixture to a room temperature, it was filtered through a Celite filter. After concentrating the resulting solution under a reduced pressure, the resulting solution was purified through silica gel column chromatography to obtain Compound 1 as a final product. (Yield: 0.36 g, 52%)

The produced compound was confirmed through mass spectrometry using fast atom bombardment (MS/FAB).

C₅₄H₃₆BN₃O cal. 753.30, found 753.31.

### Synthesis Example 2. Synthesis of Compound 3

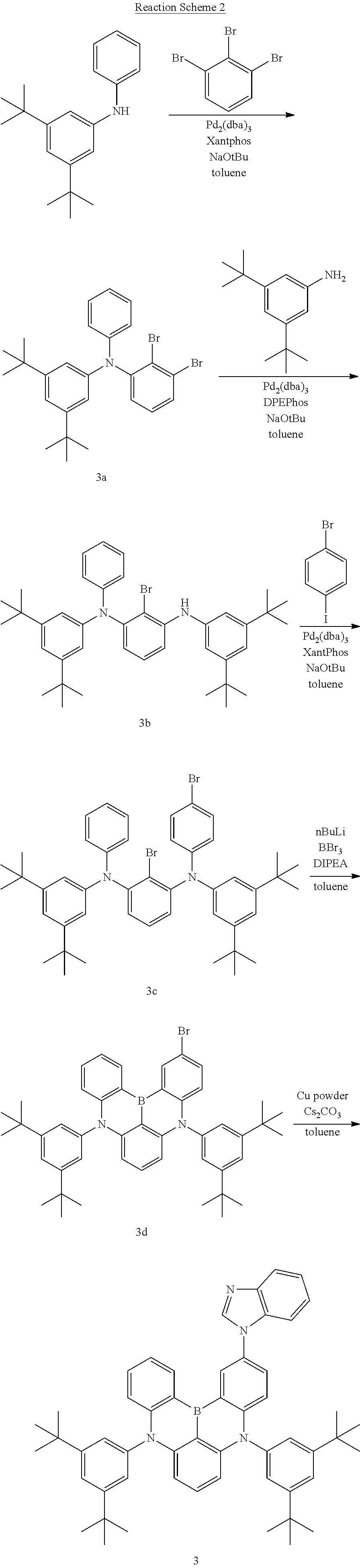

1,2,3-tribromobenzene (3.08 g, 9.77 mmol), 3,5-di-tert-butyl-N-phenylaniline (2.5 g, 8.88 mmol), tris(dibenzylideneacetone)dipalladium(0) (Pd₂(dba)₃) (262 mg, 0.286 mmol), 9,9-dimethyl-4,5-bis(diphenylphosphino) xanthene (Xantphos) (163 mg, 0.178 mmol), and sodium tert-butoxide (NaOtBu) (1.28 g, 13.3 mmol) were added in a 100 mL round-bottom Schlenk flask, and dried toluene (25 mL) was added under a nitrogen atmosphere. The mixture was stirred at 110 °C overnight. The reaction mixture was cooled to a room temperature, filtered through a Celite filter, and washed with dichloromethane. The resulting solution was concentrated under a reduced pressure, and the residue materials were purified through silica gel column chromatography with hexane/dichloromethane solvent to obtain Compound 3a. (Yield: 3.2 g (6.21 mmol), 70%).

Compound 3a (3.7 g, 7.18 mmol), 3,5-di-tert-butylaniline (1.47 g, 7.18 mmol), Pd₂(dba)₃ (131 mg, 0.144 mmol), bis(2-diphenylphosphinophenyl)ether (DPEPhos) (155 mg, 0.072 mmol), and NaOtBu (1.04 g, 10.8 mmol) were added in a 100 mL round-bottom Schlenk flask, and dried toluene (30 mL) was added under a nitrogen atmosphere. The mixture was stirred overnight at 90 °C. The reaction mixture was cooled to a room temperature, filtered through a Celite filter, and washed with dichloromethane. The resulting solution was concentrated under a reduced pressure, and the residue materials were purified through silica gel column chromatography using hexane/dichloromethane to obtain Compound 3b. (Yield: 3.83 g (5.99 mmol), 83%).

Compound 3b (3.8 g, 5.99 mmol), 1-bromo-4-iodobenzene (2.54 g, 8.99 mmol), and NaOtBu (864 mg, 8.99 mmol) were added in a 100 mL round-bottom Schlenk flask, and dried toluene (30 mL) was added under nitrogen atmosphere. A mixed solution of Pd₂(dba)₃ (108 mg, 0.120 mmol) and Xantphos (139 mg, 0.240 mmol) was added to the mixture. The mixture was stirred overnight at 110 °C. The reaction mixture was cooled to a room temperature, filtered through a Celite filter, and washed with dichloromethane. The resulting solution was concentrated under a reduced pressure, and the residue materials were purified through silica gel column chromatography with a hexane/dichloromethane solvent to obtain Compound 3c. (Yield: 4.1 g (5.16 mmol), 87%).

An n-BuLi pentane solution (2.47 mL, 6.19 mmol) was slowly added to a solution of Compound 3c (4.1 g, 5.16 mmol) dissolved in toluene (45 mL) at −78 °C under a nitrogen atmosphere. The reaction mixture was slowly heated and stirred for 3 hours, and pentane was removed under a reduced pressure. Boron tribromide (BBr₃, 1.47 mL, 15.5 mmol) was slowly added dropwise at −30 °C, and the resulting mixture was stirred at 50 °C overnight. N,N-diisopropylethylamine (DIPEA, 4.5 mL, 25.8 mmol) was added at 0 °C, and the reaction mixture was stirred at 120 °C for 3 hours. After cooling it to a room temperature, an aqueous solution of sodium acetate (NaOAc) was added, and the mixture was extracted with ethyl acetate. A separated organic layer was dried with MgSO₄, filtered, and washed several times with toluene. The mixture was concentrated under a reduced pressure and filtered through silica gel column (solvents: dichloromethane/hexane) to obtain Compound 3d as a yellow solid. (Yield: 1.6 g, 40%).

Compound 3d (578 mg, 0.8 mmol) and 1H-benzo[d]imidazole (0.14 g, 1.2 mmol) were dissolved in toluene (30 mL), and copper powder (0.012 g, 0.02 mmol), and Cs₂CO₃ (0.52 g, 1.6 mmol) were added under a nitrogen atmosphere. Subsequently, the reaction mixture was stirred at 110 °C for 8 hours. After cooling it to a room temperature, an organic solvent was concentrated under a vacuum environment, and residual solid was purified through silica flash column chromatography to obtain a final product of Compound 3 as a yellow solid. (Yield: 0.30 g, 50%).

The produced compound was confirmed through MS/FAB.

C₅₃H₅₇BN₄ cal. 760.47, found 760.47.

### Synthesis Example 3. Synthesis of Compound 7

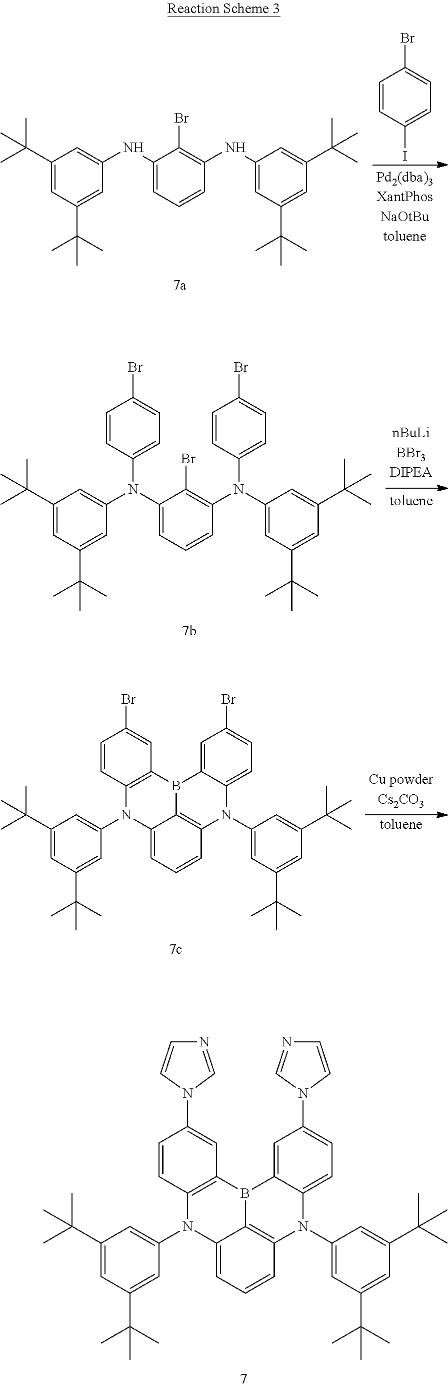

Compound 7a (1.75 g, 3.10 mmol), 1-bromo-4-iodobenzene (2.19 g, 7.75 mmol), and NaOtBu (894 mg, 9.3 mmol) were added to a 100 mL round-bottom Schlenk flask, and dried toluene (30 mL) was added under a nitrogen atmosphere. A mixed solution of Pd₂(dba)₃ (112 mg, 0.124 mmol) and Xantphos (140 mg, 0.248 mmol) was added to the above mixture. The mixture was stirred overnight at 90 °C. The reaction mixture was cooled to a room temperature, filtered through a Celite filter and washed with dichloromethane. The resulting mixture as concentrated under a reduced pressure, and the remaining materials were purified through silica gel column chromatography with a hexane/dichloromethane solvent mixture to obtain Compound 7b. (Yield: 2.57 g (2.24 mmol), 83%).

An n-BuLi pentane solution (1 mL, 2.5 mmol) was slowly added to a solution of Compound 7b (2.0 g, 2.29 mmol) dissolved in toluene (30 mL) at −78 °C under a nitrogen atmosphere. After heating it slowly to room temperature and stirring for 3 hours, pentane was removed under a reduced pressure. Boron tribromide (BBr₃, 0.65 mL, 6.9 mmol) was slowly added dropwise at −30 °C, and the mixture was stirred overnight at 50 °C. DIPEA (2.0 mL, 11.5 mmol) was added at 0 °C, and the reaction mixture was stirred for 2 hours at 120 °C. After cooling it to a room temperature, and the reaction was completed. Residual materials obtained after work-up were separated through a silica gel column to obtain Compound 7c as a yellow solid. (Yield: 0.88 g, 48%).

Compound 7c (640 mg, 0.80 mmol) and 1H-imidazole (80 mg, 1.2 mmol) were dissolved in toluene (30 mL), and copper powder (0.012 g, 0.02 mmol), and Cs₂CO₃ (0.52 g, 1.6 mmol) were added under nitrogen atmosphere. Resulting materials after stirring at 110 °C for 8 hours were cooled to a room temperature, and work-up was performed. The residual solid was purified through silica column chromatography to obtain Compound 7 as the final product as yellow solids. (Yield: 0.47 mg, 75%).

The produced compound was confirmed through MS/FAB.

C₅₂H₅₇BN₆ cal. 776.47, found 776.46.

### Synthesis Example 4. Synthesis of Compound 12

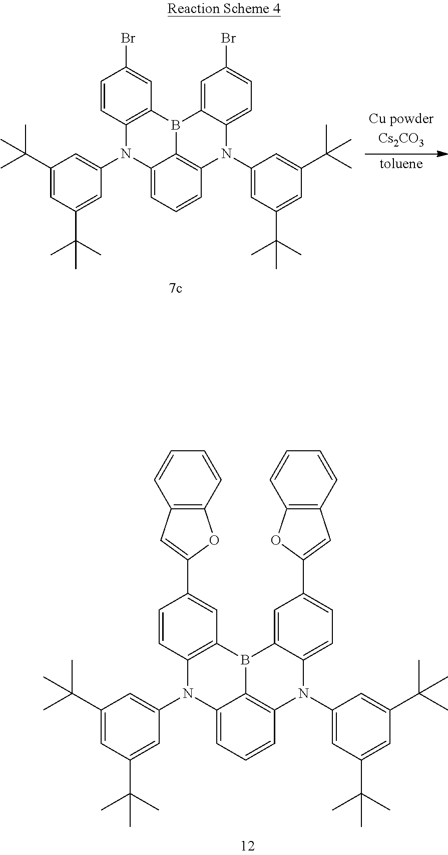

A mixture of Compound 7c (640 mg, 0.80 mmol), benzofuran-2-ylboronic acid (194 mg, 1.2 mmol), Pd(OAc)₂ (20 mg, 0.08 mmol), and Na2CO₃ (17 mg, 1.60 mmol) was added under a nitrogen atmosphere. After stirring at 110 °C for 8 hours, the reaction materials were cooled to a room temperature, and work-up was performed. The residual solid was purified through silica column chromatography to obtain final products of Compound 12 as a yellow solid. (Yield: 505 mg, 72%).

The produced compound was confirmed through MS/FAB.

C₈₂H₆₁BN₂O₂ cal. 876.48, found 876.47.

### Synthesis Example 5. Synthesis of Compound 14

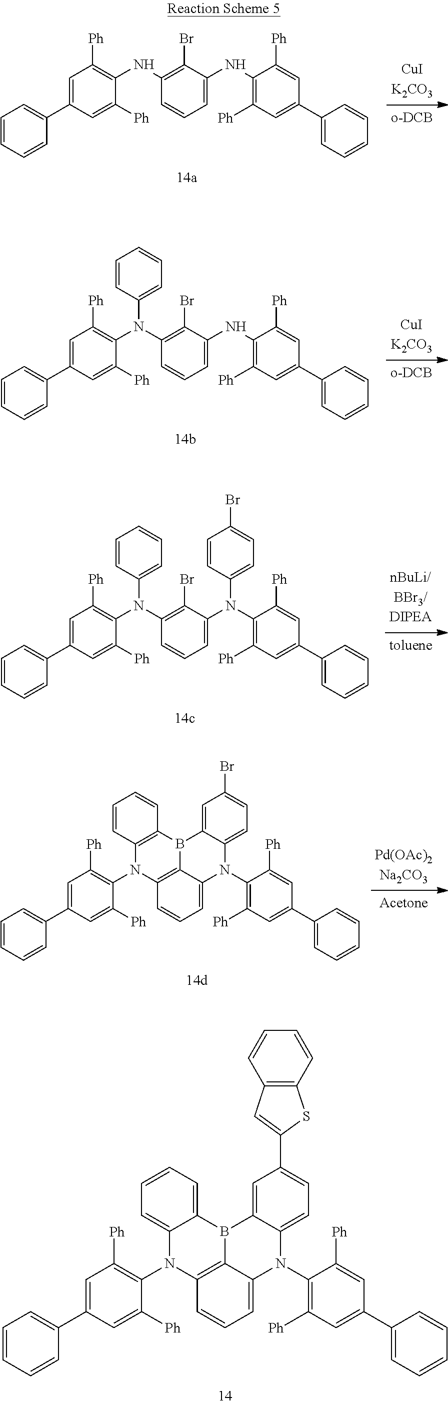

Compound 14a (2.38 g, 3.0 mmol), 4-iodo-bromobenzene (6.11 g, 30.0 mmol), CuI (0.28 g, 1.50 mmol), and K₂CO₃ (1.24 g, 9.0 mmol) were added in o-dichlorobenzene (3 mL), and the mixture was stirred at 200 °C for 48 hours. After cooling the reaction to a room temperature, an organic solvent was concentrated under a vacuum environment, and the remaining solid was purified through column chromatography (eluents: hexane/dichloromethane) using silica gel to obtain Compound 14b. (Yield: 1.46 g, 56%).

Compound 14b (2.61 g, 3.0 mmol), 4-iodo-1-bromobenzene (8.45 g, 30.0 mmol), CuI (0.28 g, 1.50 mmol), and K₂CO₃ (1.24 g, 9.0 mmol) were added to o-dichlorobenzene (3 mL), the mixture was stirred at 200 °C for 48 hours. After cooling the reaction to a room temperature, an organic solvent was concentrated under a vacuum environment, and the remaining solid was purified through column chromatography (eluents: hexane/dichloromethane) using silica gel to obtain Compound 14c. (Yield: 2.21 g, 72%).

A toluene (30 mL) solution of Compound 14c (3.07 g, 3.0 mmol) was cooled to −78 °C, and n-BuLi (1.1 equivalents) was added. After slowly heating to a room temperature and stirring for 3 hours, the reaction mixture was cooled to −30 °C. Boron tribromide (BBr₃, 0.86 mL, 9.0 mmol) was added to the reaction mixture, heated to 50 °C, and stirred overnight. After cooling the reaction flask to 0 °C, N,N-diisopropylethylamine (DIPEA, 3 equivalents) was added, and the resulting mixture was heated to 110 °C and stirred for 3 hours. After cooling the reaction mixture to a room temperature, it was diluted with dichloromethane solvent, and the reaction solution was filtered through a Celite filter. The filtered solution was concentrated and separated through column chromatography to obtain Compound 14d as a yellow solid. (Yield: 1.03 g, 36%).

A mixture of Compound 14d (1.43 g, 1.5 mmol), benzo[b]thiophen-2-ylboronc acid (0.40 g, 2.25 mmol), Pd(OAc)₂ (0.012 g, 0.045 mmol), and Na₂CO₃ (0.32 g, 3.0 mmol) was dissolved in acetone (30.0 mL) and stirred under nitrogen atmosphere at 70 °C overnight. After cooling the reaction mixture to a room temperature, it was filtered through a Celite filter. After concentrating the filtered solution under a reduced pressure, the residual materials were purified through silica gel column chromatography to obtain Compound 14 as a final product. (Yield: 0.96 g, 63%).

The produced compound was confirmed through MS/FAB.

C₇₄H₄₉BN₂S cal. 1008.37, found 1008.37.

### Synthesis Example 6. Synthesis of Compound 18

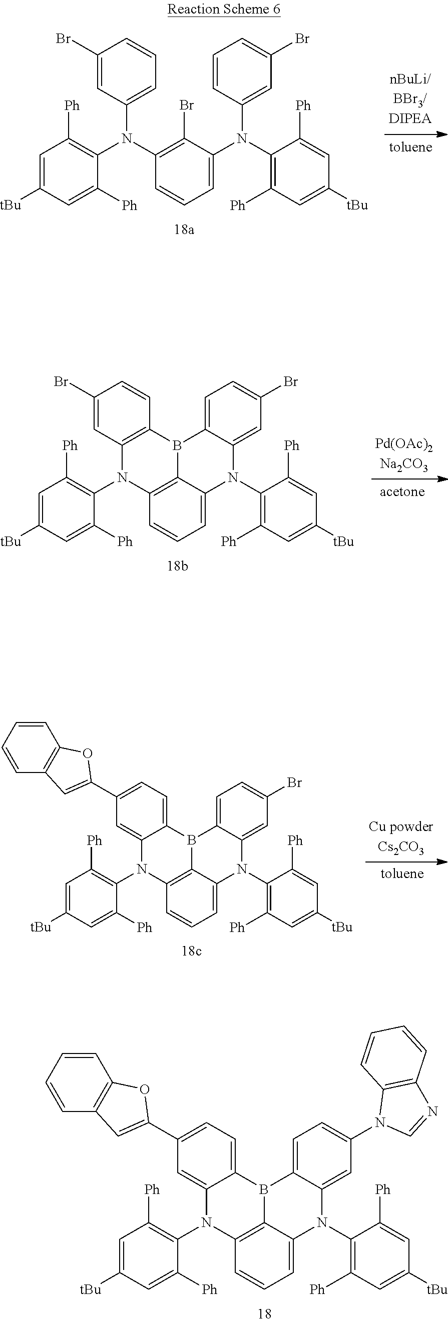

A toluene solution (30 mL) of Compound 18a (3.18 g, 3.0 mmol) was cooled to −78 °C, and n-BuLi (1.1 equivalents) was added. After slowly cooling to a room temperature, it was stirred for 3 hours, and then the reaction mixture was cooled to −30 °C. Boron tribromide (BBr₃, 0.86 mL, 9.0 mmol) was added to the reaction mixture, and the reaction mixture was then heated to 50 °C, and stirred overnight. After cooling the reaction flask to 0 °C, N,N-diisopropylethylamine (DIPEA, 3 equivalents) was added, and the reaction mixture was heated to 110 °C and stirred for 3 hours. After cooling the reaction mixture to a room temperature, it was diluted with a dichloromethane solvent, and the reaction solution was filtered through a Celite filter. Subsequently, the solution was concentrated and separated through column chromatography to obtain Compound 18b as a yellow solid. (Yield: 0.98 g, 33%).

A mixture of Compound 18b (1.43 g, 3.0 mmol), benzofuran-2-ylboronic acid (0.34 g, 2.10 mmol), Pd(OAc)₂ (17 mg, 0.063 mmol), and Na₂CO₃ (0.45 g, 4.20 mmol) were dissolved in acetone (50 mL) and stirred overnight at 70 °C under nitrogen atmosphere. The reaction mixture was cooled to a room temperature and filtered through a Celite filter. The filtered solution was concentrated under a reduced pressure, and the residual materials were purified through silica gel column chromatography to obtain Compound 18c. (Yield: 1.48 g, 48%)

Compound 18c (3.09 g, 3.0 mmol), and 1H-benzo[d]imidazole (0.53 g, 4.5 mmol) were dissolved in toluene (50 mL), and copper powder (36 mg, 0.06 mmol), and Cs₂CO₃ (1.95 g, 6.0 mmol) were added under a nitrogen atmosphere. Subsequently, the reaction mixture was stirred for 8 hours at 110 °C. After cooling the reaction mixture to a room temperature, the organic solvent was concentrated under a vacuum environment, and the residual solid was purified through silica flash column chromatography. As a final product, Compound 18 as a yellow solid was obtained. (Yield: 1.98 g, 62%).

The produced compound was confirmed through MS/FAB.

C₇₇H₆₁BN₄O cal. 1068.49, found 1068.50.

Synthesis methods of other compounds in addition to synthesized compounds in Synthesis Examples 1 through 6 may also be easily understood by a person ordinarily skilled in the art by referring to synthesis pathways and raw materials described above.

### Example 1

### Manufacture of Light-Emitting Diode of Example 1

A glass substrate (a product of Corning) formed with an ITO electrode of 15 Ω/cm² (1200 Å) as an anode was cut into a piece of 50 mm×50 mm×0.7 mm size, and processed through ultrasonic cleaning by using isopropyl alcohol and deionized (DI) water for 5 minutes, followed by treatment by ultraviolet radiation for 30 minutes and exposure to ozone. Then, the glass substrate was installed in a vacuum deposition device.

N,N′-di(1-naphthyl)-N,N′-diphenyl-(1,1′-biphenyl)-4,4′-diamine (NPD, refer to device embodiment below) was deposited on the anode to form a hole injection layer having a thickness of 300 and N-([1,1′-biphenyl]-4-yl)-9,9-dimethyl-N-(4-(9-phenyl-9H-carbazol-3-yl)phenyl)-9H-fluoren-2-a mine (BCFN, refer to device embodiment below) was deposited on the hole injection layer to form hole transport layer having a thickness of 200 Å. Thereafter, 9-(4-tert-butylphenyl)-3,6-bis(triphenylsilyl)-9H-carbazole (CzSi, refer to device embodiment below) was deposited on the hole transport layer to form a light-emission auxiliary layer having a thickness of 100 Å.

Pre-mixed HT and ET were mixed on the light-emission auxiliary layer as an exciplex host. Co-deposition was performed with a weight ratio of the exciplex host:the first dopant:the second dopant as 85:1:14 to form a light-emission layer having a thickness of 200 Å. Thereafter, diphenyl-4-triphenylsilylphenyl-phosphine oxide (TSPO1, refer to device embodiment below) was deposited on the hole blocking layer to form an electron transport layer having a thickness of 300 Å. Subsequently, LiF was deposited on the electron transport layer to form an electron injection layer having a thickness of 10 Å, and Al was deposited on the electron injection layer to form a cathode having a thickness of 3000 Å. Accordingly, a light-emitting diode was manufactured.

A compound used in the Examples are shown in Table 2.

Particularly, ET-2 was used as an ET host, and HT-2 was used as an HT host. PS-2 was used as the second dopant.

### Device Embodiment

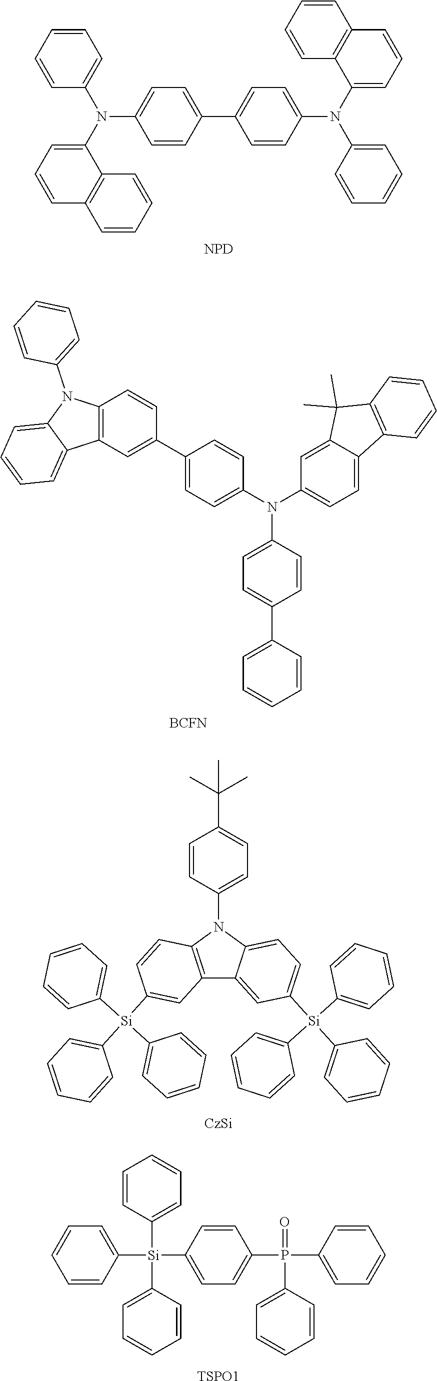

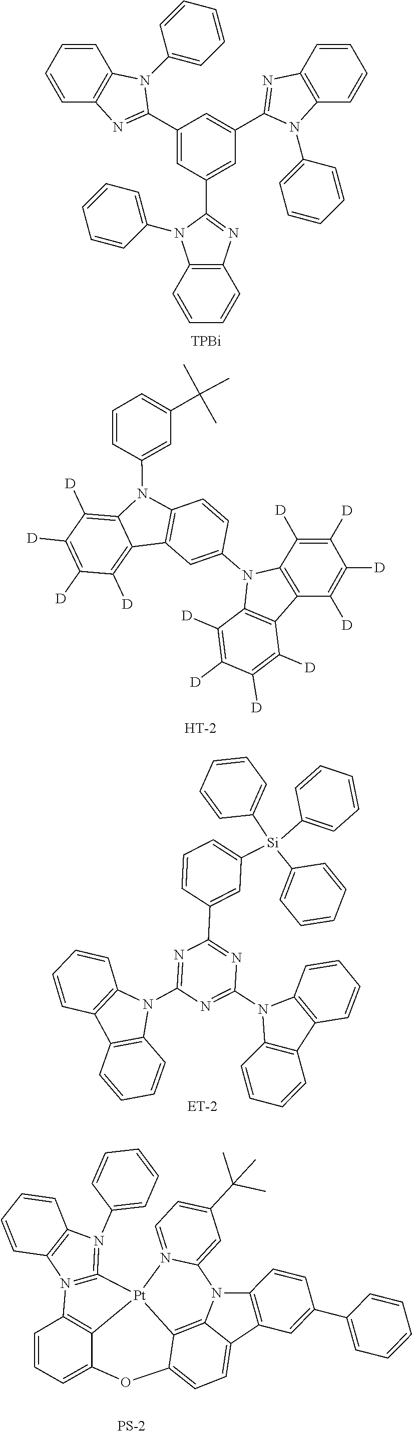

### Manufacture of Light-Emitting Diode of Example 2 Through Example 6

In formation of a blue light-emission layer, except for using Compound 3 (Example 2), Compound 7 (Example 3), Compound 12 (Example 4), Compound 14 (Example 5), or Compound 18 (Example 6) instead of Compound 1, a light-emitting diode was manufactured through the same method as Example 1.

### COMPARATIVE EXAMPLES

### Manufacture of Light-Emitting Diode of Comparative Example 1 (Compound 100) and Comparative Example 2 (Compound 101)

Except for using Compound 100 (Comparative Example 1) or Compound 101 (Comparative Example 2) instead of Compound 1, a light-emitting diode was manufactured through the same method as in Example 1.

Compounds of Comparative Example 1 (Compound 100) and Comparative Example (Compound 101) are shown below.

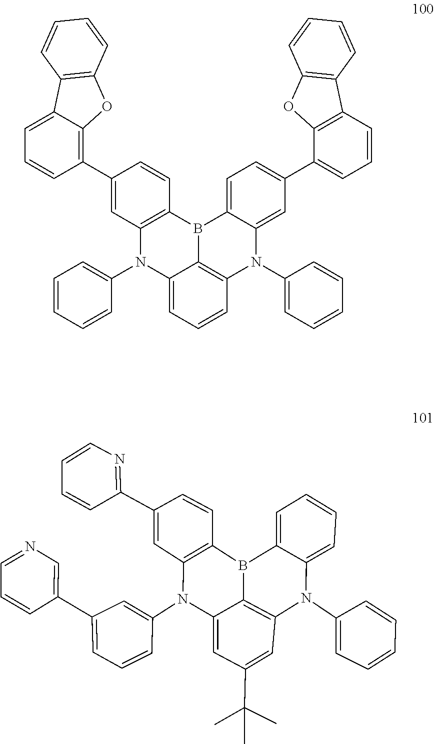 [SMILES: c1ccc(N2c3cc(-c4cccc5c4oc4ccccc45)ccc3B3c4ccc(-c5cccc6c5oc5ccccc56)cc4N(c4ccccc4)c4cccc2c43)cc1 ; CC(C)(C)c1cc2c3c(c1)N(c1cccc(-c4cccnc4)c1)c1cc(-c4ccccn4)ccc1B3c1ccccc1N2c1ccccc1]

### Evaluation Example 1. Evaluation Results of Optical-Physical Properties

In order to determine optical-physical properties of Synthesis Example 1 through Synthesis Example 6, an absorption wavelength, a light-emission wavelength, quantum efficiency and light-emission full width at half maximum were measured and described in Table 1.

TABLE 1

| | | Absorption | Light-emission | Quantum | Full Width at |
|---|---|---|---|---|---|
| | | Wavelength | Wavelength | Efficiency | Half Maximum |
| No. | Compound | (nm) | (nm) | (%) | (nm) |
| Synthesis | 1 | 455 | 470 | 86 | 20 |
| Example 1 | | | | | |
| Synthesis | 3 | 451 | 465 | 83 | 19 |
| Example 2 | | | | | |
| Synthesis | 7 | 453 | 473 | 95 | 20 |
| Example 3 | | | | | |
| Synthesis | 12 | 446 | 462 | 80 | 19 |
| Example 4 | | | | | |
| Synthesis | 14 | 443 | 458 | 78 | 21 |
| Example 5 | | | | | |
| Synthesis | 18 | 448 | 463 | 100 | 20 |
| Example 6 | | | | | |

Referring Table 1, quantum efficiencies of Synthesis Example 1 through Synthesis Example 6 were improved. This shows that stability of a material of a light-emitting diode is improved.

### Evaluation Example 2. Result Properties of Efficiency and Lifespan Ratio of Light-Emitting Diode

Compositions of the manufactured Example 1 through Example 6, and Comparative Example 1 and Comparative Example 2, and driving voltages (V, volts), current efficiency (cd/A), and lifespan ratios thereof were measured and shown in Table 2. Here, the lifespan is calculated as a relative ratio with respect to Comparative Example 2. The lifespan ratio (T95) is a measured value of a time taken for luminance of a light-emitting diode to decrease by 5% compared to its initial luminance since its operation. The lifespan (T95) may be a measurement of stability and durability of a light-emitting diode and be a key factor in determining potential occurrence of burn-in phenomena.

TABLE 2

| | | | | Driving | Current | Lifespan |
|---|---|---|---|---|---|---|
| | Exciplex | | Second | Voltage | Efficiency | ratio |
| No. | host | First dopant | dopant | (V) | (cd/A) | (T95) |
| Embodiment 1 | HT-2/ET-2 | Compound 1 | PS-2 | 4.1 | 28.7 | 2.3 |
| Embodiment 2 | HT-2/ET-2 | Compound 3 | PS-2 | 4.5 | 28.6 | 2.0 |
| Embodiment 3 | HT-2/ET-2 | Compound 7 | PS-2 | 4.3 | 28.7 | 2.2 |
| Embodiment 4 | HT-2/ET-2 | Compound 12 | PS-2 | 4.3 | 28.2 | 2.6 |
| Embodiment 5 | HT-2/ET-2 | Compound 14 | PS-2 | 4.4 | 26.5 | 2.2 |
| Embodiment 6 | HT-2/ET-2 | Compound 18 | PS-2 | 4.0 | 27.3 | 2.7 |
| Comparative | HT-2/ET-2 | Compound 100 | PS-2 | 4.6 | 24.5 | 1.5 |
| Example 1 | | | | | | |
| Comparative | HT-2/ET-2 | Compound 101 | PS-2 | 5.0 | 23.0 | 1.0 |
| Example 2 | | | | | | |

Referring to Table 2, a light-emitting diode having a structure according to one or more embodiments may include a first dopant represented by Formula 1 and a second dopant represented by Formula 2 in an organic layer as light-emission layer materials. In comparison to Comparative Example 1 and Comparative Example 2, driving voltages were reduced, and current efficiency and lifespan ratio (T95) were improved. The improved current efficiency and lifespan ratio may allow mass production of a light-emitting diode and implementation of high performance.

While certain embodiments have been described above, anyone ordinarily skilled in the art to which the present disclosure pertains shall appreciate that there may be a variety of modifications and permutations of the present disclosure without departing from the technical ideas and scopes of the present disclosure that are defined in the appended claims.

Therefore, the technical scope of the present disclosure should be interpreted by the scope of the claims and equivalents thereof, instead of being restricted the disclosed description in Detailed Description.

What is claimed is:

1. A light-emitting diode comprising:
a first electrode;
a second electrode arranged on the first electrode; and
one or more organic layers arranged between the first electrode and the second electrode,
wherein at least one organic layer among the one or more organic layers comprises a first dopant and a second dopant,
wherein the first dopant is a fluorescence dopant,
wherein the second dopant is a phosphorescence dopant, and
wherein the first dopant comprises a compound represented by Formula 1: 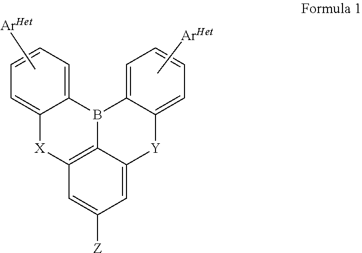
wherein, in Formula 1,
each Ar^{Het} is independently hydrogen or a substituted or unsubstituted heteroaryl group of 2 to 60 carbons;
each Ar^{Het} is identical to or different from the other, provided that at least one of Ar^{Het} is not hydrogen;
X and Y are each independently O, S, Se, or NAr¹;
Z is hydrogen, deuterium, a halogen, a cyano group, a substituted or unsubstituted silyl group, a substituted or unsubstituted amino group, a substituted or unsubstituted oxy group, a substituted or unsubstituted alkyl group of 1 to 20 carbons, a substituted or unsubstituted aryl group of 6 to 60 ring-forming carbons, or a substituted or unsubstituted heteroaryl group of 2 to 60 ring-forming carbons;
Z is optionally bonded to an adjacent group to form a ring; and
Ar¹ is a substituted or unsubstituted aryl group of 6 to 60 carbons.

2. The light-emitting diode of claim 1,
wherein the second dopant comprises one or more organometallic compounds represented by Formula 2: 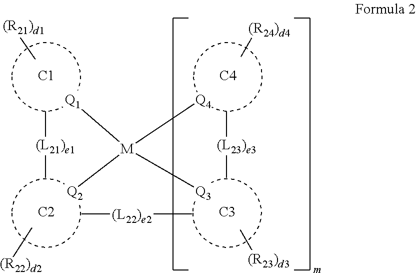
wherein in Formula 2:
M is Pt, Pd, Cu, Os, Ir, Ru, or Rh;
Q₁ to Q₄ each independently is C or N;
ring C₁ to ring C₄ each independently is a substituted or unsubstituted hydrocarbon ring group of 5 to 30 ring-forming carbons, or a substituted or unsubstituted heteroring group of 2 to 30 ring-forming carbons;
R₂₁ to R₂₄ are each independently hydrogen, deuterium, a halogen, a cyano group, a substituted or unsubstituted silyl group, a substituted or unsubstituted amino group, a substituted or unsubstituted oxy group, a substituted or unsubstituted alkyl group of 1 to 20 carbons, a substituted or unsubstituted aryl group of 6 to 60 ring-forming carbons, or a substituted or unsubstituted heteroaryl group of 2 to 60 ring-forming carbons;
R₂₁ to R₂₄ are optionally bonded to an adjacent group to form a ring;
d1 through d4 each independently is an integer of greater than or equal to 0 and less than or equal to 10;
L₂₁ to L₂₃ each independently is a direct linkage, O, or S;
e1 through e3 is each independently an integer of greater than or equal to 0 and less than or equal to 5; and
m is an integer of greater than or equal to 1 and less than or equal to 3.

3. The light-emitting diode of claim 1,
wherein the first dopant is one or more of a compound represented by Formula 3 through Formula 6: 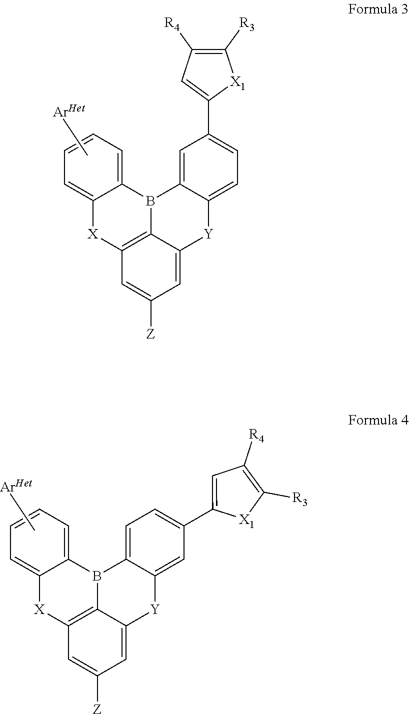
wherein in Formula 3 and Formula 4,
X₁ is N, S, O, or Se;
R₃ and R₄ are each independently hydrogen, a substituted or unsubstituted heteroaryl group of 2 to 30 ring-forming carbons or bonded together to form a ring; and
X, Y, and Z are as defined for Formula 1 in claim 1, 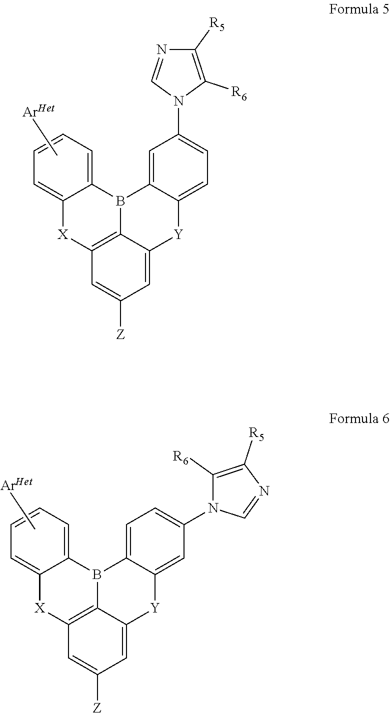
wherein, in Formula 5 and Formula 6,
R₅ and R₆ each independently are hydrogen, a substituted or unsubstituted heteroaryl group of 2 to 30 ring-forming carbons or bonded together to form a ring; and
X, Y, and Z are as defined for Formula 1 in claim 1.

4. The light-emitting diode of claim 1,
wherein each Ar^{Het} is independently hydrogen, a pyrrole group, a furan group, a thiophene group, a pyrazole group, an imidazole group, a thiazole group, a triazole group, an oxazole group, an isoxazole group, an indole group, an indazole group, a benzofuran group, a benzothiazole group, an indolizine group, or a pyrrolidine group.

5. The light-emitting diode of claim 1,
wherein the compound represented by the Formula 1 is one or more of Compound 1 through Compound 19: 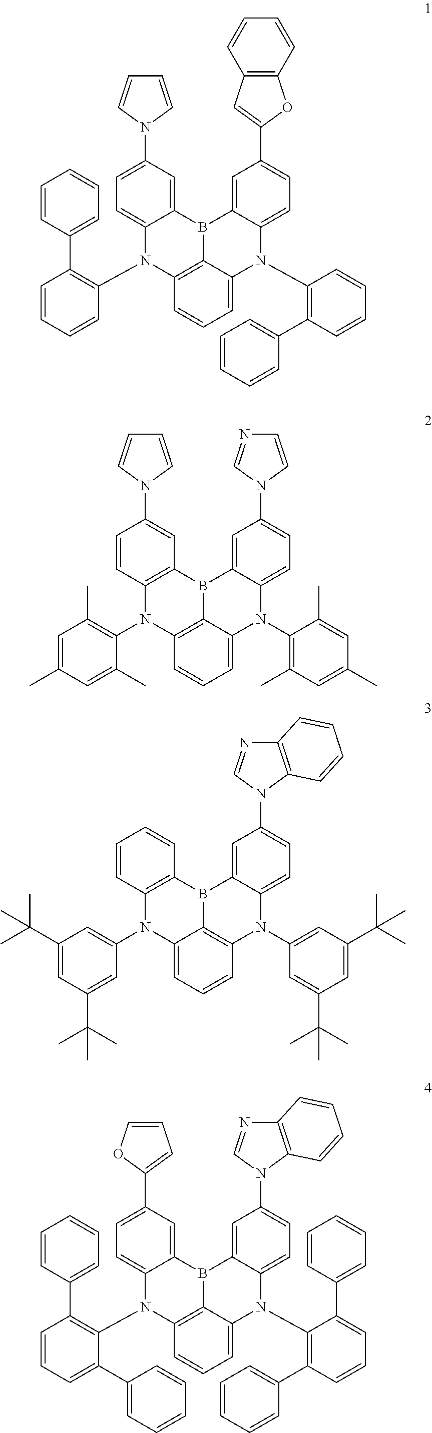 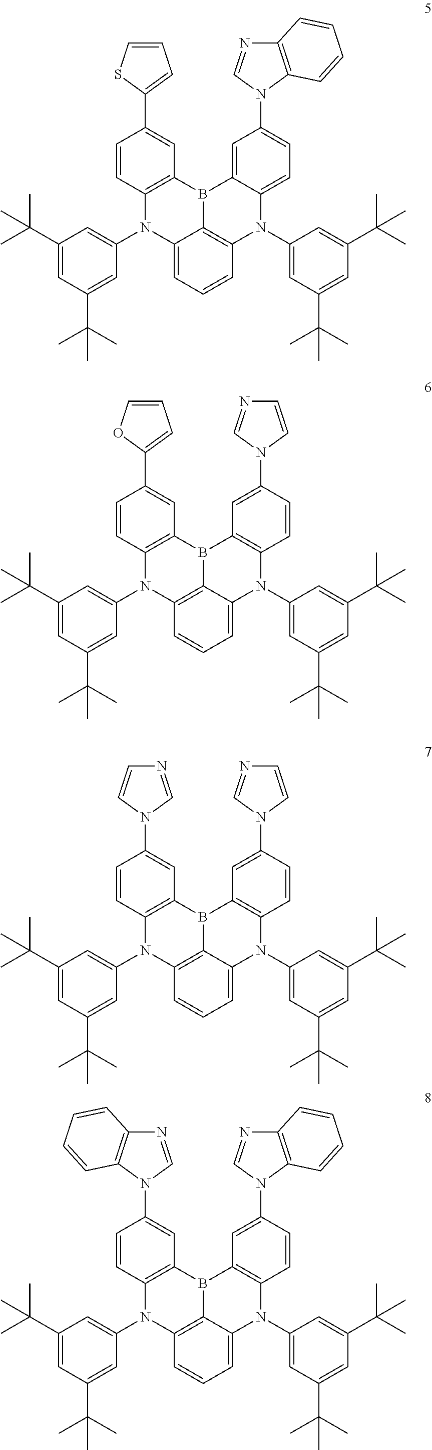 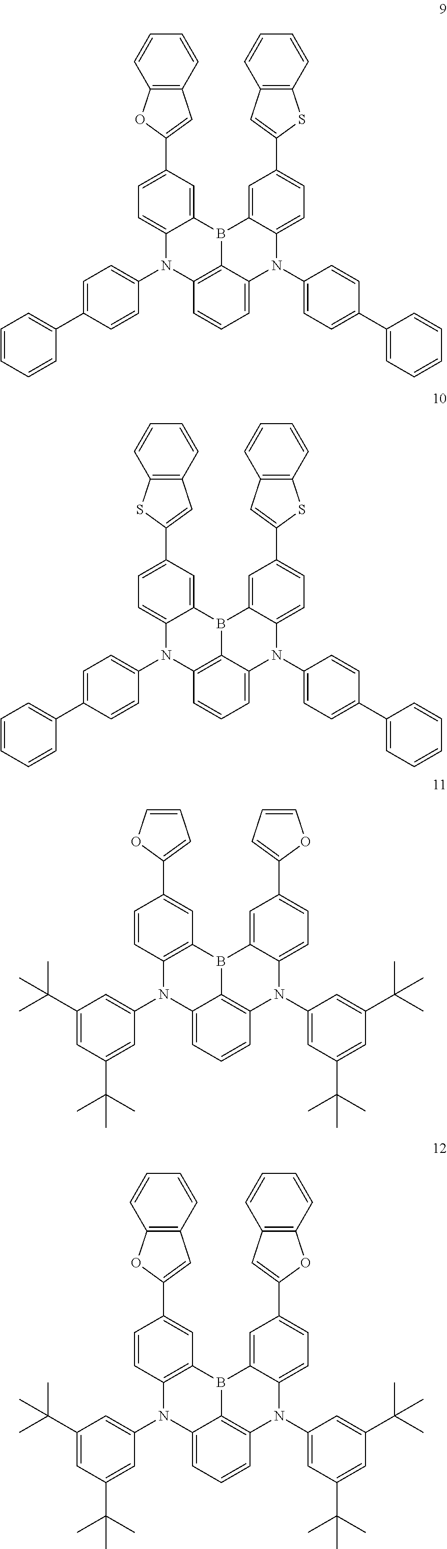 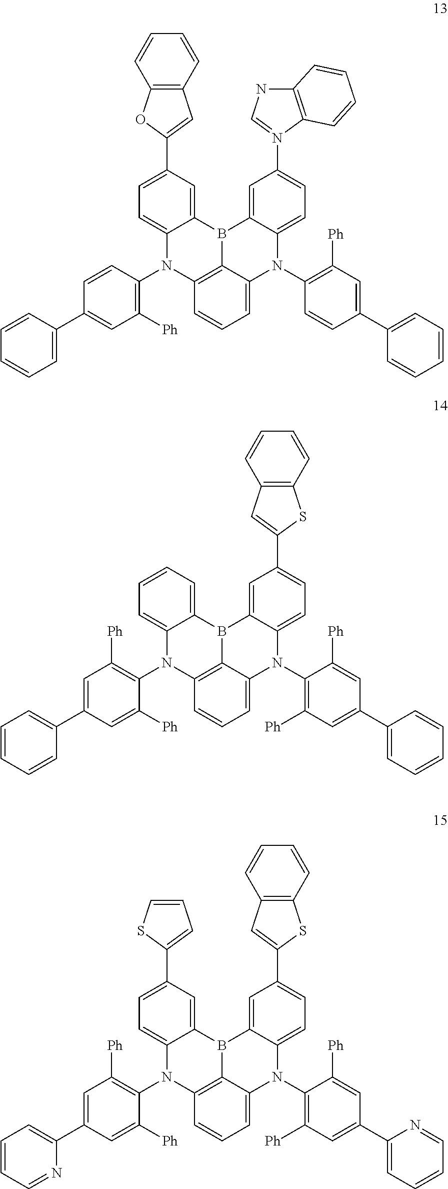 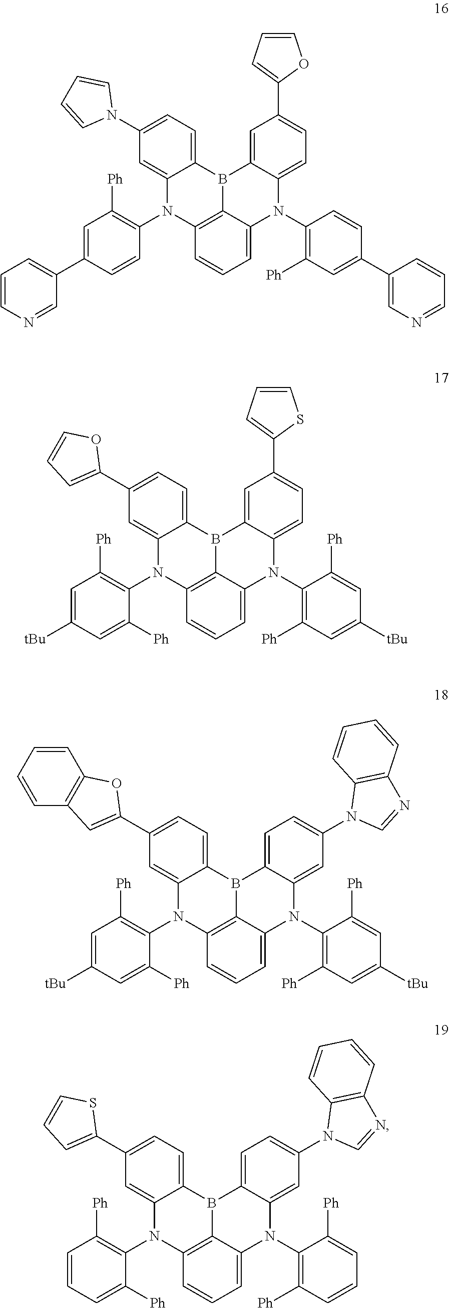
wherein “Ph” is phenyl and “tBu” is tertiary butyl.

6. The light-emitting diode of claim 2,
wherein the second dopant comprises one or more organometallic compounds represented by Formula 7: 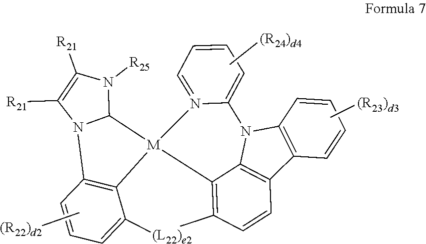
Wherein, in Formula 7,
M is Pt, Pd, Cu, Os, Ir, Ru, or Rh;
R₂₁ to R₂₅ each independently are hydrogen, deuterium, a halogen, a cyano group, a substituted or unsubstituted silyl group, a substituted or unsubstituted amino group, a substituted or unsubstituted oxy group, a substituted or unsubstituted alkyl group of 1 to 20 carbons, a substituted or unsubstituted aryl group of 6 to 60 ring-forming carbons, or a substituted or unsubstituted heteroaryl group of 2 to 60 ring-forming carbons;
R₂₁ to R₂₅ are optionally bonded to an adjacent group to form a ring;
d2 through d4 each independently are an integer of greater than or equal to 0 and less than or equal to 2;
L₂₂ is a direct linkage, O, or S; and
e2 is an integer of 1 or 2.

7. The light-emitting diode of claim 1,
wherein a weight ratio of the first dopant to the second dopant is about 1:8 to about 1:30.

8. The light-emitting diode of claim 1,
wherein the first dopant has an absorption wavelength of about 440 nanometers to about 455 nanometers and a light-emission wavelength of about 455 nanometers to about 480 nanometers.

9. The light-emitting diode of claim 1,
wherein the first dopant has a full width at half maximum of less than or equal to about 40 nanometers.

10. The light-emitting diode of claim 1,
wherein a thickness of an organic layer manufactured through co-deposition of the first dopant and the second dopant is greater than or equal to about 100 angstroms and less than or equal to about 500 angstroms.

11. The light-emitting diode of claim 1,
wherein a content of the first dopant is about 0.01 to about 10 parts by weight based on 100 parts by weight of a light-emission layer, and a content of the second dopant is about 10 parts by weight to about 20 parts by weight based on 100 parts by weight of the light-emission layer.

12. The light-emitting diode of claim 1,
wherein light emitted from the organic layer has a maximum light-emission wavelength of greater than or equal to about 380 nanometers and less than or equal to about 500 nanometers.

13. The light-emitting diode of claim 1,
wherein the organic layer is a deep blue light-emission layer.

14. The light-emitting diode of claim 1,
wherein light-emission quantum efficiency of a light-emission spectrum of the first dopant is greater than or equal to about 50% and less than or equal to about 100%.

15. An electronic device comprising a light-emitting diode, wherein the light-emitting diode comprises:
a first electrode;
a second electrode arranged on the first electrode; and
one or more organic layers arranged between the first electrode and the second electrode,
wherein at least one organic layer among the one or more organic layers comprises a first dopant and a second dopant,
wherein the first dopant is a fluorescence dopant,
wherein the second dopant is a phosphorescence dopant, and
wherein the first dopant comprises a compound represented by Formula 1: 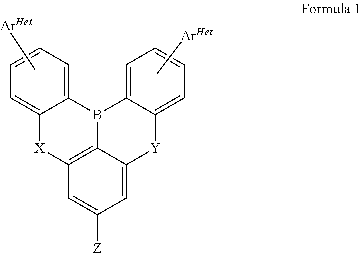
wherein in Formula 1:
each Ar^{Het} is independently hydrogen or a substituted or unsubstituted heteroaryl group of 2 to 60 carbons;
each Ar^{Het} is identical to or different from the other, provided that at least one of Ar^{Het} is not hydrogen;
X and Y each independently are O, S, Se, or NAr¹;
Z is hydrogen, deuterium, a halogen, a cyano group, a substituted or unsubstituted silyl group, a substituted or unsubstituted amino group, a substituted or unsubstituted oxy group, a substituted or unsubstituted alkyl group of 1 to 20 carbons, a substituted or unsubstituted aryl group of 6 to 60 ring-forming carbons, or a substituted or unsubstituted heteroaryl group of 2 to 60 ring-forming carbons,
Z is optionally bonded to an adjacent group to form a ring; and
Ar¹ is a substituted or unsubstituted aryl group of 6 to 60 carbons.

16. The electronic device of claim 15,
wherein the electronic device further comprises a display device, a processor configured to control the display device, a memory storing data necessary for operation of the display device or the processor, and a power module configured to generate or supply power.

17. A composition for producing a light-emitting diode, the composition comprising:
a first dopant, which is a fluorescence dopant, represented by Formula 1; and
a second dopant, which is a phosphorescence dopant, represented by Formula 2: 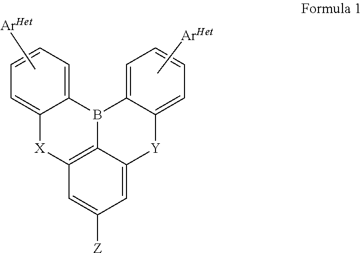
wherein, in Formula 1,
each Ar^{Het} is independently hydrogen or a substituted or unsubstituted heteroaryl group of 2 to 60 carbons;
each Ar^{Het} is identical to or different from the other, provided that at least one Ar^{Het} is not hydrogen;
X and Y each independently are O, S, Se, or NAr¹;
Z is hydrogen, deuterium, a halogen, a cyano group, a substituted or unsubstituted silyl group, a substituted or unsubstituted amino group, a substituted or unsubstituted oxy group, a substituted or unsubstituted alkyl group of 1 to 20 carbons, a substituted or unsubstituted aryl group of 6 to 60 ring-forming carbons, or a substituted or unsubstituted heteroaryl group of 2 to 60 ring-forming carbons,
Z is optionally bonded to an adjacent group to form a ring; and
Ar¹ is a substituted or unsubstituted aryl group of 6 to 60 carbons, 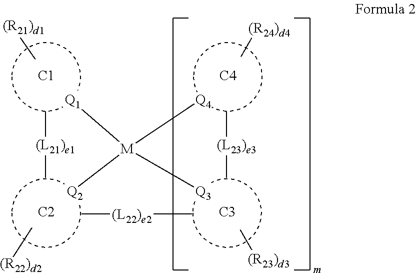
wherein, in Formula 2,
M is Pt, Pd, Cu, Os, Ir, Ru, or Rh;
Q₁ to Q₄ each independently is C or N;
ring C₁ to ring C₄ each independently is a substituted or unsubstituted hydrocarbon ring group of 5 to 30 ring-forming carbons, or a substituted or unsubstituted heteroring group of 2 to 30 ring-forming carbons;
R₂₁ to R₂₄ are each independently hydrogen, deuterium, a halogen, a cyano group, a substituted or unsubstituted silyl group, a substituted or unsubstituted amino group, a substituted or unsubstituted oxy group, a substituted or unsubstituted alkyl group of 1 to 20 carbons, a substituted or unsubstituted aryl group of 6 to 60 ring-forming carbons, or a substituted or unsubstituted heteroaryl group of 2 to 60 ring-forming carbons;
R₂₁ to R₂₄ are optionally bonded to an adjacent group to form a ring;
d1 through d4 each independently is an integer of greater than or equal to 0 and less than or equal to 10;
L₂₁ to L₂₃ each independently is a direct linkage, O, or S;
e1 through e3 is an integer of greater than or equal to 0 and less than or equal to 5; and
m is an integer of greater than or equal to 1 and less than or equal to 3.

18. The composition of claim 17,
wherein the first dopant is one or more of a compound represented by Formula 3 through Formula 6 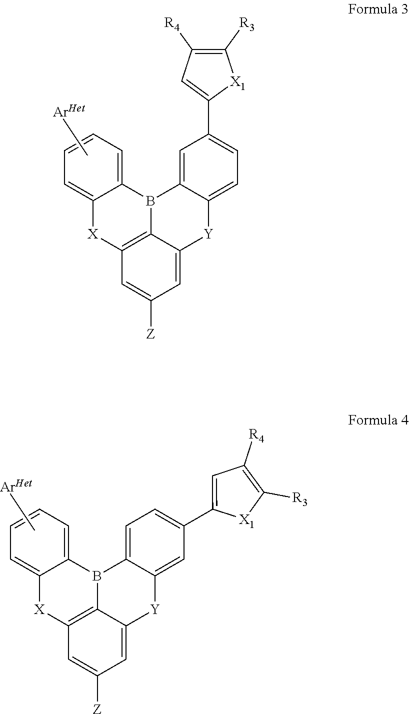
wherein, in Formula 3 and Formula 4,
X₁ is N, S, O, or Se;
R₃ and R₄ each independently are hydrogen, a substituted or unsubstituted heteroaryl group of 2 to 30 ring-forming carbons or bonded together to form a ring; and
X, Y, and Z are as defined for Formula 1 in claim 17, 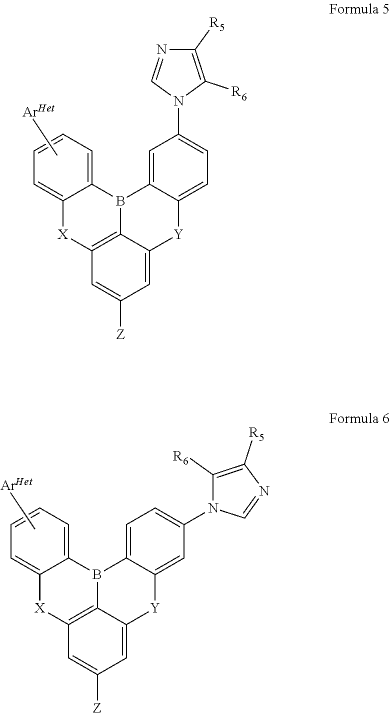
wherein, in Formula 5 and Formula 6,
R₅ and R₆ each independently are hydrogen, a substituted or unsubstituted heteroaryl group of 2 to 30 ring-forming carbons or bonded together to form a ring; and
X, Y, and Z are as defined for Formula 1 in claim 17.

19. The composition for producing a light-emitting diode of claim 17,
wherein the second dopant comprises one or more organometallic compounds represented by Formula 7: 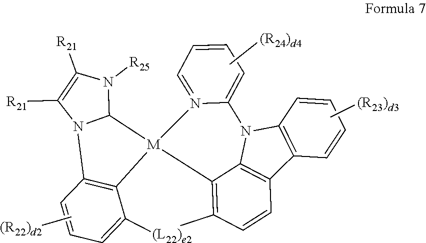
wherein, in Formula 7,
M is Pt, Pd, Cu, Os, Ir, Ru, or Rh;
R₂₁ to R₂₅ each independently are hydrogen, deuterium, a halogen, a cyano group, a substituted or unsubstituted silyl group, a substituted or unsubstituted amino group, a substituted or unsubstituted oxy group, a substituted or unsubstituted alkyl group of 1 to 20 carbons, a substituted or unsubstituted aryl group of 6 to 60 ring-forming carbons, or a substituted or unsubstituted heteroaryl group of 2 to 60 ring-forming carbons;
R₂₁ to R₂₅ are optionally bonded to an adjacent group to form a ring;
d2 through d4 each independently are an integer of greater than or equal to 0 and less than or equal to 2;
L₂₂ is a direct linkage, O, or S; and
e2 is an integer of 1 or 2.

20. The composition of claim 18,
wherein the first dopant has an absorption wavelength of about 440 nanometers to about 455 nanometers, a light-emission wavelength of about 455 nanometers to about 480 nanometers, and a full width at half maximum of less than or equal to about 40 nanometers.
